(19) United States
(12) Patent Application Publication
(10) Pub. No.: US 2025/0048916 A1
(43) Pub. Date: Feb. 6, 2025

(54) BINUCLEAR METAL PLATINUM COMPLEX AND ORGANIC ELECTROLUMINESCENT DEVICE

(71) Applicant: SHENZHEN UNIVERSITY, Shenzhen, Guangdong (CN)

(72) Inventors: Kai LI, Shenzhen (CN); Jinfan XIONG, Shenzhen (CN); Chuluo YANG, Shenzhen (CN)

(73) Assignee: SHENZHEN UNIVERSITY, Shenzhen, Guangdong (CN)

(21) Appl. No.: 18/700,249

(22) PCT Filed: May 16, 2022
(86) PCT No.: PCT/CN2022/092983

§ 371 Date: Apr. 10, 2024

(30) Foreign Application Priority Data
Oct. 28, 2021 (CN) 202111265181.7

(51) Int. Cl. H10K 85/30; C07F 15/00; C09K 11/02; C09K 11/06; H10K 50/11

(52) U.S. Cl. CPC H10K 85/346; C07F 15/0086; C09K 11/02; C09K 11/06; C09K 2211/1007; C09K 2211/1029; C09K 2211/1037; C09K 2211/1044; C09K 2211/1092; C09K 2211/185; H10K 50/11

(57) ABSTRACT

The present invention relates to the technical field of electronic materials, and specifically relates to a binuclear metal platinum complex and an organic electroluminescent device. The binuclear metal platinum complex provided by the present invention has a structure as shown in formula I, and has high luminous efficiency and excellent thermal stability. Therefore, an OLED device prepared from the binuclear metal platinum complex as a luminescent layer material shows high external quantum efficiency and relatively low luminous efficiency roll-off.

### TECHNICAL FIELD

The present application relates to the technical field of electronic materials, and specifically relates to a binuclear metal platinum complex and an organic electroluminescent device.

### BACKGROUND

Organic Light Emitting Diodes (OLEDs), made of organic luminescent materials, have been used as display screens in high-end smart phones, wearable devices, and other fields due to their low energy consumption, wide operating temperature range, high color purity, self-illumination, flexibility and foldability, ultra-thin characteristics, etc., and they will receive more attention in the fields of television, car displays, etc.

At present, in the OLED display device industry, as one of the core materials of OLED technology, the mechanism and performance of luminescent materials are one of the key factors restricting the performance of OLEDs. In 1998, Chinese and American scientists developed phosphorescent OLEDs based on osmium and platinum complexes, respectively. Phosphorescent materials enhance the molecular spin-orbit coupling by introducing heavy metal atoms to promote the radiative transition from the lowest triplet excitons to the ground state to produce luminescence. Because singlet and triplet excitons can be utilized simultaneously, the theoretical maximum internal quantum efficiency (IQE) can reach 100%. Since then, iridium complexes based on this mechanism have attracted widespread attention in academia and industry due to their excellent luminescent properties, thermal stability, etc. At present, red light-emitting and green light-emitting iridium complexes have been industrialized in the field of commercial OLED display screens.

However, the extremely low reserves of iridium element in the earth's crust are considered to be a bottleneck restricting the development of the OLED industry, and scientists have been exploring luminescent materials that can replace iridium complexes. Among them, the research group of Academician Zhi Zhiming of the University of Hong Kong (Chem. Commun. 2005, 11, 1408-1410; Chem. Asian J. 2014, 9, 2984-2994; Adv. Optical Mater. 2019, 7, 1801452) and Li Jian research group from Arizona State University (Adv. Mater. 2017, 29, 1605002; ACS Appl. Mater. Interfaces 2015, 7, 16240-16246) has made a series of studies on red light-emitting platinum complexes based on tetradentate ligands, and found that tetradentate chelate ligands can improve the luminescent properties of materials and maintain good thermal stability of the complexes. UDC Company of the United States, Samsung of South Korea, and Guangdong Aglaia Optoelectronic Materials co. LTD of Foshan, Guangdong, China have all carried out related invention explorations based on tetradentate ligands.

At present, the commercialized red light-emitting OLED materials are still mainly iridium complexes, and other materials have not yet reached the standards for industrial use in terms of comprehensive performance. The excited state lifetime of phosphorescent platinum complexes is significantly longer than that of iridium complexes, and it is easy to cause exciton quenching at high current densities, thereby limiting the maximum luminous brightness and causing serious efficiency roll-off. More importantly, long excited-state lifetime is not conducive to device lifetimes. At the same time, more complex molecular structures usually include more active chemical groups or chemical bonds, which is not conducive to the stability of the device under the electric field. Therefore, luminescent materials with short excited state lifetimes and the use of simple and stable molecular frameworks are the key to the development of new OLED luminescent materials.

### SUMMARY OF THE INVENTION

Aiming at the deficiencies of the prior art, the purpose of the present application is to overcome the shortcomings of the limited efficiency and stability of the device obtained by using the existing metal platinum complex, and then provide a dual nuclear metal platinum complex and organic electroluminescent device.

The solution adopted in the present application is as follows.

A binuclear metal platinum complex, having the following structure:

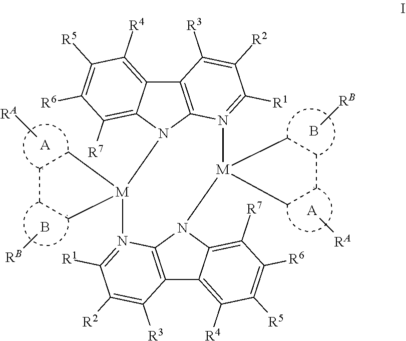

wherein, M is platinum metal; ring A and ring B are each independently selected from a C₆-C₁₈ aryl and a C₅-C₁₇ heteroaryl, ring A and ring B can be connected by a single bond or by forming a fused ring, and ring A and ring B coordinate with metal M center in a form of a negative monovalent bidentate ligand;
ring A and ring B are optionally substituted by one or more substituents R^{A} or R^{B}; R^{A} and R^{B} are each independently selected from hydrogen, deuterium, a heteroatom-containing substituent, a C₁-C₄₀ alkyl, a C₂-C₄₀ alkenyl, a C₂-C₄₀ alkynyl, a C₆-C₄₈ aryl, and a C₅-C₄₈ heteroaryl; R¹ to R⁷ are the same or different and are each independently selected from hydrogen, deuterium, a heteroatom-containing substituent, a C₁-C₄₀ alkyl, a C₂-C₄₀ alkenyl, a C₂-C₄₀ alkynyl, a C₆-C₄₈ aryl and a C₅-C₄₈ heteroaryl; or adjacent two of R¹ to R⁷ are connected with each other to form a C₃-C₁₀ cycloalkyl, a C₆-C₃₀ aryl or a C₅-C₃₀ heteroaryl.

The binuclear metal platinum complex provided by the present application is a half-lantern type neutral binuclear platinum (II) complex formed by using α-carboline and its derivatives as bridging bidentate ligands: [(L_{AB})M(μ-L_{cz1})]₂, where M is the transition metal platinum (Pt), and its oxidation valence is +2; L_{cz1} is a substituted (R¹-7) or unsubstituted α-carboline, used as a bridging bidentate ligand, and its total valence is −1; L_{AB} is a bidentate chelating ligand formed by linking ring A and ring B, and its total valence is −1.

Preferably, the ligand L_{AB} has the following structure

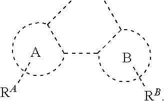

Further preferably, ring A and ring B are each independently selected from phenyl, naphthyl, anthryl, fluorenyl, pyridyl, pyrimidinyl, pyridazinyl, pyrazinyl, quinolinyl, isoquinolinyl, benzopyrimidinyl, benzopyridazinyl, benzopyrazinyl, thienyl, pyrrolyl, pyrazolyl, thiazolyl, imidazolyl, oxazolyl, 1,2,4-triazolyl, 1,2,3-triazolyl, isoxazolyl, isothiazolyl, indolyl, benzimidazolyl, benzothienyl, and benzothiazolyl;
ring A and ring B are optionally substituted by one or more substituents R^{A} or R^{B}; R^{A} and R^{B} are each independently selected from hydrogen, deuterium, a heteroatom-containing substituent, a C₁-C₄₀ alkyl, a C₆-C₄₈ aryl, and a C₅-C₄₈ heteroaryl.

Preferably, the ligand L_{cz1} has the following structure:

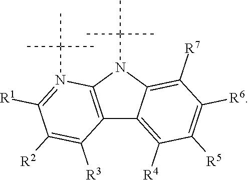

Further preferably, R¹ to R⁷ are the same or different and are each independently selected from hydrogen, deuterium, a heteroatom-containing substituent, a C₁-C₁₀ alkyl, a C₆-C₂₀ aryl and a C₅-C₁₉ heteroaryl; or adjacent two of R¹ to R⁷ are connected with each other to form a C₃-C₈ cycloalkyl, a C₆-C₁₀ aryl or a C₅-C₉ heteroaryl.

Preferably, R^{A} and R^{B} are each independently selected from —F, —Cl, —Br, —I, —O(R′), —S(R′), —N(R′)₂, —SO(R′), —SO₂(R′), —P(R′)₂, —PO(R′)₂, —PO(OR′)(R′), —PO(OR′)₂, —Si(R′)₃, a C₁-C₂₀ alkyl, a C₂-C₂₀ alkenyl, a C₂-C₂₀ alkynyl, a C₁-C₂₀ haloalkyl, a C₁-C₈ alkoxy, a C₃-C₈ cycloalkyl, a C₃-C₈ heterocycloalkyl, a C₃-C₈ aryl, a C₃-C₈ heteroaryl; wherein, R′ is independently selected from hydrogen, a halogen, a C₁-C₈ alkyl, a C₁-C₈ haloalkyl, a C₃-C₈ cycloalkyl, a C₃-C₈ heterocycloalkyl, a C₃-C₈ aryl, and a C₃-C₈ heteroaryl.

Preferably, R², R³, R⁴, R⁶ and R⁷ are selected from hydrogen, and R¹ and R⁵ are independently selected from hydrogen, deuterium, a heteroatom-containing substituent, a C₁-C₄₀ alkyl, a C₆-C₄₈ aryl and a C₃-C₄₈ heteroaryl.

The heteroatom-containing substituent includes but is not limited to silicon atoms, oxygen atoms, nitrogen atoms, sulfur atoms, and halogen atoms.

Preferably, in formula I,

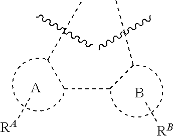

comprises the following structures:

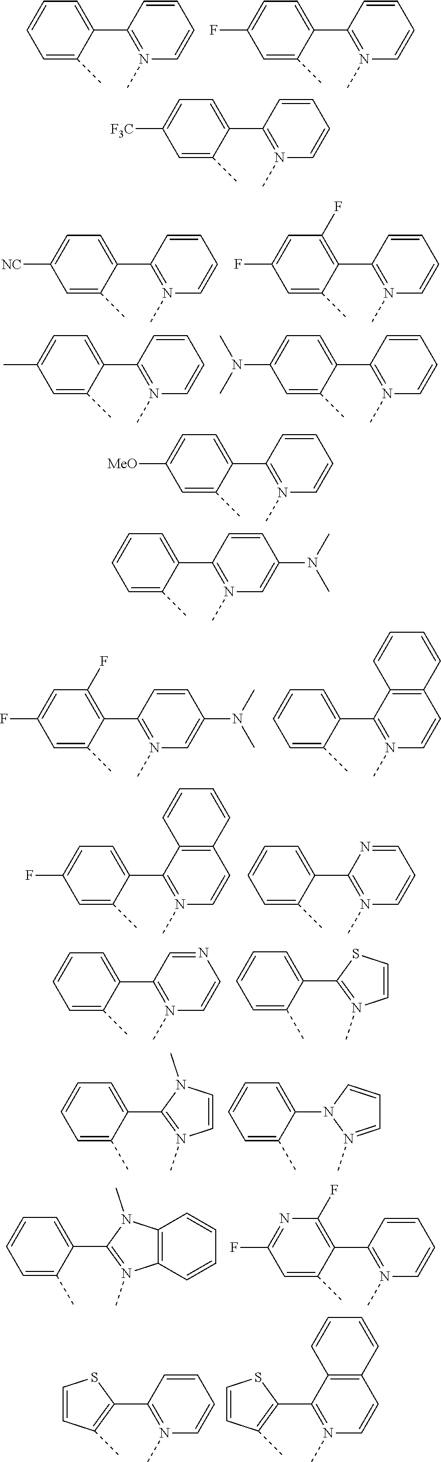

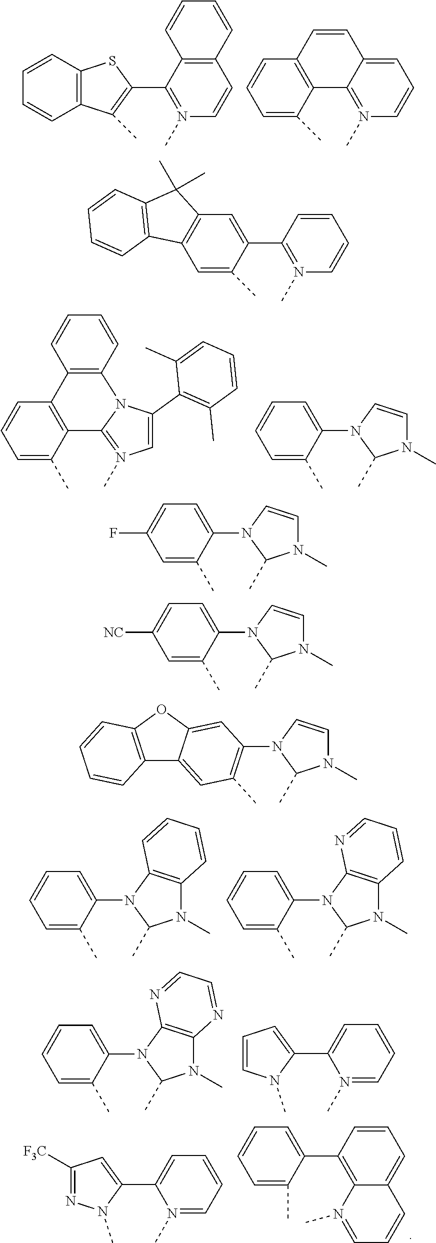

It can be understood that the dotted line in the above group represents the connection site between the group and metal platinum.

Preferably, in formula I,

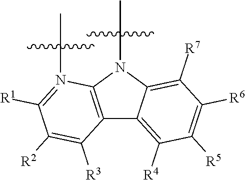

comprises the following structures:

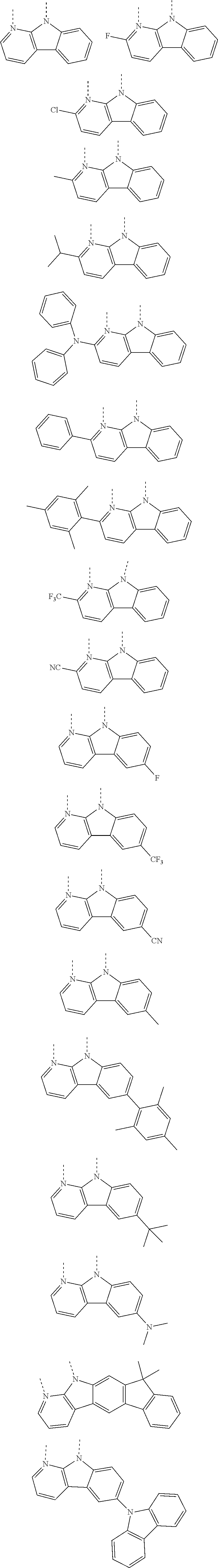

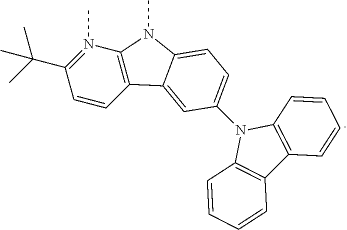

It can be understood that the dotted line in the above group represents the connection site between the group and metal platinum.

Preferably, it has the following structure:

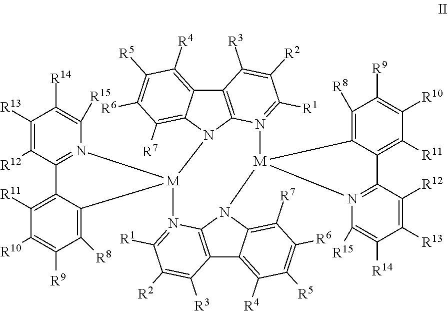

wherein, M is platinum metal;
R¹ to R¹⁵ are the same or different and are each independently selected from hydrogen, deuterium, a heteroatom-containing substituent, a C₁-C₄₀ alkyl, a C₁-C₄₀ alkoxy, a C₂-C₄₀ alkenyl, a C₂-C₄₀ alkynyl, a C₆-C₄₈ aryl and a C₅-C₄₈ heteroaryl; or
adjacent two of R¹ to R¹⁵ are connected with each other to form a C₃-C₁₀ cycloalkyl, a C₆-C₃₀ aryl or a C₅-C₃₀ heteroaryl.

Preferably, R¹ to R¹⁵ are the same or different and are each independently selected from hydrogen, deuterium, a halogen, a C₁-C₁₀ alkyl, a C₁-C₁₀ alkoxy, and a C₆-C₃₀ aryl;
or adjacent two of R¹ to R¹⁵ are connected with each other to form a C₆-C₃₀ aryl.

Preferably, the halogen is selected from fluorine, chlorine, bromine and iodine;
the C₁-C₁₀ alkyl is selected from methyl, ethyl, n-propyl, isopropyl, n-butyl, isobutyl, sec-butyl and tert-butyl;
the C₁-C₁₀ alkoxy is selected from methoxy and ethoxy; and
the C₆-C₃₀ aryl is selected from phenyl, naphthyl and anthryl.

Preferably, the binuclear metal platinum complex comprises the following structures:

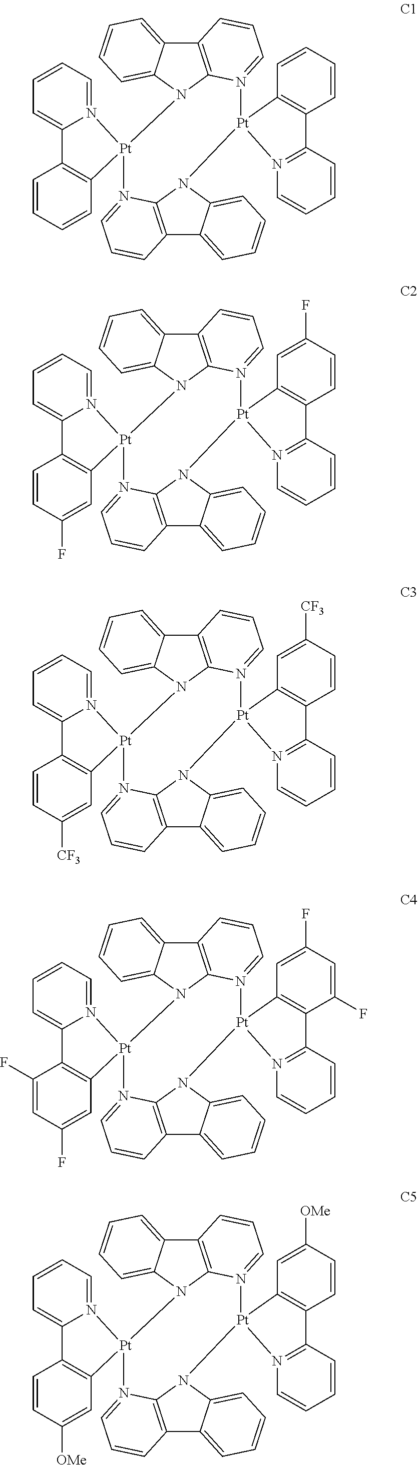

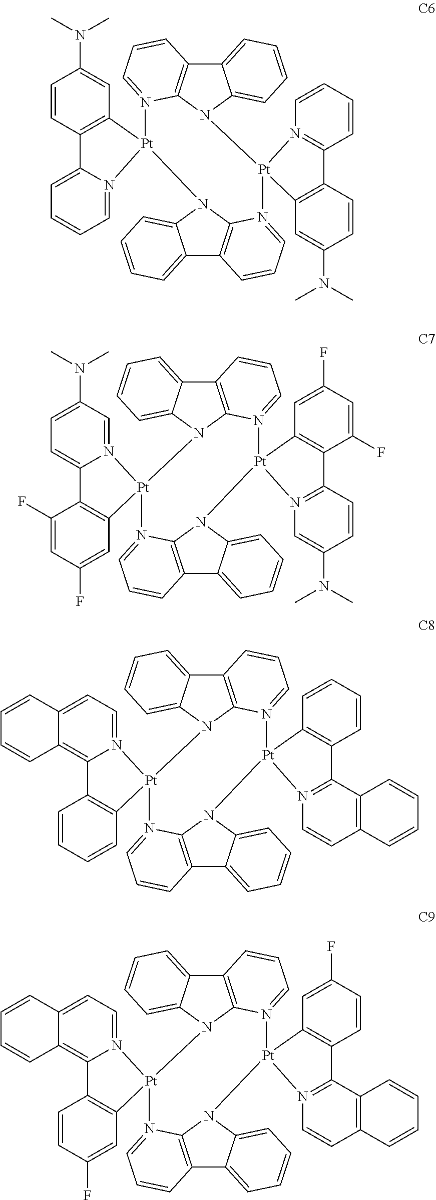

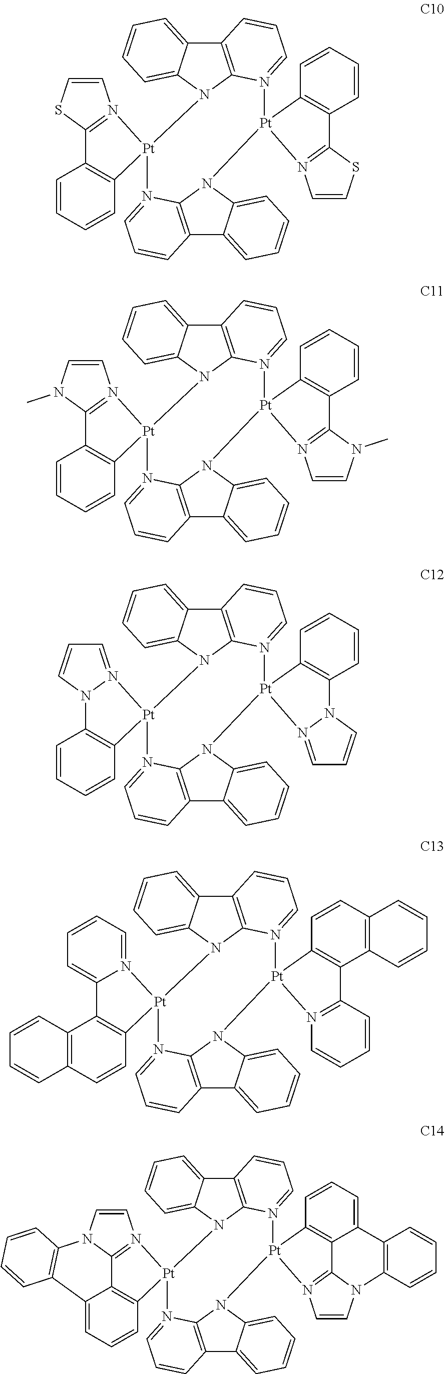

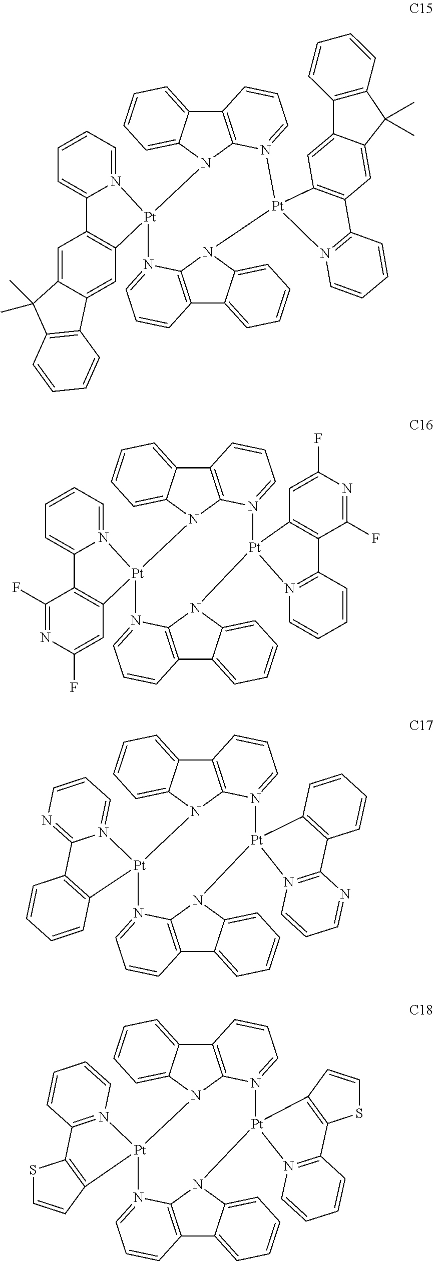

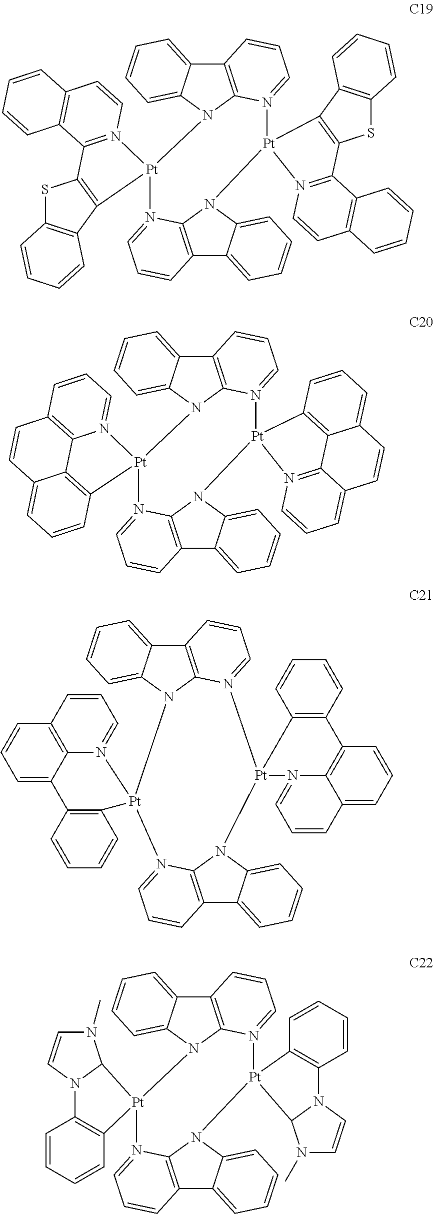

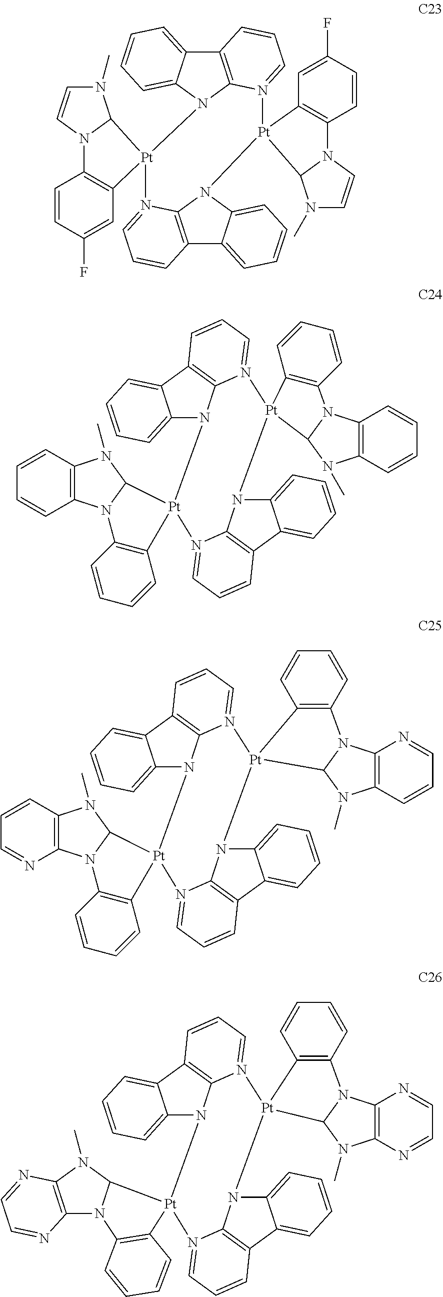

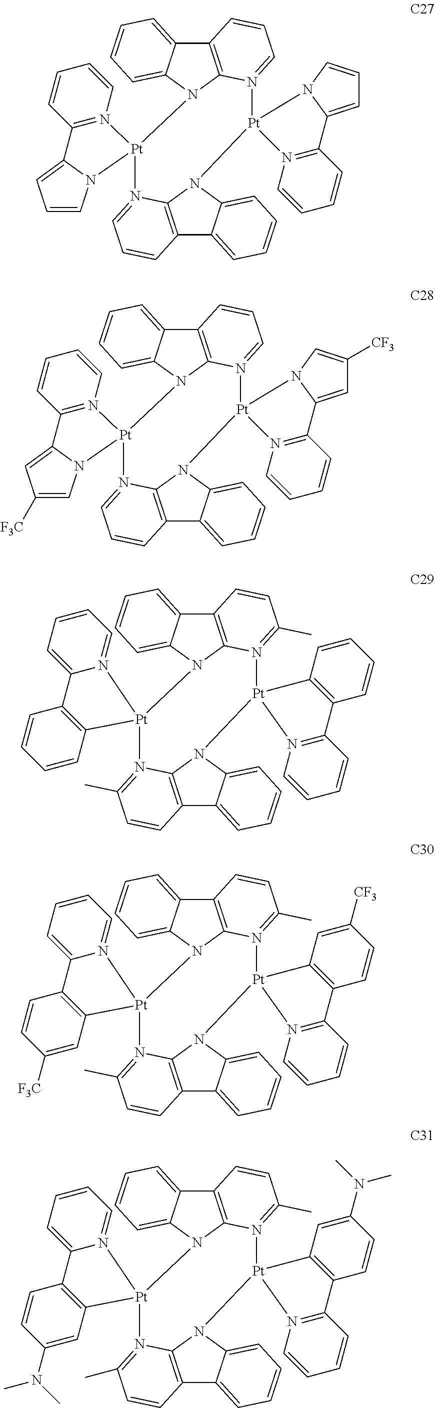

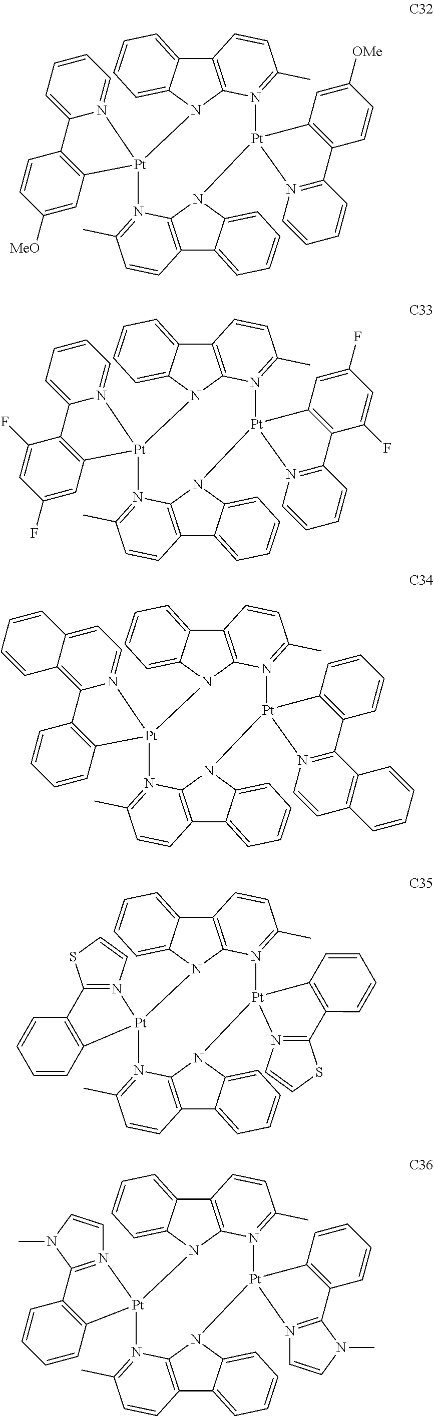

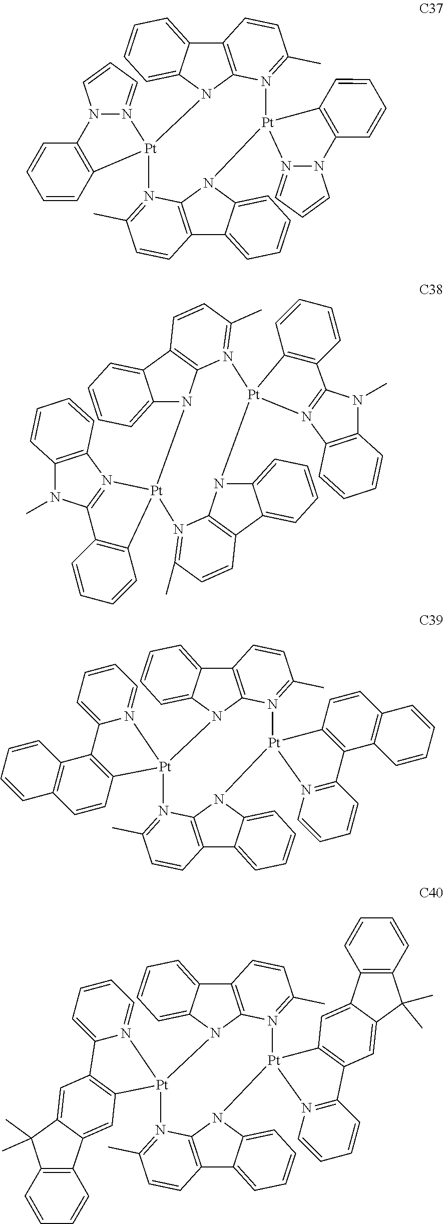

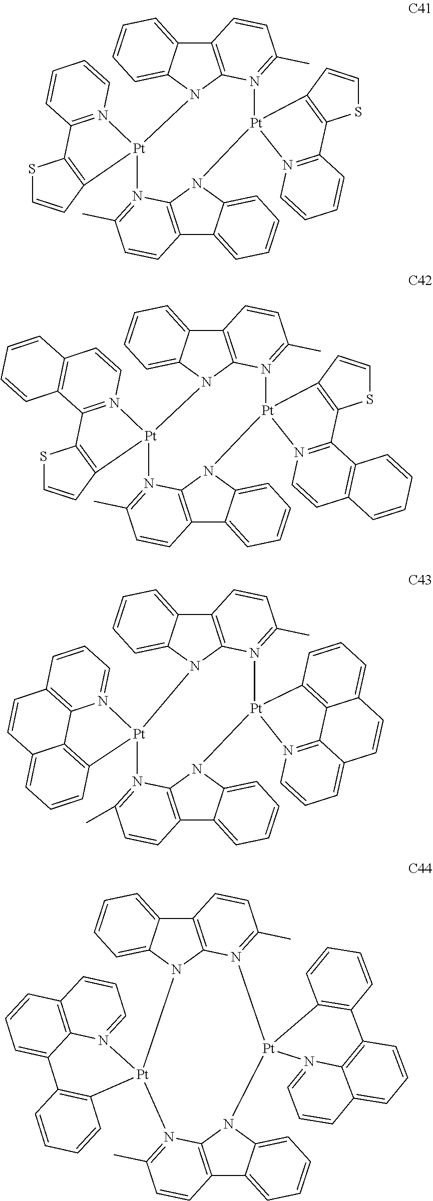

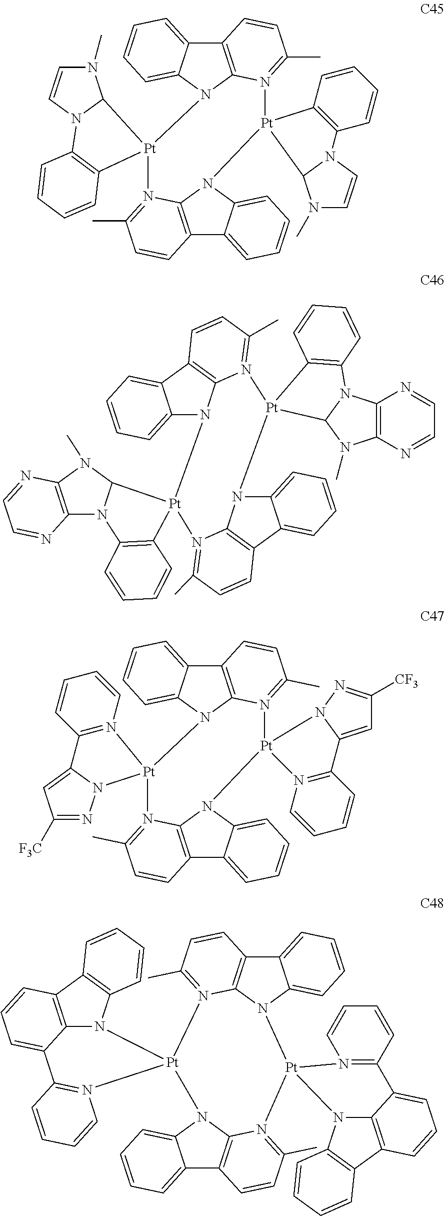

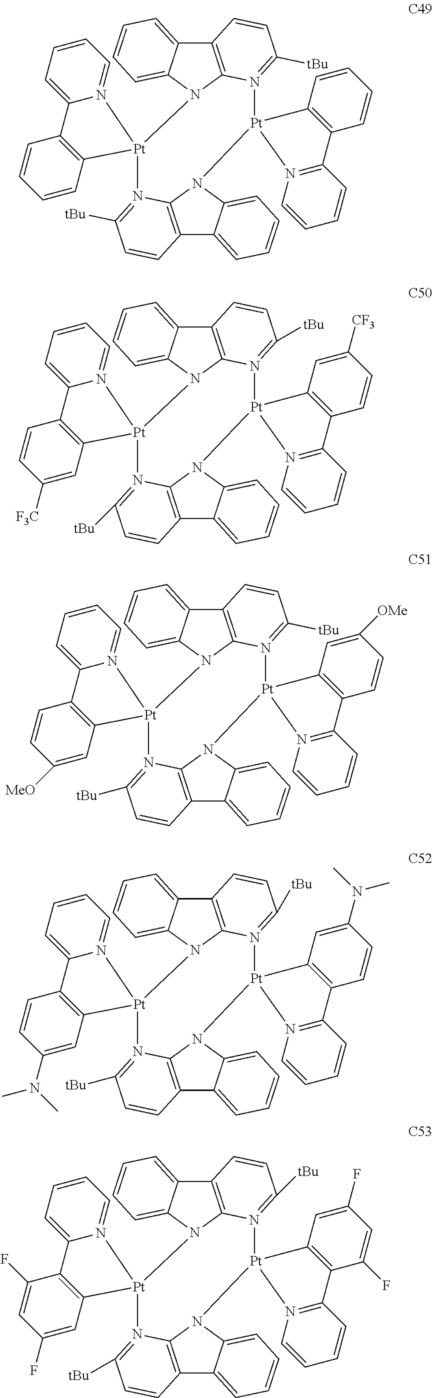

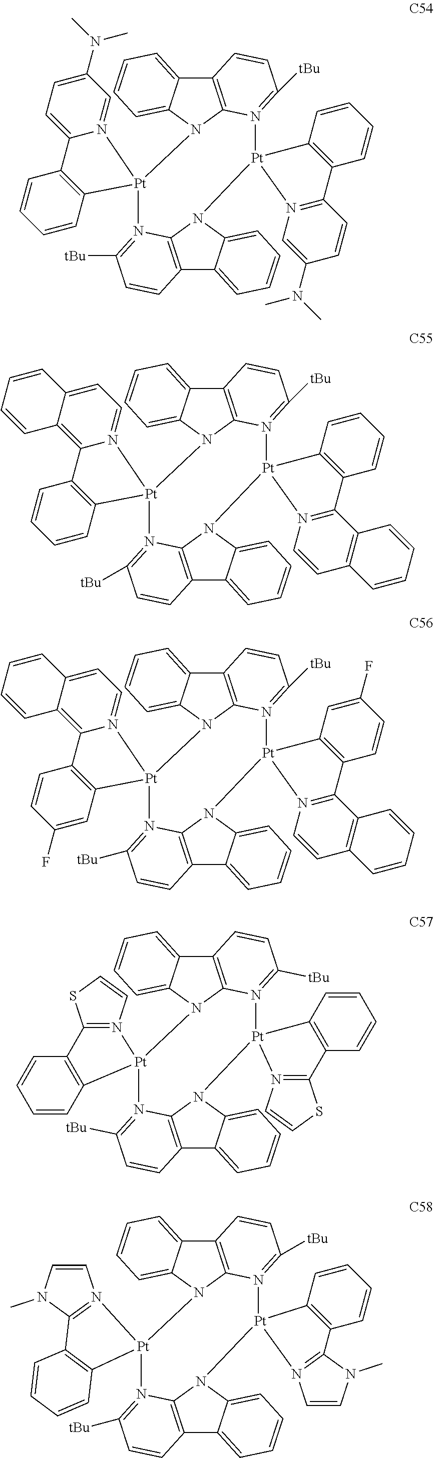

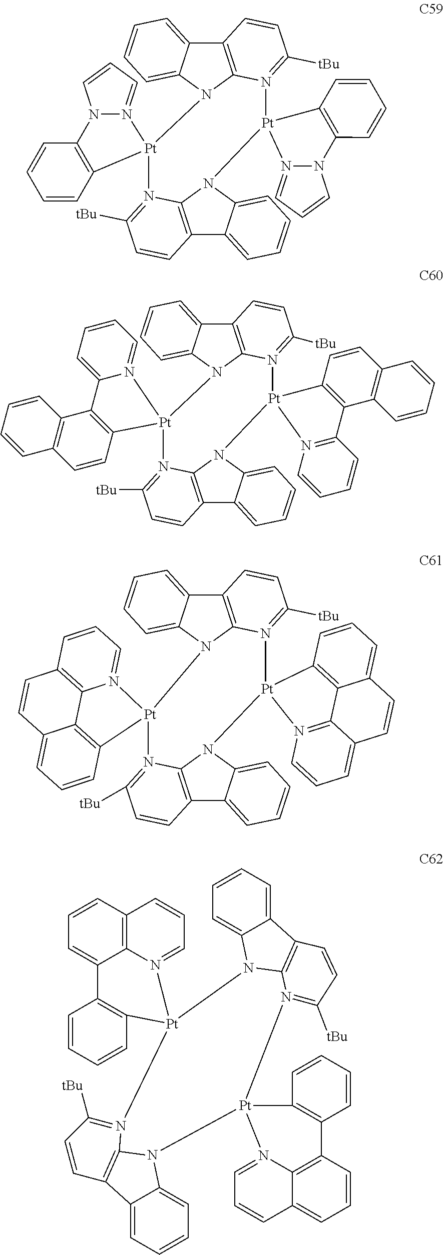

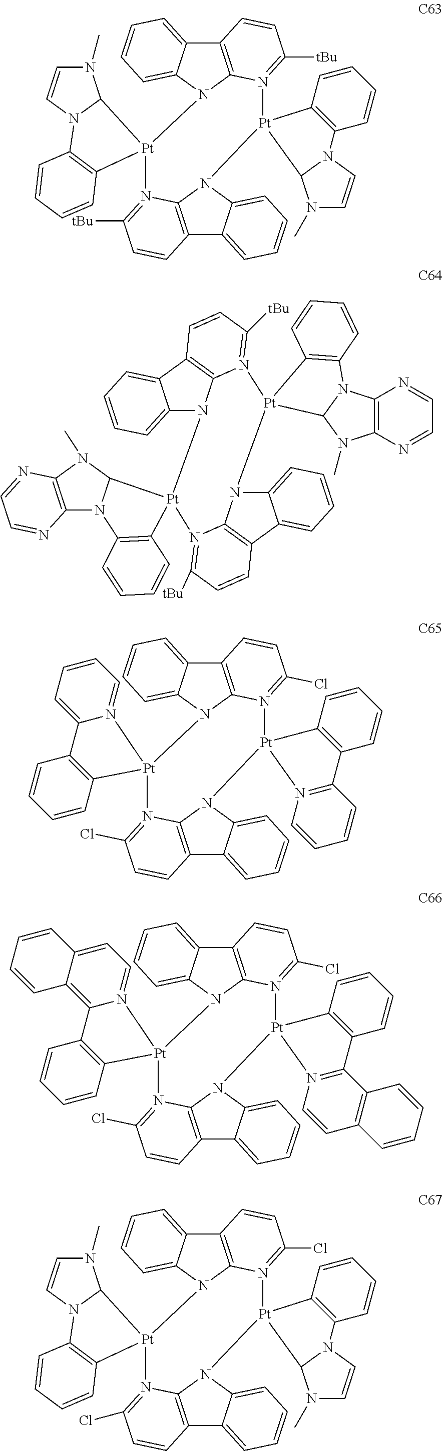

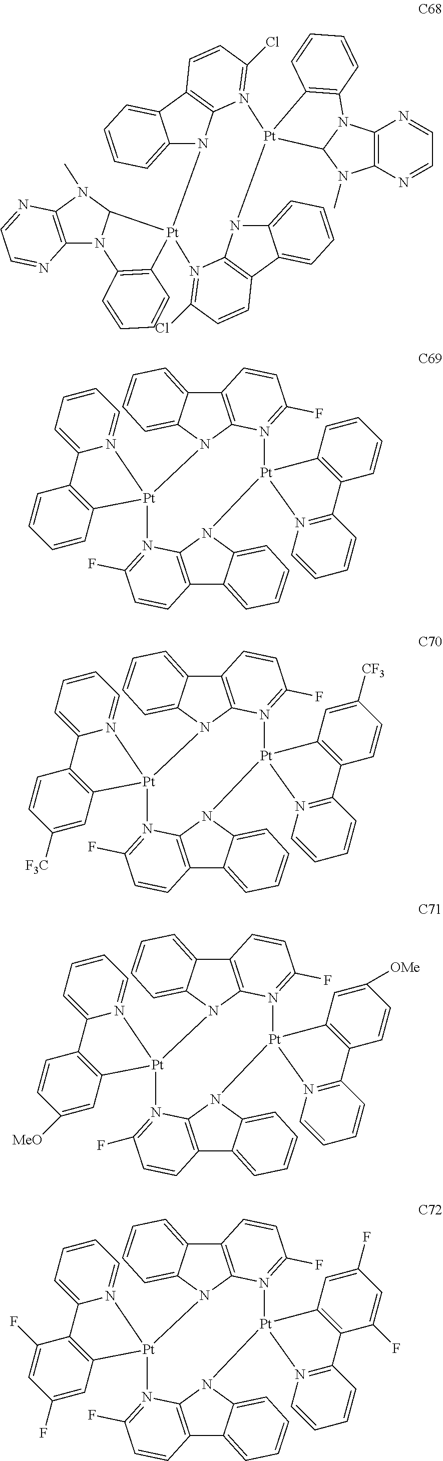

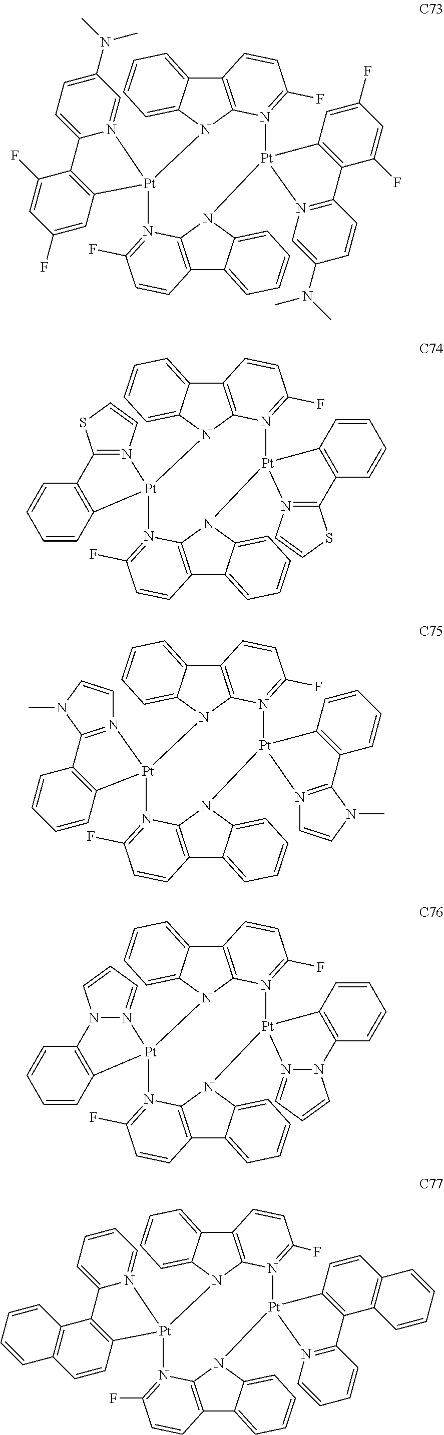

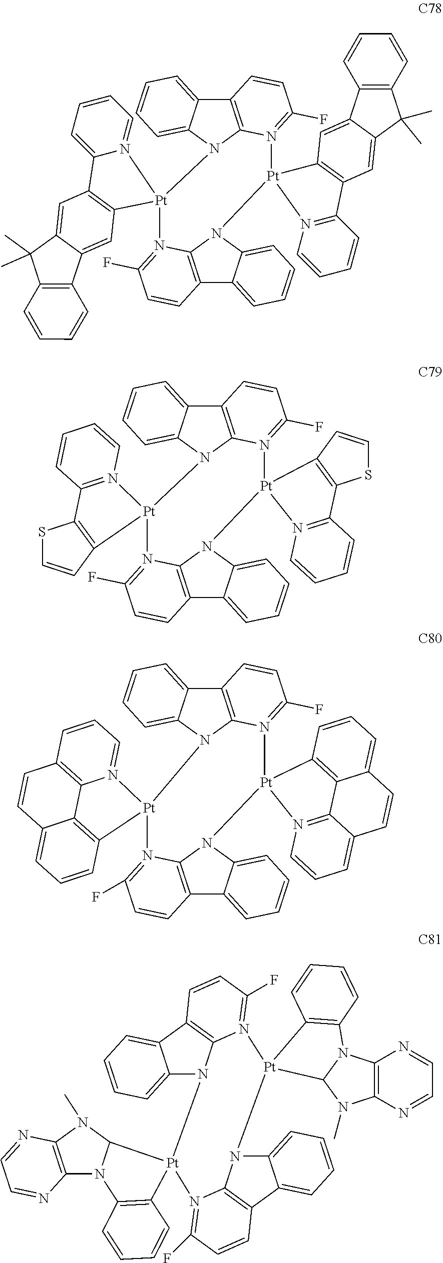

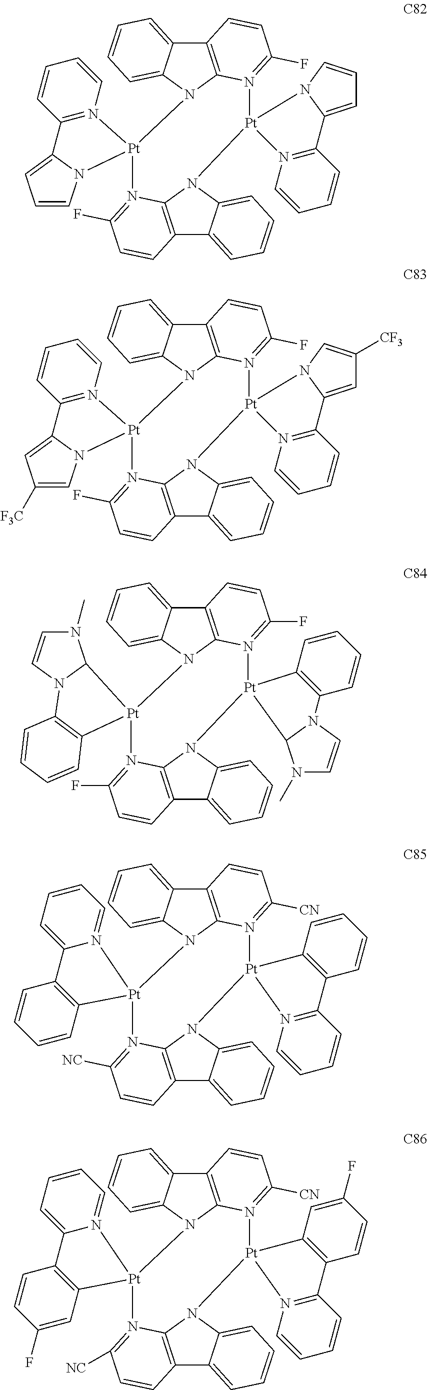

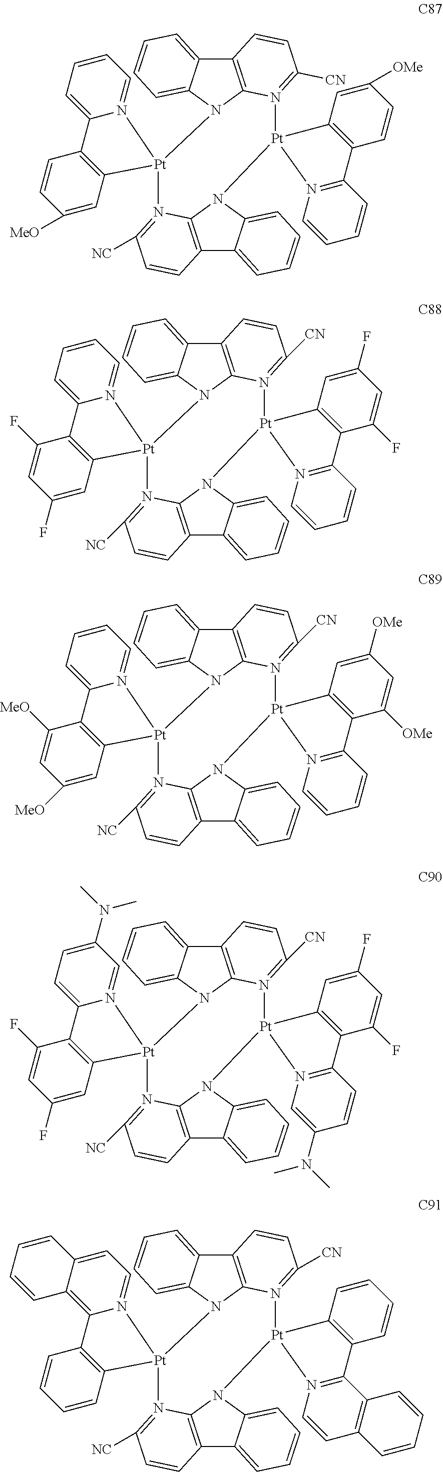

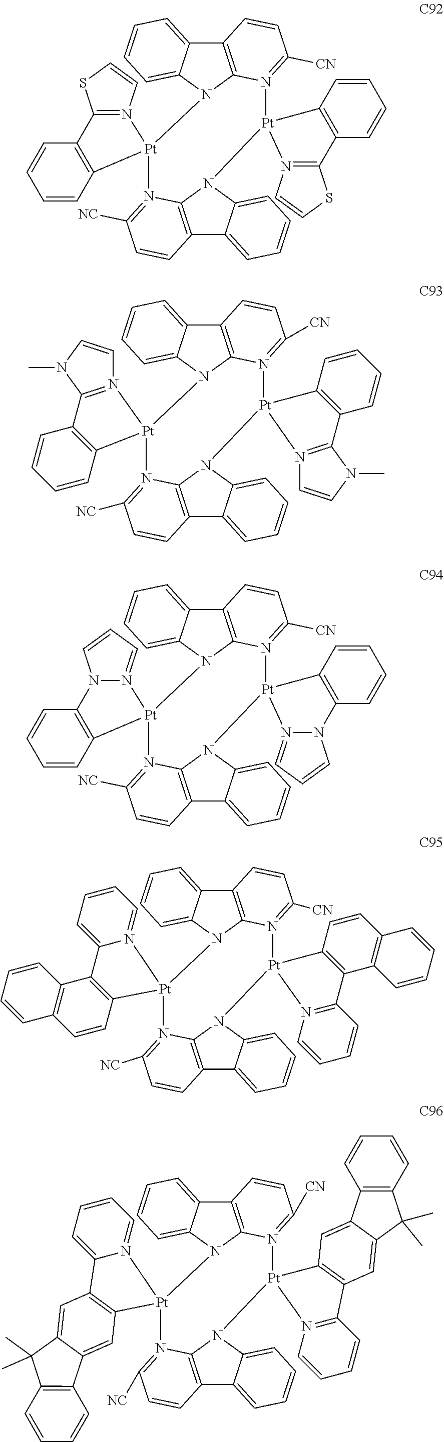

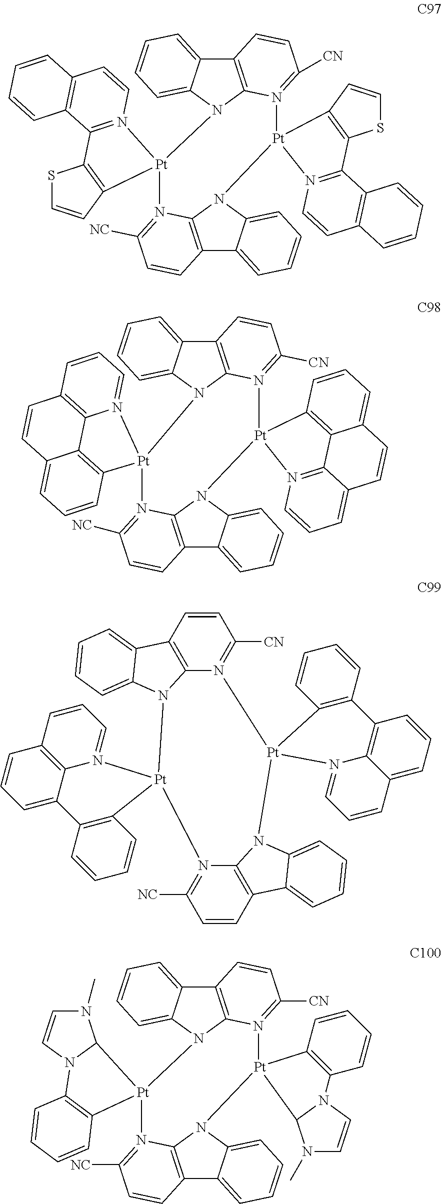

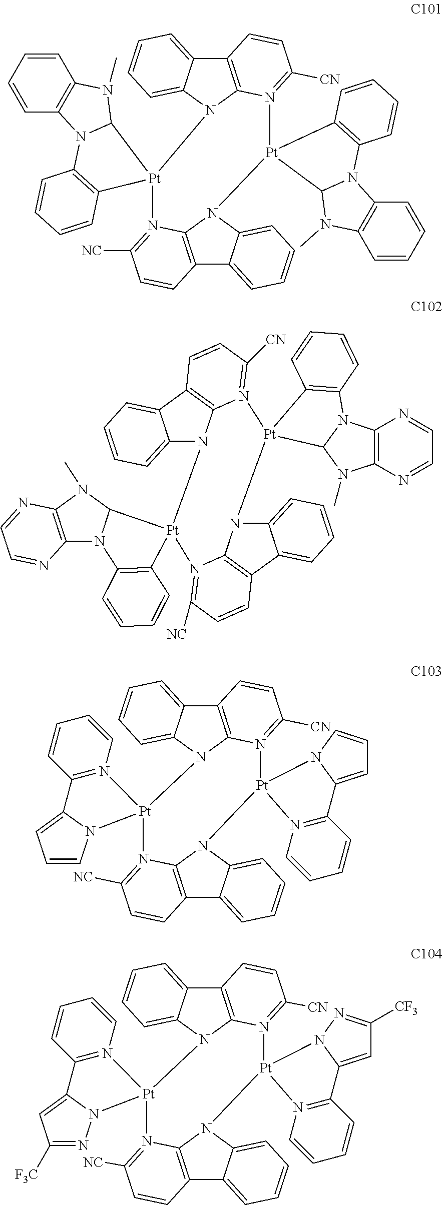

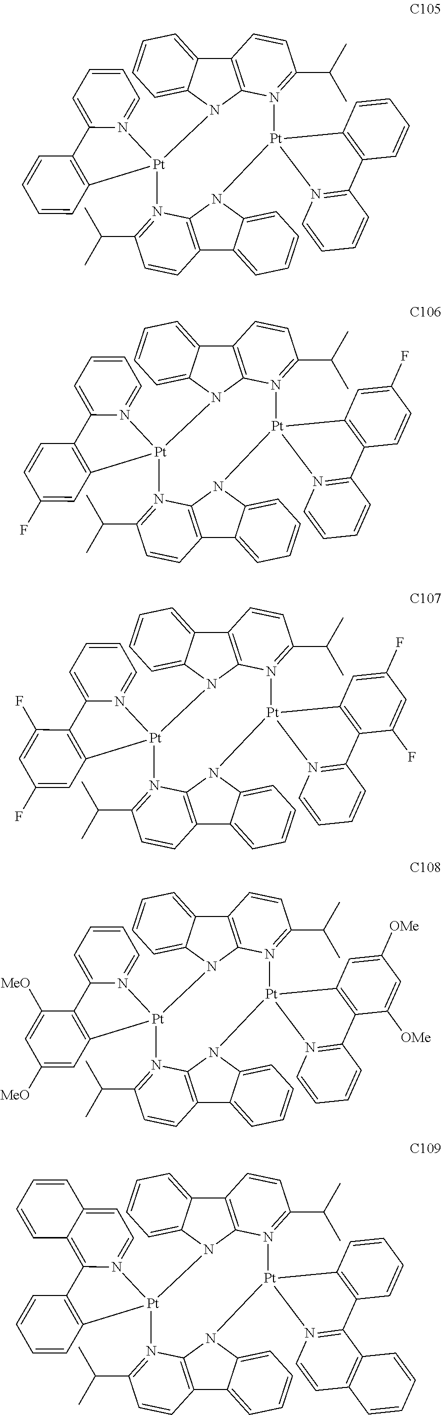

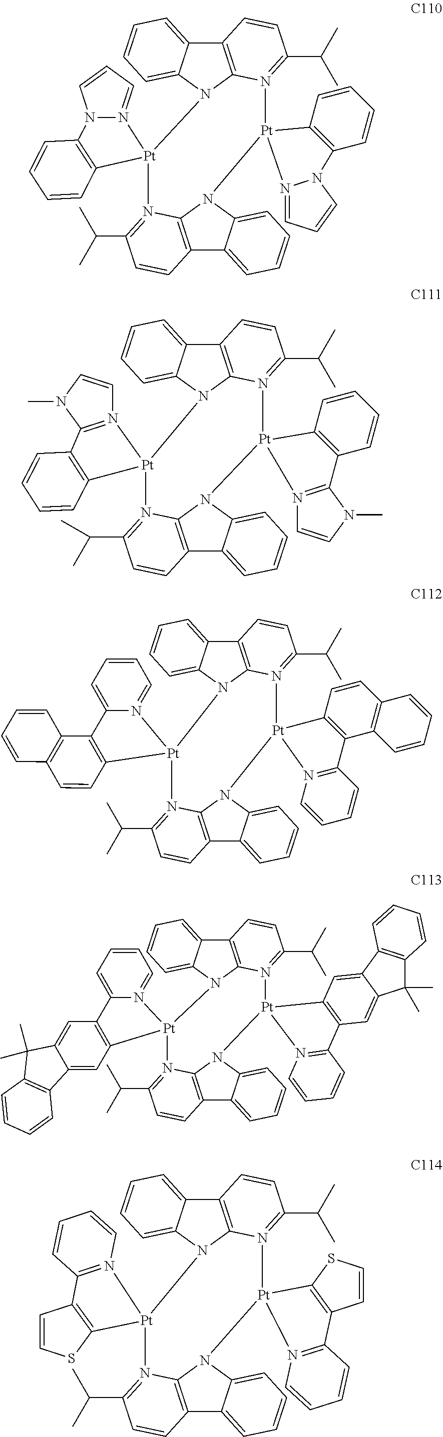

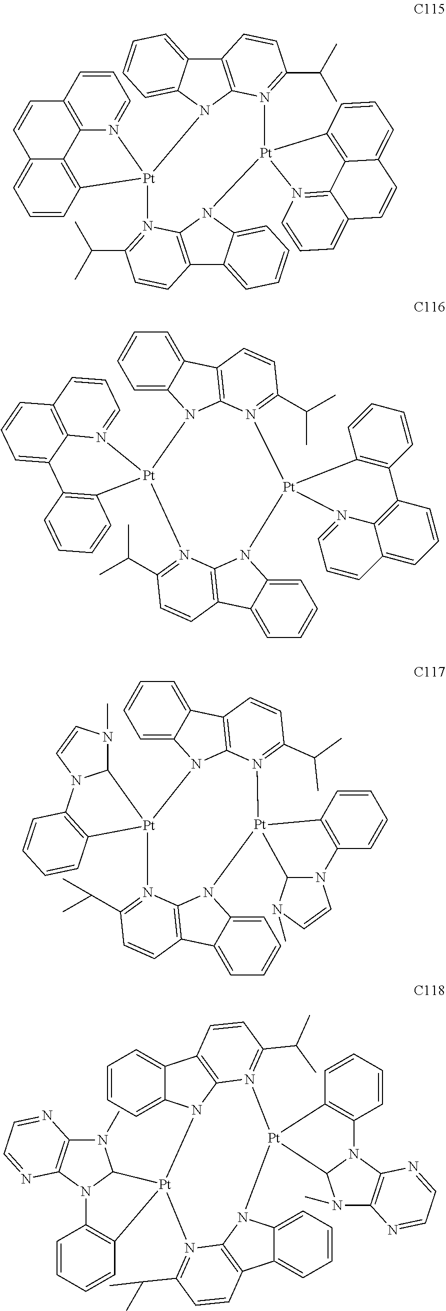

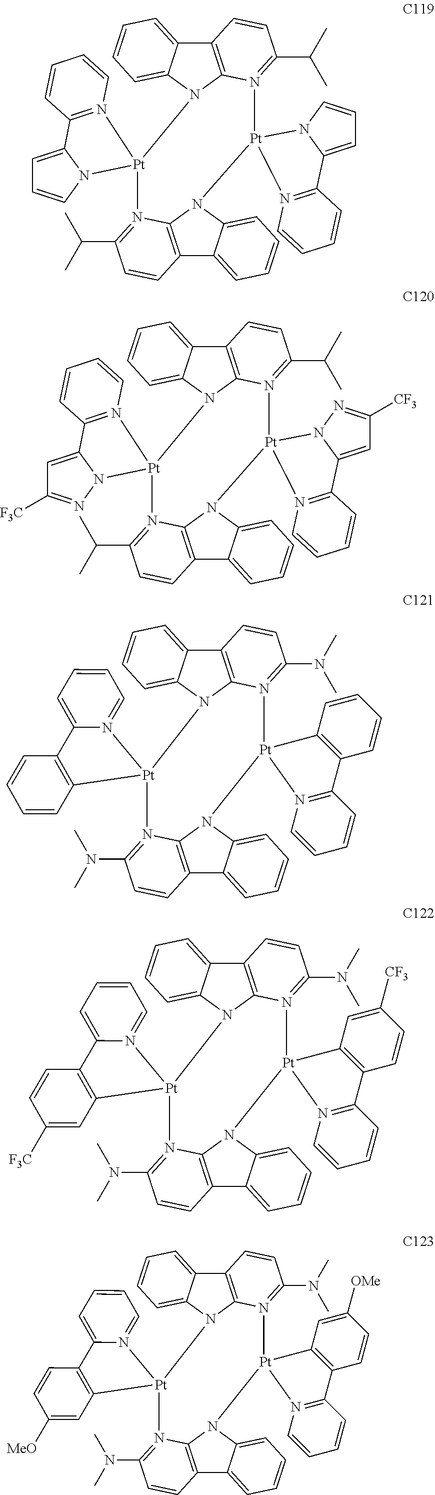

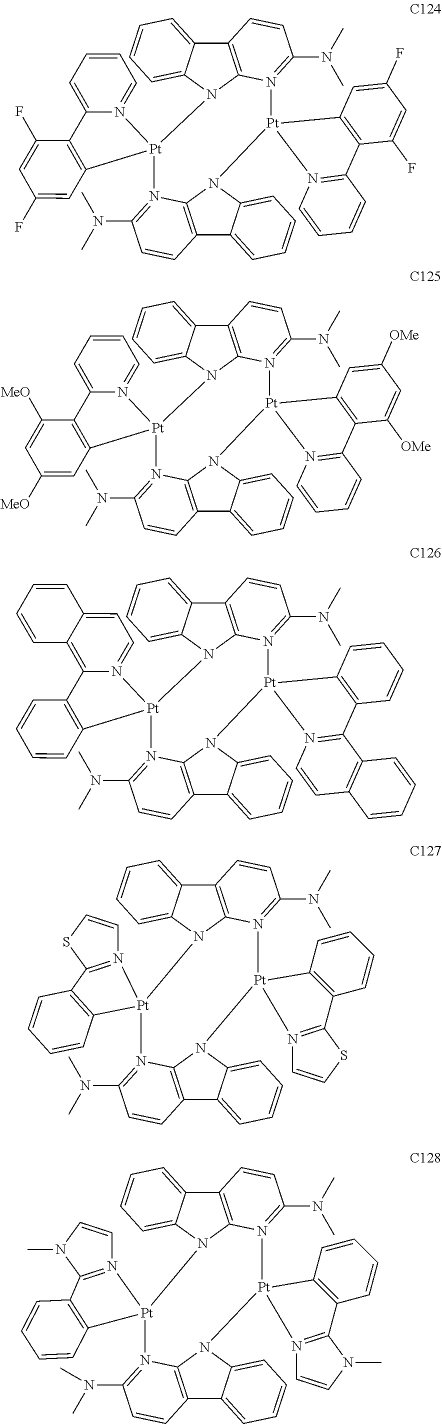

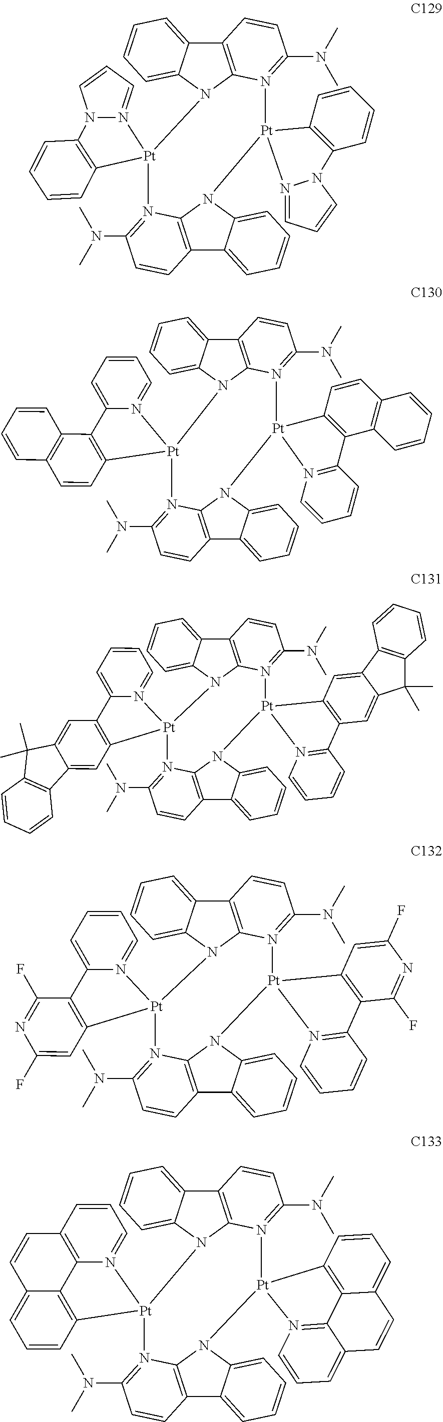

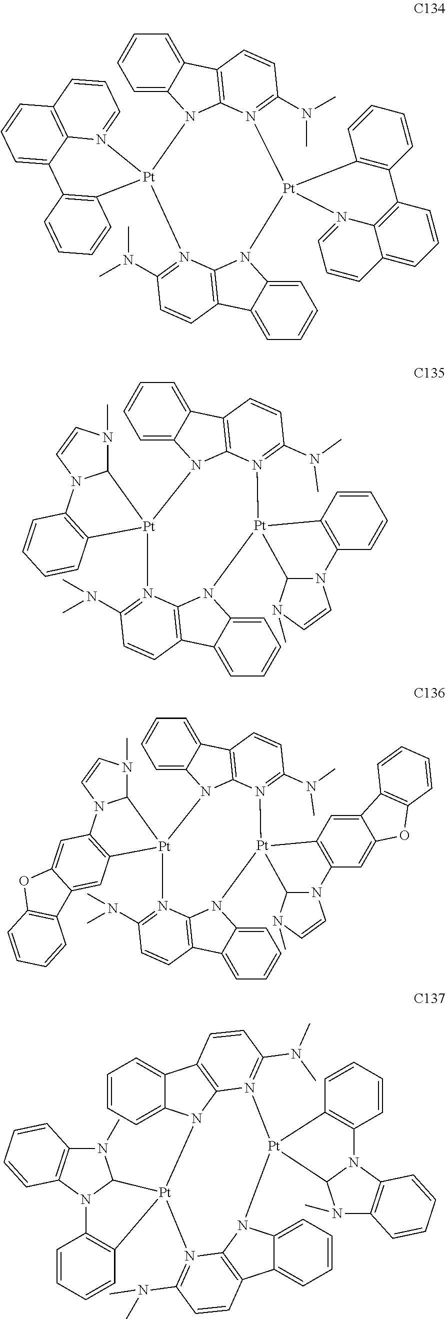

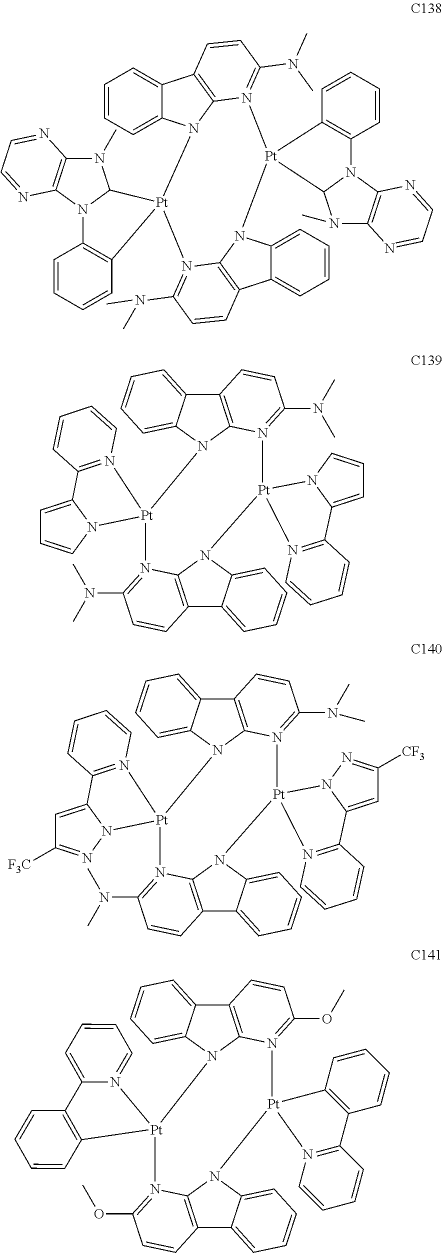

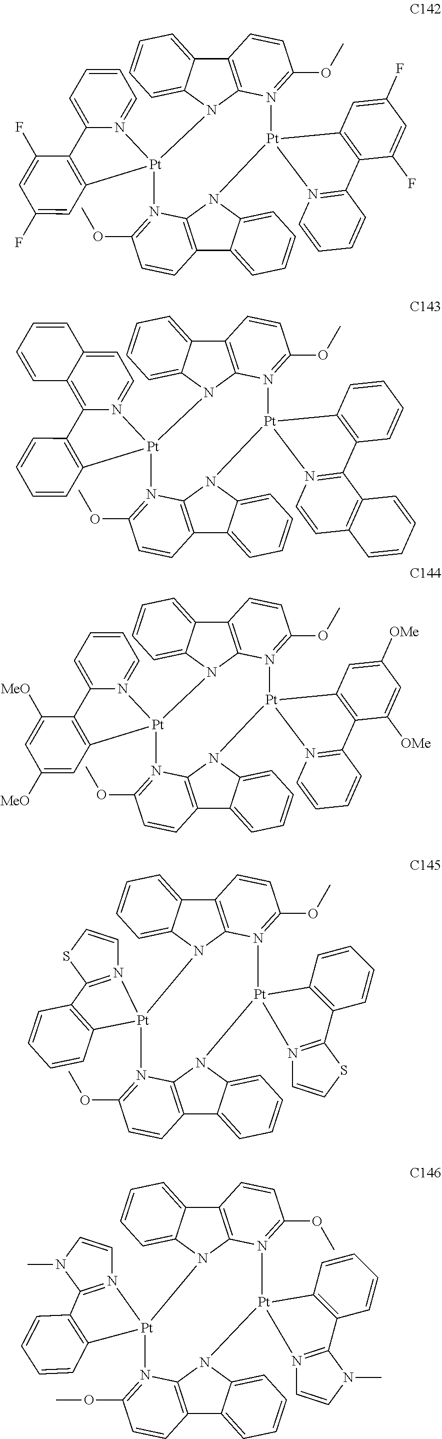

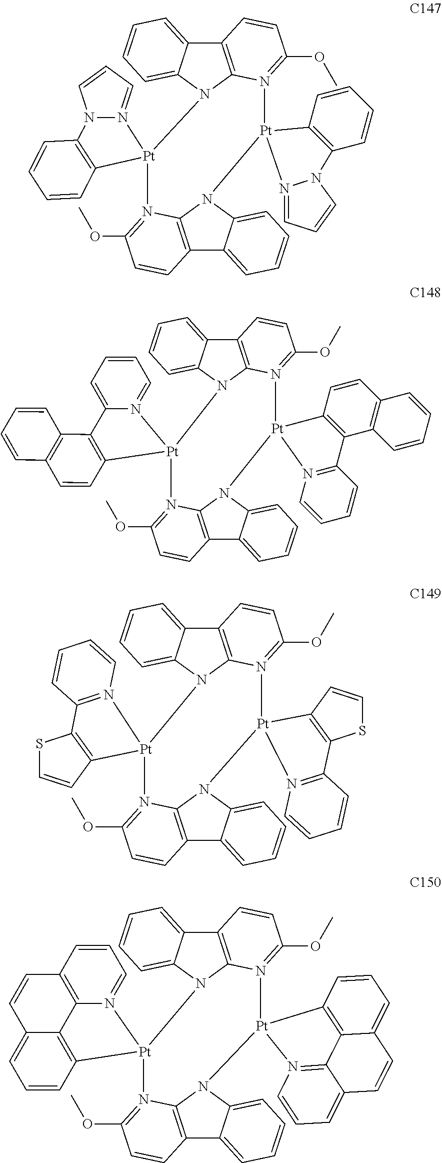

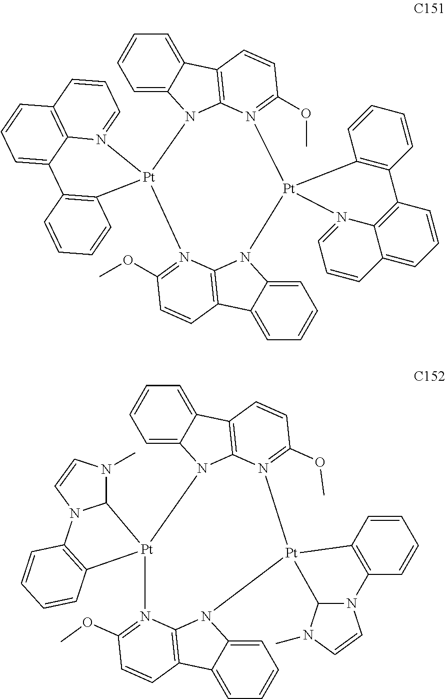

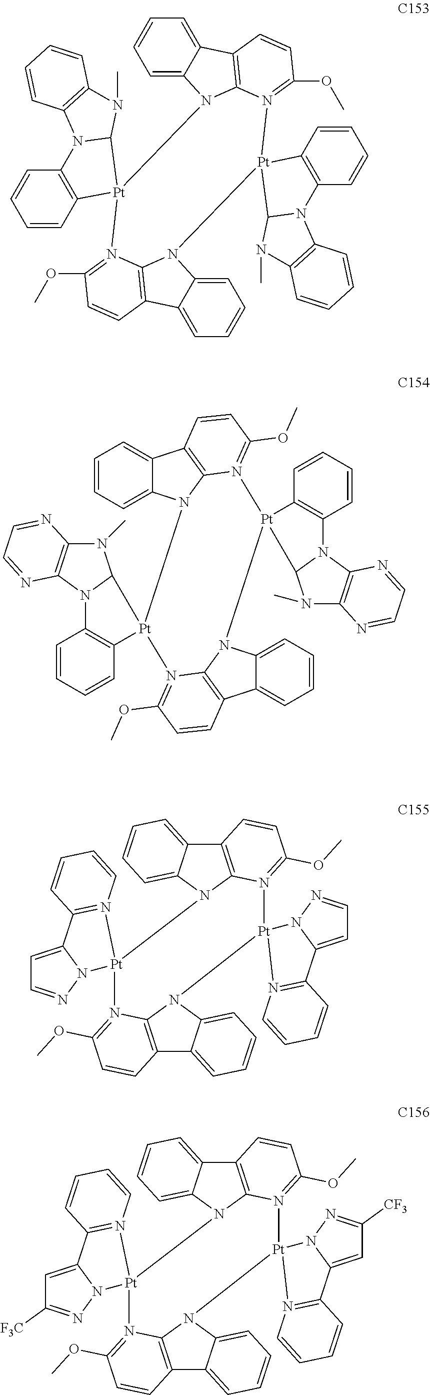

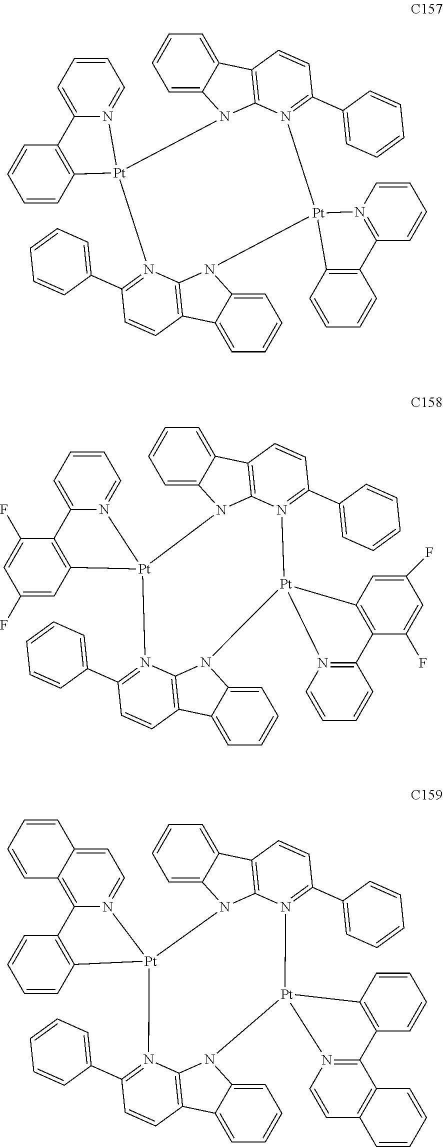

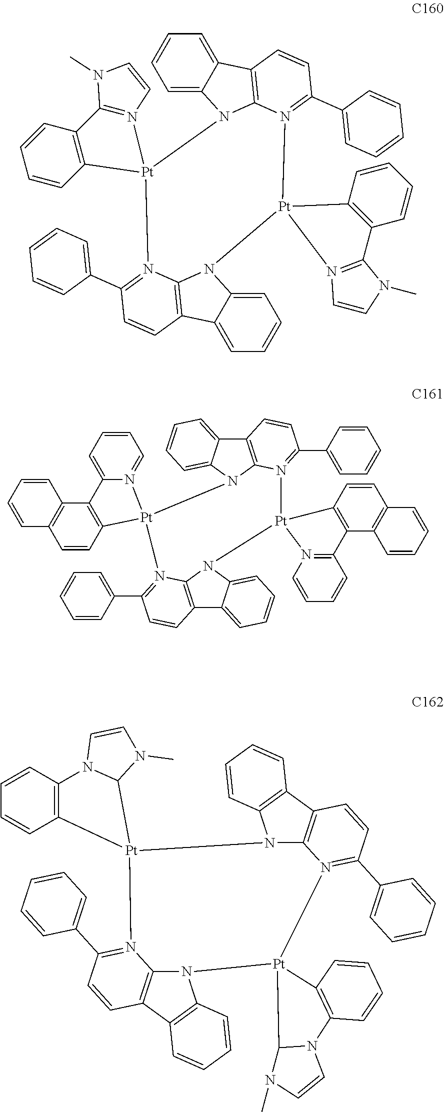

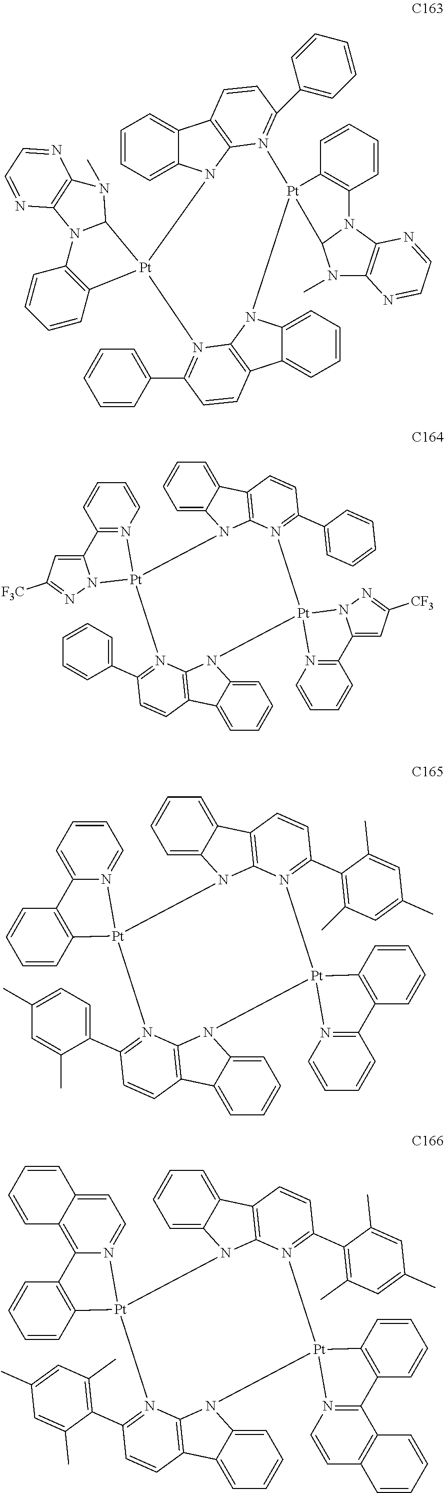

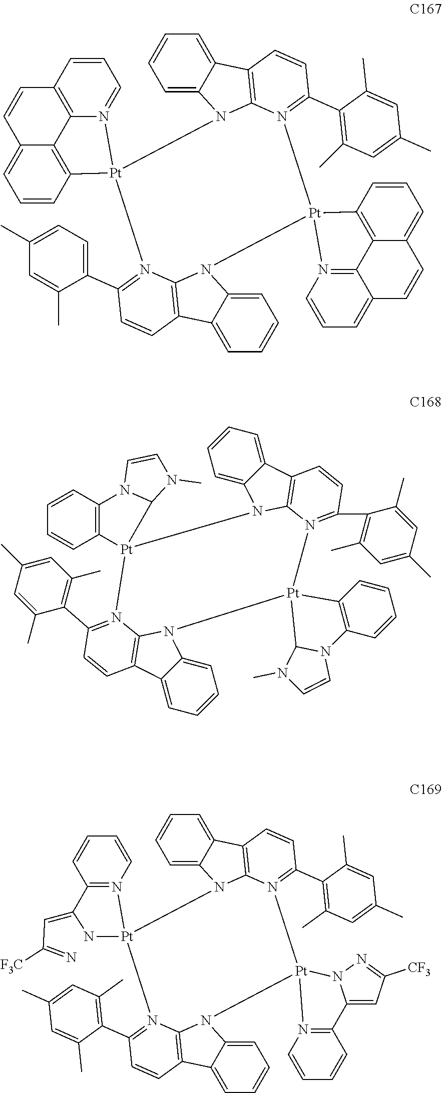

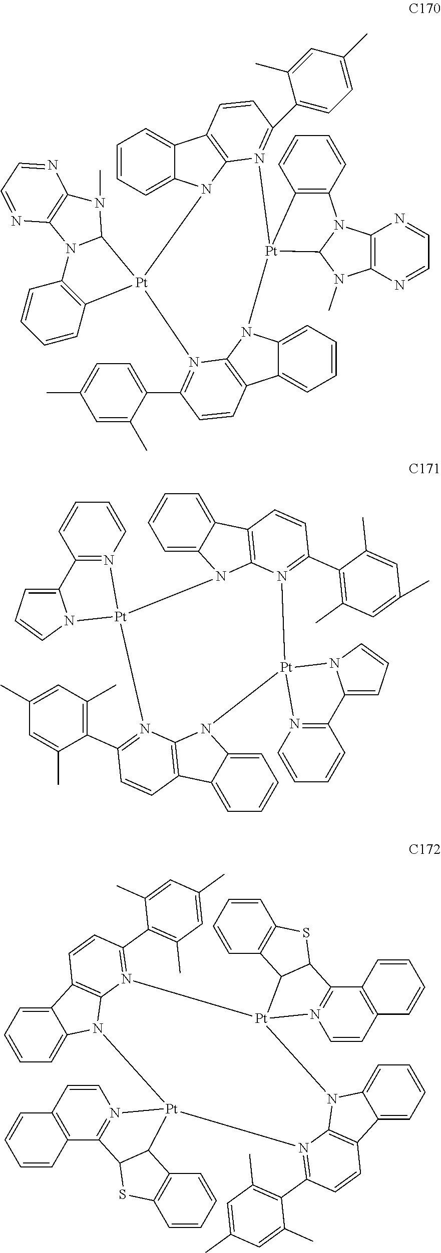

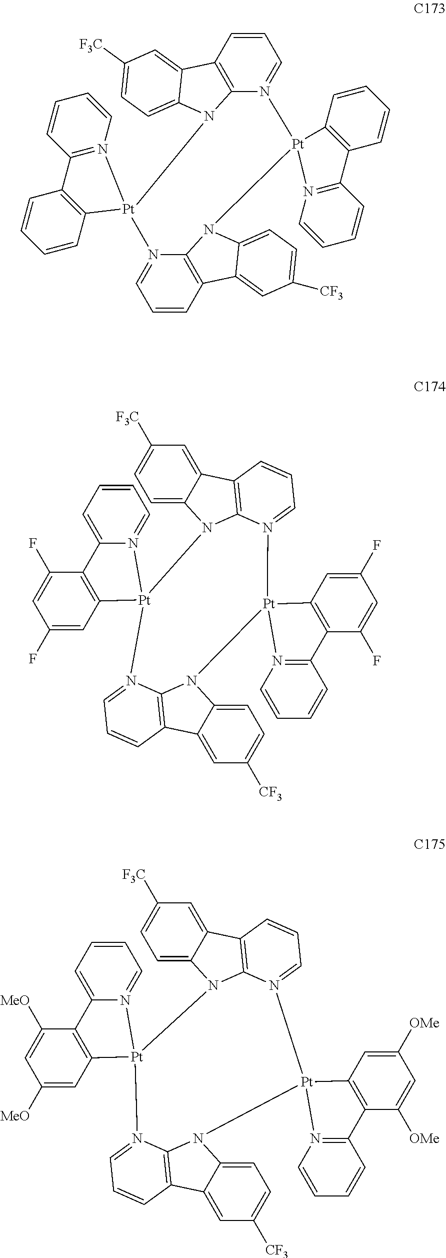

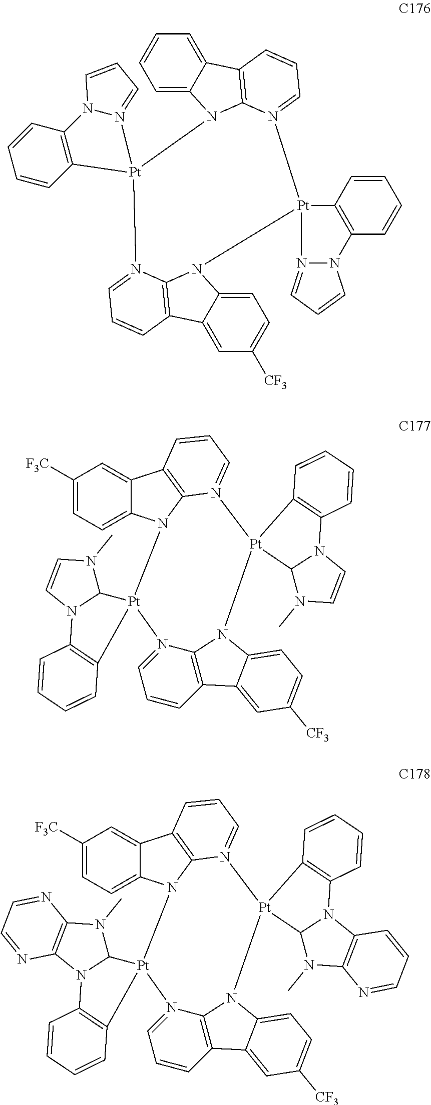

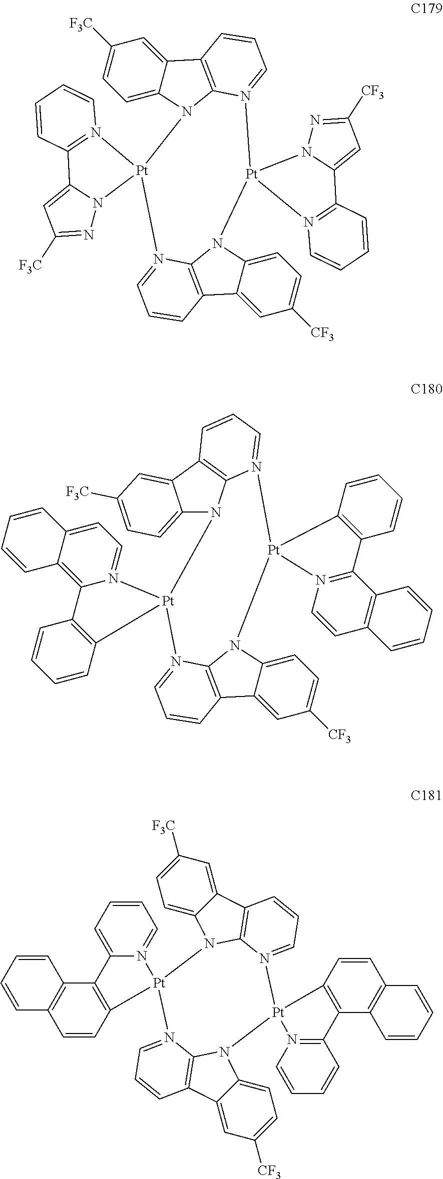

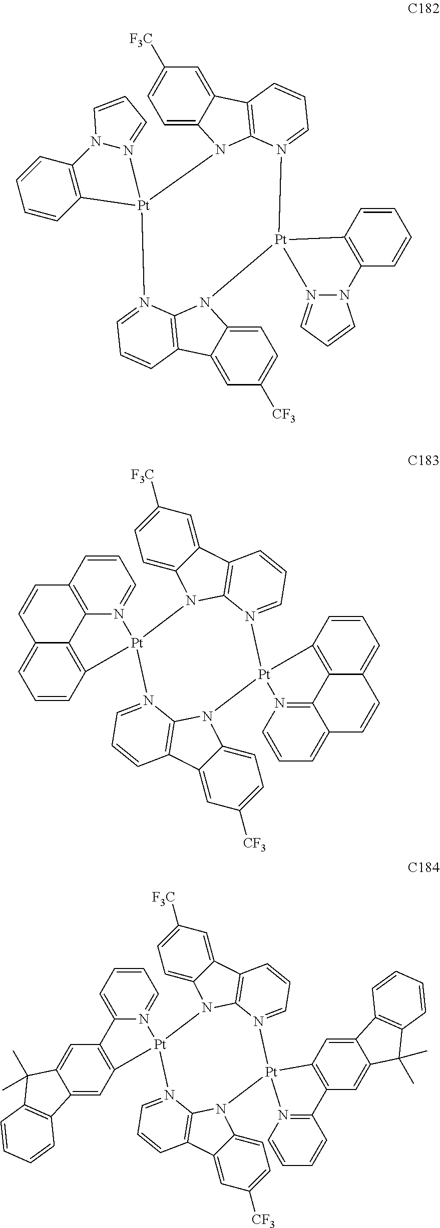

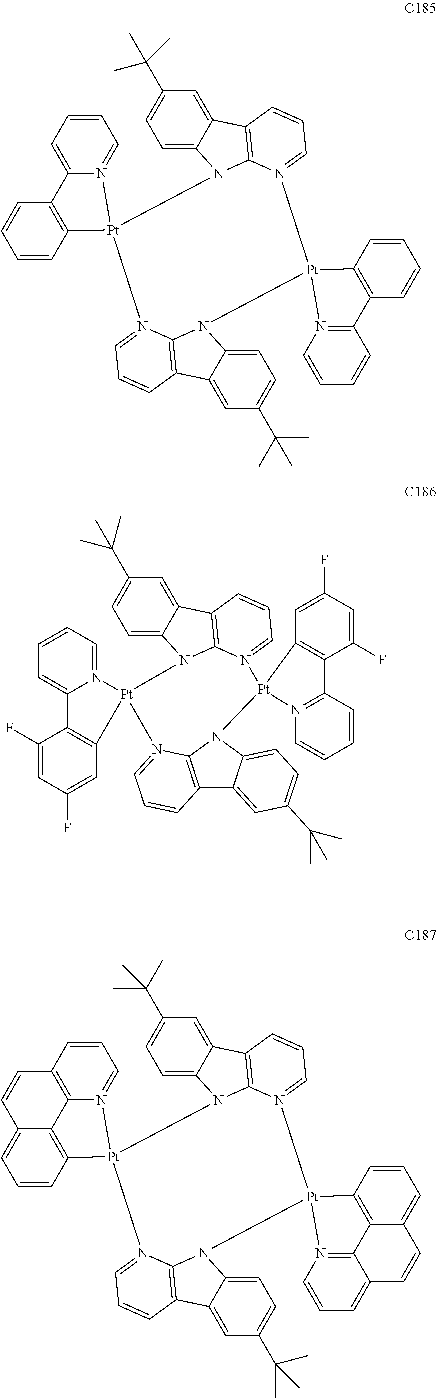

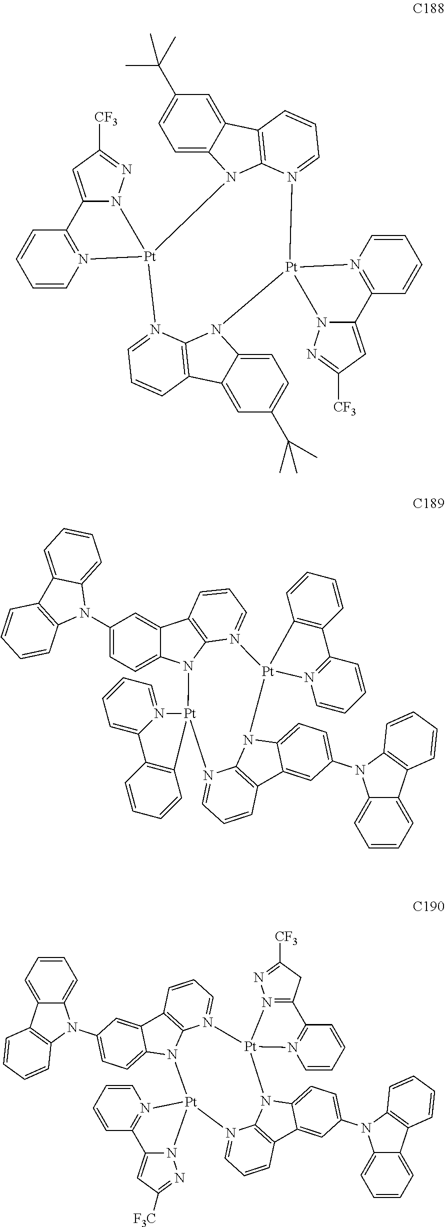

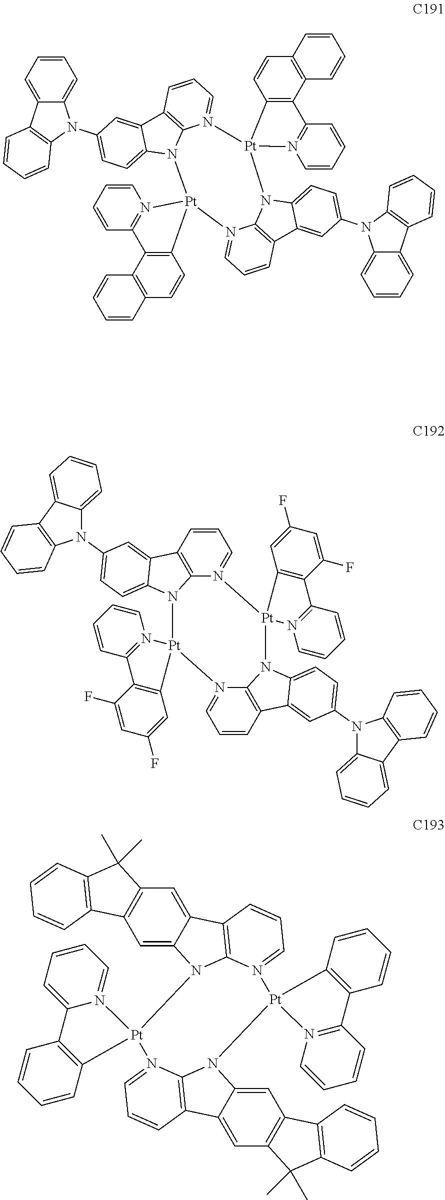

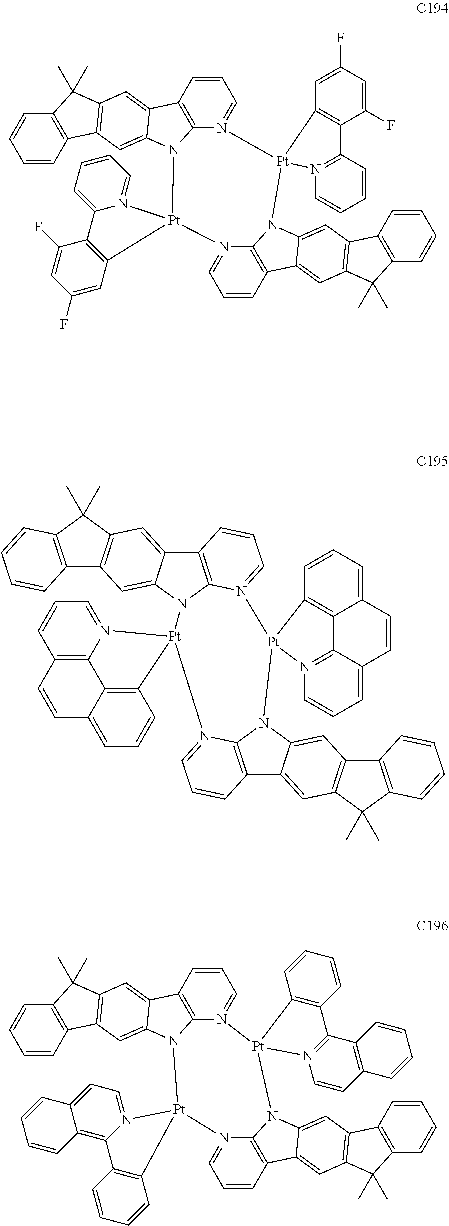

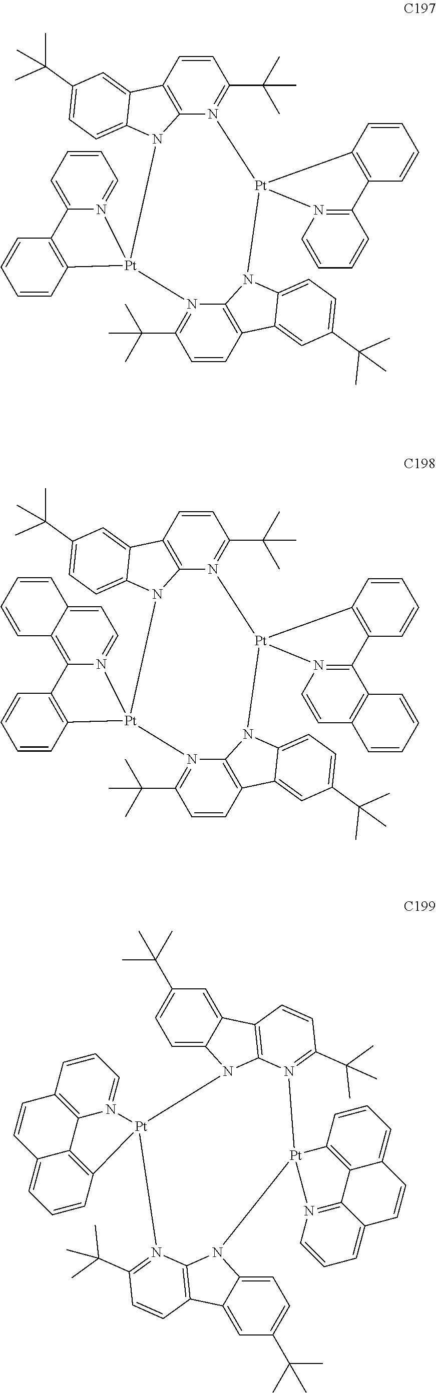

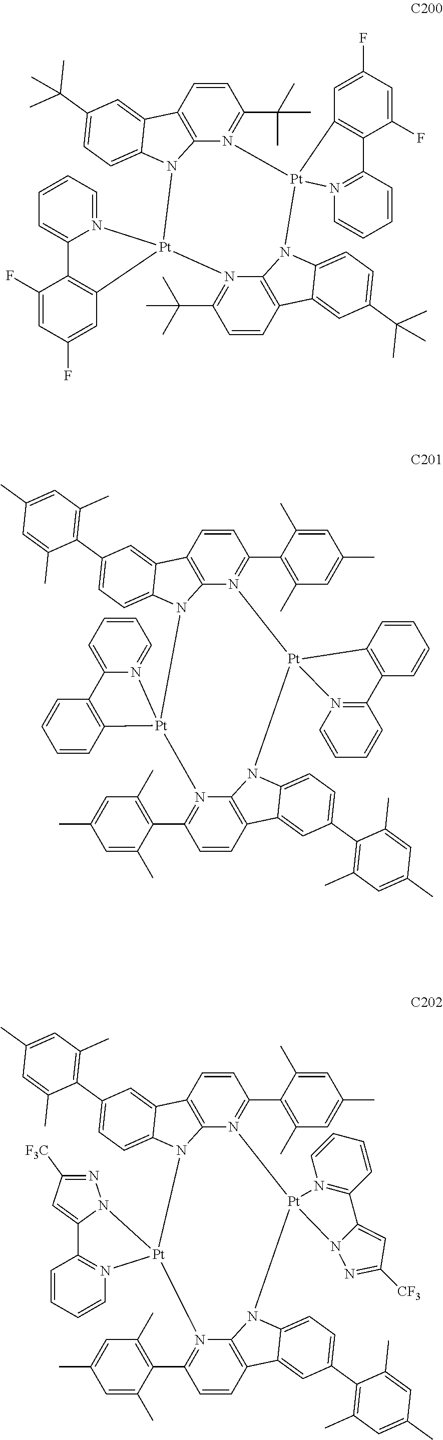

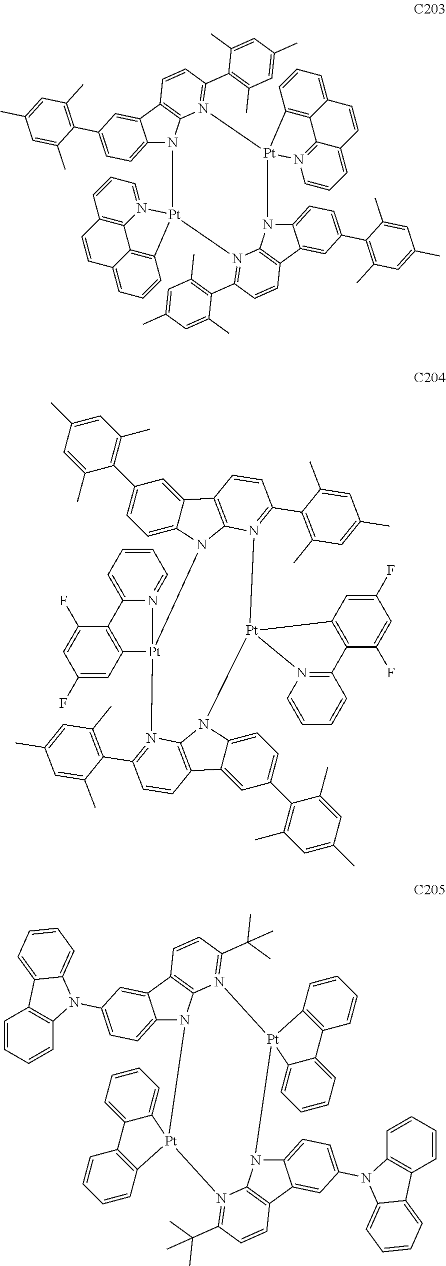

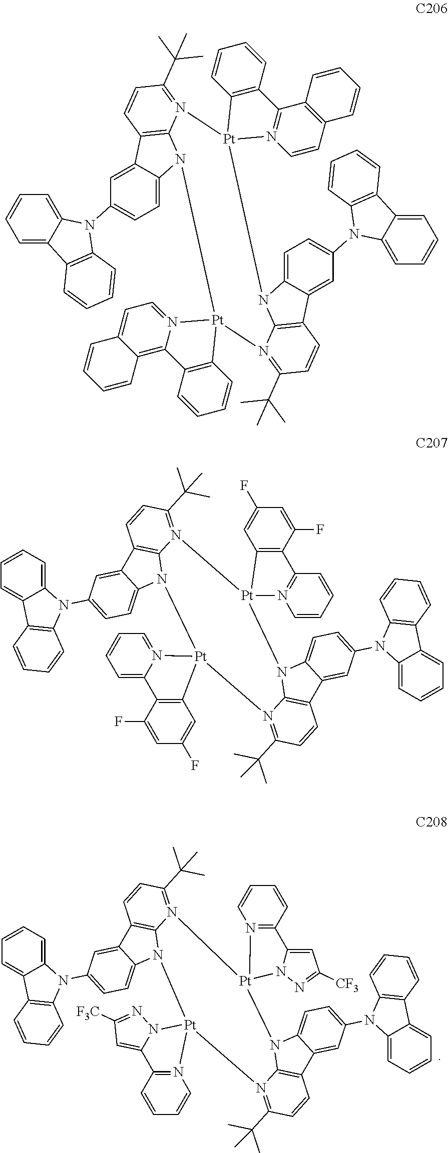

The present application also provides a method for preparing the metal complex described above, comprising the following steps:
firstly, the corresponding chlorine-bridged platinum dimer (abbreviated as [Pt(L_{AB})(μ-Cl)]₂) is prepared by reacting bidentate chelating ligand L_{AB} with potassium tetrachloroplatinate, followed by ligand exchange reaction under the action of alkali, to obtain the corresponding general formula complex.

The synthetic route of the compound described in the present application is as follows:

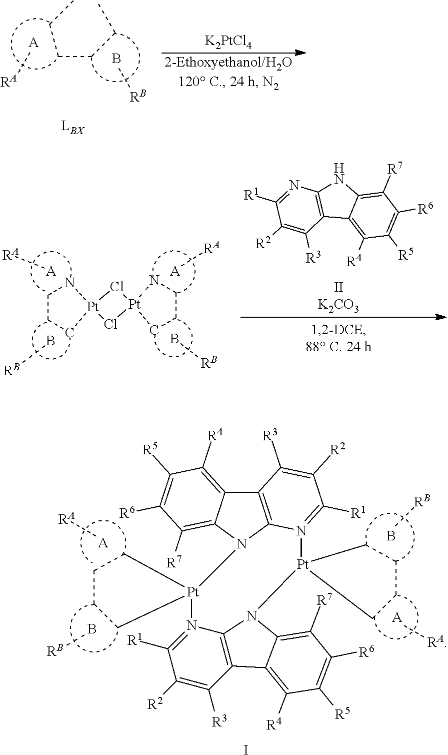

The present application also provides an organic electroluminescent device, and the organic electroluminescent device comprises a first electrode, a second electrode and a light emitting layer positioned between the first electrode and the second electrode, wherein the light emitting layer comprises any one of, or a combination of at least two of, the binuclear metal platinum complex above.

Preferably, the light emitting layer comprises the binuclear metal platinum complex above and an organic functional material, wherein the binuclear metal platinum complex accounts for 0.01%-100% by mass and the organic functional material accounts for 0-99.9% by mass.

It should be noted that the application of the metal complex described in the present application is not limited to the composition of the device, and the film thickness or composition material of each layer can be appropriately modified according to the basic physical properties of the specific compound structure of the present application.

The preparation method of the organic device described in the present application is a conventional method in the art. Optionally, the preparation of the organic electroluminescent device includes the following steps: using the glass substrate evaporated and plated with ITO as a transparent support substrate, and sequentially evaporating, plating and forming various organic layers and metal electrodes on the ITO film of the transparent support substrate.

### Beneficial Effects of the Present Application

The binuclear metal platinum complex provided by the present application is a half-lantern type neutral binuclear platinum (II) complex formed by using α-carboline and its derivatives as bridging bidentate ligands, and is a high-efficiency molecular-based luminescence materials, and the key to the design of this type of molecules is to use rigid bridging ligands to limit the platinum-platinum metal distance in the molecule, enhance the metal-metal interaction, and facilitate the radiative transition of the triplet excited state. At the same time, the present application uses a rigid chromophore ligand to enhance the π-π metal interaction in the molecule, and the whole molecule has better rigidity after coordination, which helps to suppress the non-radiative transition of the excited state. The compound based on the strategy of the present application has both high luminous efficiency and short excited state lifetime. In addition, the intramolecular interaction of the compound of the present application can help enhance the metal-ligand interaction, increase the energy barrier for coordination bond dissociation, and improve the thermal stability of the compound. The compounds of the present application can be used to prepare efficient and stable organic luminescent diodes.

The binuclear metal platinum complex provided by the present application has relatively high luminous efficiency, and the highest red light efficiency can exceed 60%. The complex provided by the present application has a short luminous lifetime, the shortest being less than 1 microsecond. The maximum external quantum efficiency of the red light-emitting device prepared based on it exceeds 23%, the device efficiency roll-off is small, and the efficiency is still maintained at about 18% at a brightness of 10,000 cd·m⁻². In addition, the regulation of emission color and structural rigidity can be further realized through ligand modification. For example, compound C1/C4/C9, with the change of the ligand, the emission wavelength changes between 600 nm and 700 nm. Among them, the luminous wavelength of the C9 solution exceeds 700 nm, the luminous efficiency of the doped film is about 40%, the maximum external quantum efficiency of the prepared device is close to 15%, and the comprehensive performance is the highest level of current doped OLED. In summary, the platinum complex provided by the present application has high luminous efficiency and good thermal stability, and OLED devices prepared using it as light emitting layer materials also show high external quantum efficiency and lower luminous efficiency roll-off, having great application prospects.

### BRIEF DESCRIPTION OF THE DRAWINGS

In order to illustrate the technical solutions in the specific embodiments of the present application or in the prior art more clearly, the drawings to be used in the description of the specific embodiments or the prior art will be briefly introduced below. Obviously, the drawings in the following description show some of the embodiments of the present application, and those of ordinary skill in the art may still obtain other drawings from these drawings without creative efforts.

FIG. 1 is the luminescence spectrum diagram of the compounds in Example 1-3 of the present application in the polymethyl methacrylate (PMMA) film.

FIG. 2 is the luminescence transient decay curve diagram of the compounds in Example 1-3 of the present application in the polymethyl methacrylate (PMMA) film.

FIG. 3 is a schematic structural view of an organic electroluminescent device in Device Examples 1-9 of the present application.

FIG. 4 is an electroluminescent spectrum diagram based on compound C1 in Device Examples 1-3 of the present application.

FIG. 5 is a current density-voltage diagram based on compound C1 in Device Examples 1-3 of the present application.

FIG. 6 is a brightness-voltage diagram based on compound C1 in Device Examples 1-3 of the present application.

FIG. 7 is a current efficiency-brightness diagram based on compound C1 in Device Examples 1-3 of the present application.

FIG. 8 is an energy efficiency-brightness diagram based on compound C1 in Device Examples 1-3 of the present application.

FIG. 9 is an external quantum efficiency-brightness diagram based on compound C1 in Device Examples 1-3 of the present application.

FIG. 10 is an electroluminescent spectrum diagram based on compound C2 in Device Examples 4-6 of the present application.

FIG. 11 is a current density-voltage diagram based on compound C2 in the Device Examples 4-6 of the present application

FIG. 12 is a brightness-voltage diagram based on compound C₂ in Device Examples 4-6 of the present application.

FIG. 13 is a current efficiency-brightness diagram based on compound C2 in Device Examples 4-6 of the present application.

FIG. 14 is an energy efficiency-brightness diagram based on compound C2 in Device Examples 4-6 of the present application.

FIG. 15 is an external quantum efficiency-brightness diagram based on compound C2 in Device Examples 4-6 of the present application.

FIG. 16 is an electroluminescent spectrum diagram based on compound C3 in Device Examples 7-9 of the present application.

FIG. 17 is a current density-voltage diagram based on compound C3 in Device Examples 7-9 of the present application.

FIG. 18 is a radiance-voltage diagram based on compound C3 in the Device Examples 7-9 of the present application.

FIG. 19 is a current efficiency-radiance diagram based on compound C3 in Device Examples 7-9 of the present application.

FIG. 20 is an energy efficiency-radiance diagram based on compound C3 in Device Examples 7-9 of the present application.

FIG. 21 is an external quantum efficiency-radiance diagram based on compound C3 in Device Examples 7-9 of the present application.

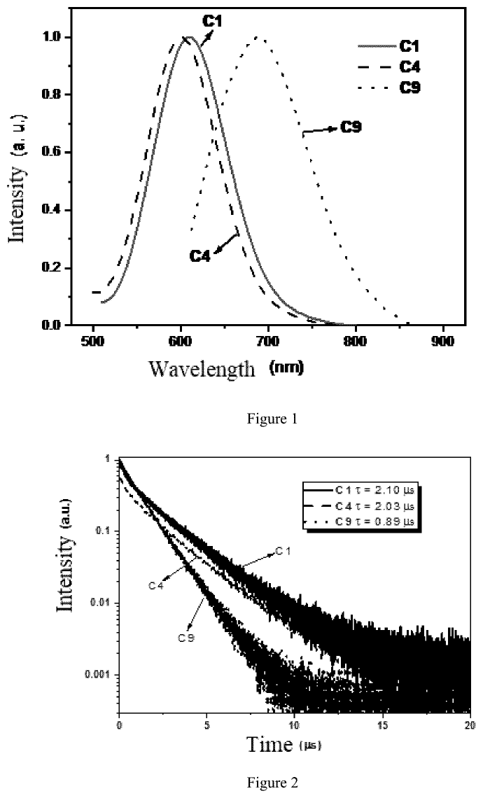

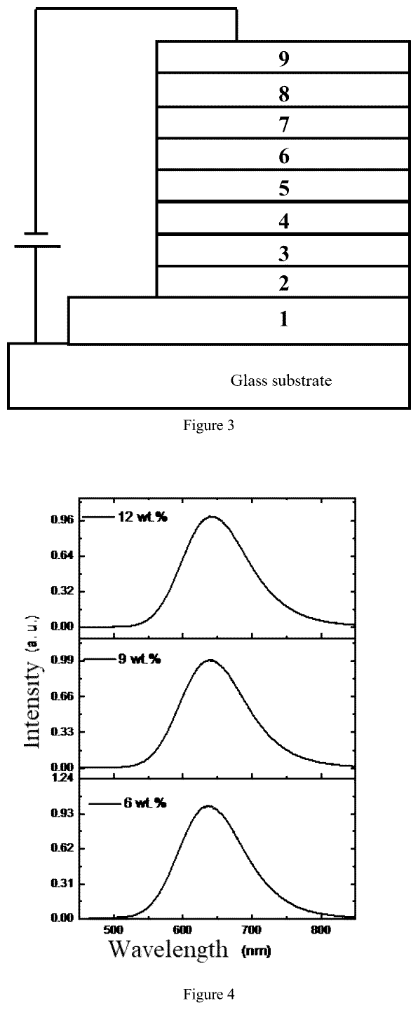

### EXPLANATION OF REFERENCE NUMBERS

1—anode layer, 2—hole injection layer, 3—hole transport layer, 4—electron blocking layer, 5—light emitting layer, 6—hole blocking layer, 7—electron transport layer, 8—electron injection layer, 9—cathode layer.

### DETAILED DESCRIPTION

The following examples are provided for a better understanding of the present application, are not limited to the best implementations, and do not constitute a limitation on the content or scope of protection of the present application. Any product identical or similar to the present application, derived by anyone under the inspiration of the present application or by combining the present application with other features of the prior art, falls within the scope of protection of the present application.

The drugs used in the reactions in the following examples of the present application were obtained from regular channels without further purification, and all reactions were carried out in an argon atmosphere.

In some specific embodiments, the preparation of the following 12 compounds is used as examples:

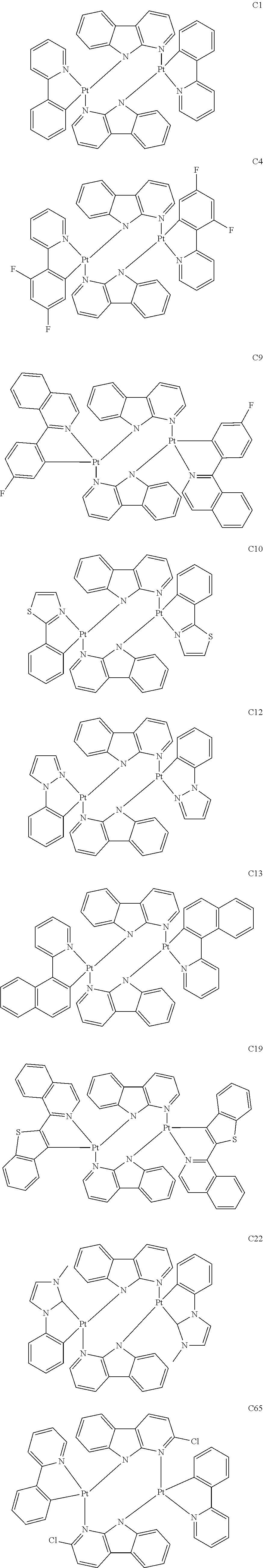

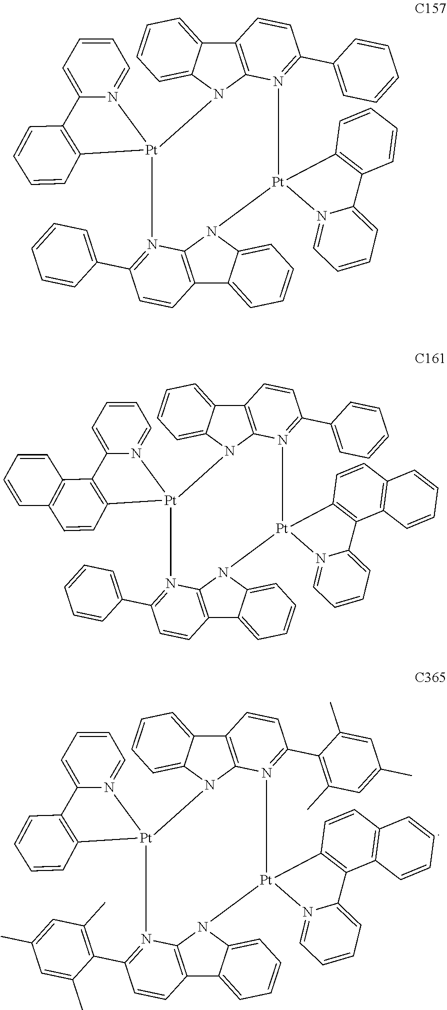

### Example 1

This example provides the preparation method of compound C1, and its synthetic route is as follows:

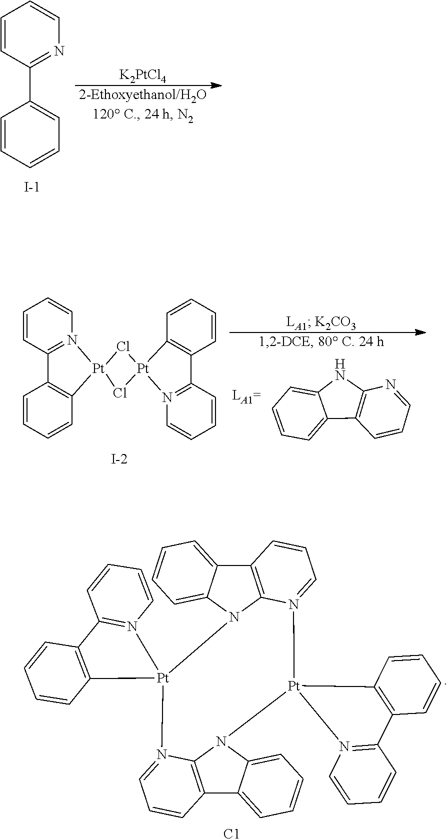

The preparation method of compound C1 comprises the following steps:

### 1) Preparation of Intermediate I-2

Potassium tetrachloroplatinate (3.6 g, 8.7 mmol) and magnetic agitator were placed in a two-necked flask, the flask was vacuumed and argon was blown therein for three cycles, 45 mL glycol ether and 15 mL water which were air removed were injected into the reaction system, and compound I-1 (2.4 g, 15 mmol) was injected and heated to 120° C. to react for 24 hours, then the materials were cooled to room temperature, the solvent was distilled off under reduced pressure, the materials were cooled to room temperature, 25 mL of ethanol was added therein, and the solid was collected by filtration and dried in vacuum for 24 hours to obtain yellow solid 1-2 (68% yield).

### 2) Preparation of Compound C1

The intermediate I-2 (783.1 mg, 1.0 mmol), alpha-carboline (420.2 mg, 2.5 mmol), and anhydrous potassium carbonate (345.6 mg, 2.5 mmol) were mixed in 20 mL of dry 1,2-dichloroethane to reflux for 24 hours under the protection of argon gas. After cooling to room temperature, the solvent was removed by vacuum distillation, 20 ml acetonitrile was added, the solid crude product was collected by filtration, washed with 60 ml acetonitrile for 3 times, separated and purified by column, and vacuum dried for 24 hours to obtain red solid product compound C1 (yield: 35%). ¹H NMR (500 MHz, deuterated chloroform) δ (ppm) 8.62 (d, J=7.0 Hz, 2H), 8.34 (d, J=8.2 Hz, 2H), 8.22 (d, J=7.4 Hz, 2H), 8.04 (d, J=7.7 Hz, 2H), 7.79 (d, J=5.9 Hz, 2H), 7.45 (d, J=7.2 Hz, 2H), 7.32-7.28 (m, 2H), 7.17 (t, J=7.6 Hz, 4H), 7.00 (d, J=7.6 Hz, 2H), 6.79-6.74 (m, 4H), 6.60 (t, J=7.5 Hz, 2H), 6.12 (t, J=7.2 Hz, 2H), 6.00 (d, J=7.3 Hz, 2H). Mass spectrum: [M+OH]: 1049.1827.

### Example 2

This example provides the preparation method of compound C4, and its synthetic route is as follows:

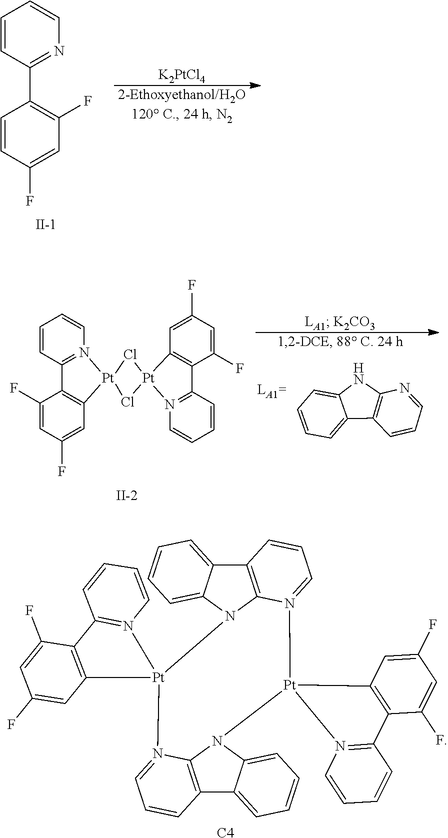

The preparation method of compound C4 comprises the following steps.
1) The preparation method of intermediate II-2 is the same as that of intermediate I-2, except that compound I-1 is replaced by II-1, and intermediate II-2 obtained is a dark green solid (yield 70%).
2) The preparation method of compound C4 is the same as that of compound C1, except that compound I-2 is replaced by II-2, and compound C4 obtained is a red solid (yield 30%). ¹H NMR (500 MHz, deuterated chloroform) δ (ppm) 8.55 (d, J=5.8 Hz, 2H), 8.29 (d, J=8.1 Hz, 2H), 8.27-8.21 (m, 2H), 8.04 (d, J=7.7 Hz, 2H), 7.82 (d, J=5.7 Hz, 2H), 7.68 (d, J=8.4 Hz, 2H), 7.48 (q, J=8.9, 8.2 Hz, 4H), 7.20 (t, J=7.5 Hz, 2H), 6.84-6.76 (m, 2H), 6.34 (t, J=6.6 Hz, 2H), 6.30-6.20 (m, 2H), 5.50 (d, J=8.6 Hz, 2H). Mass spectrum: [M+H]: 1105.1484.

### Example 3

This example provides the preparation method of compound C9, and its synthetic route is as follows:

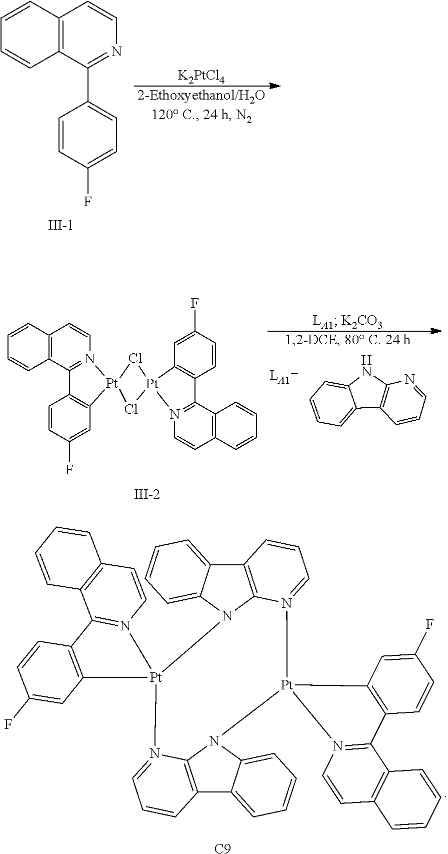

The preparation method of the compound C9 comprises the following steps.
1) The preparation method of intermediate III-2 is the same as that of intermediate I-2, except that compound I-1 is replaced by III-1, and intermediate III-2 obtained is a dark green solid (yield 70%).
2) The preparation method of compound C9 is the same as that of compound C1, except that compound I-2 is replaced by III-2, and obtained compound C9 is a magenta solid (yield 40%). ¹H NMR (400 MHz, deuterated chloroform) δ (ppm) 8.66 (s, 2H), 8.32 (d, J=8.1 Hz, 2H), 8.26 (d, J=7.5 Hz, 2H), 8.06 (d, J=7.7 Hz, 2H), 7.98 (d, J=8.7 Hz, 2H), 7.72 (d, J=6.1 Hz, 2H), 7.60 (q, J=8.6, 8.1 Hz, 4H), 7.45 (dt, J=15.0, 7.2 Hz, 4H), 7.18 (t, J=7.4 Hz, 2H), 7.16-7.08 (m, 2H), 6.81 (t, J=6.4 Hz, 2H), 6.67 (d, J=5.9 Hz, 2H), 6.16 (t, J=8.7 Hz, 2H), 5.85 (d, J=9.4 Hz, 2H). Mass spectrum: [M+H]: 1169.1980.

### Example 4

This example provides a preparation method for compound C19, and its synthetic route is as follows:

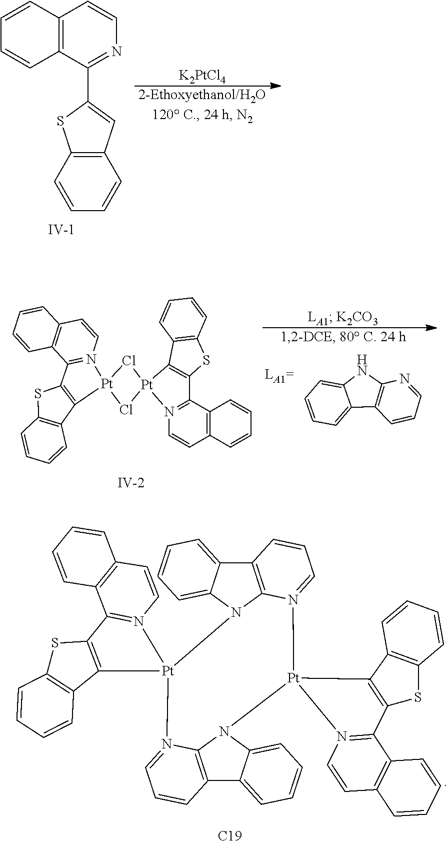

The preparation method of compound C19 comprises the following steps.
1) The preparation method of intermediate IV-2 is the same as that of intermediate I-2, except that compound I-1 is replaced by IV-1, and intermediate IV-2 obtained is a dark red solid (yield 70%).
2) The preparation method of compound C19 is the same as the preparation of compound C1, the difference is that the compound I-2 is replaced by IV-2, and the obtained compound C19 is a dark red solid (yield 10%). Mass spectrum: [M+H]: 1245.1598.

### Example 5

This example provides the preparation method of compound C13, and its synthetic route is as follows:

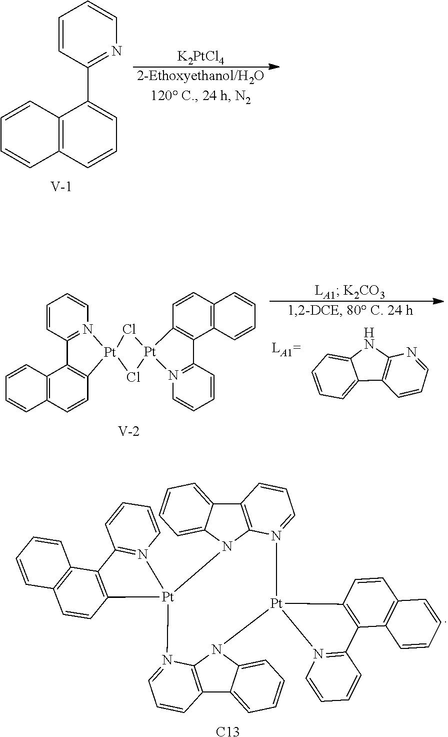

The preparation method of compound C13 comprises the following steps.
1) The preparation method of intermediate V-2 is the same as that of intermediate I-2, except that compound I-1 is replaced by V-1, and intermediate V-2 obtained is a brown solid (yield 70%).
2) The preparation method of compound C13 is the same as that of C₁, the difference is that compound I-2 is replaced by V-2, and compound C13 obtained is a red solid (yield 30%). Mass spectrum: [M+H]: 1133.2185.

### Example 6

This example provides the preparation method of compound C22, and its synthetic route is as follows:

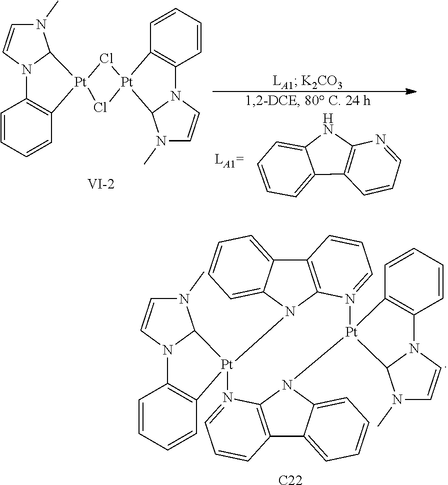

The preparation method of compound C22 comprises the following steps.

The preparation method of compound C22 is the same as that of compound C1, the difference is that compound I-2 is replaced by VI-2, and the obtained compound C22 is a red solid (yield 31%). Mass spectrum: [M+H]: 1039.2096.

### Example 7

This example provides the preparation method of compound C12, and its synthetic route is as follows:

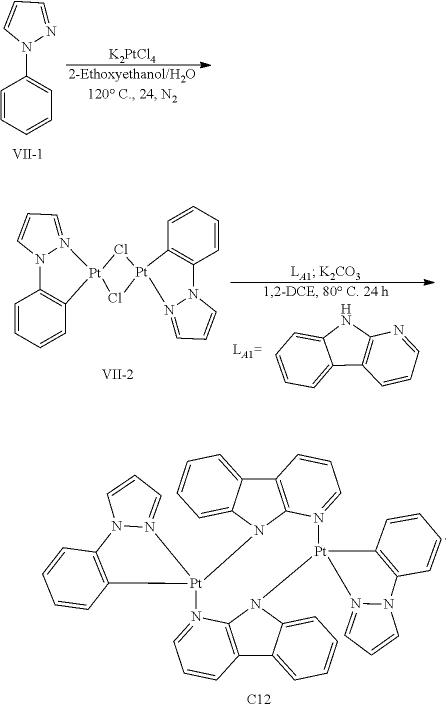

The preparation method of compound C12 comprises the following steps.
1) The preparation method of intermediate VII-2 is the same as that of intermediate I-2, except that compound I-1 is replaced by VII-1, and intermediate VII-2 is obtained as a yellow solid (yield 70%).
2) The preparation method of compound C12 is the same as that of compound C1, the difference is that compound I-2 is replaced by VII-2, and the obtained compound C12 is a red solid (yield 30%). Mass spectrum: [M+H]: 1011.1785.

### Example 8

This example provides the preparation method of compound C10, and its synthetic route is as follows:

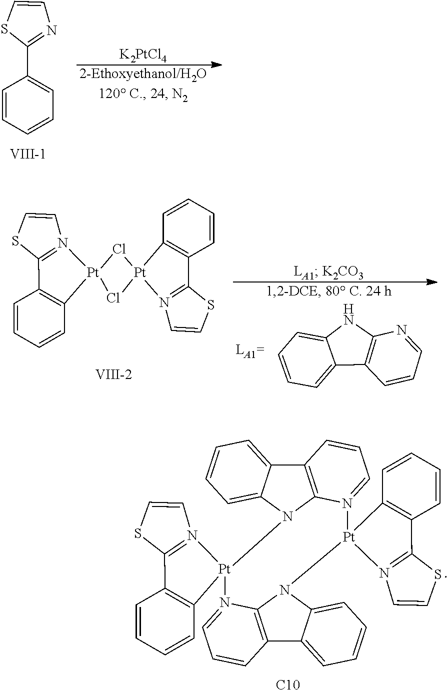

The preparation method of compound C10 comprises the following steps.
1) The preparation method of intermediate VIII-2 is the same as that of intermediate I-2, except that compound I-1 is replaced by VIII-1, and intermediate VIII-2 obtained is a dark brown solid (60% yield).
2) The preparation method of compound C10 is the same as the preparation of compound C1, the difference is that compound I-2 is replaced by VIII-2, and the obtained compound C10 is a red solid (yield 20%). Mass spectrum: [M+H]: 1045.1007.

### Example 9

This example provides the preparation method of compound C65, and its synthetic route is as follows:

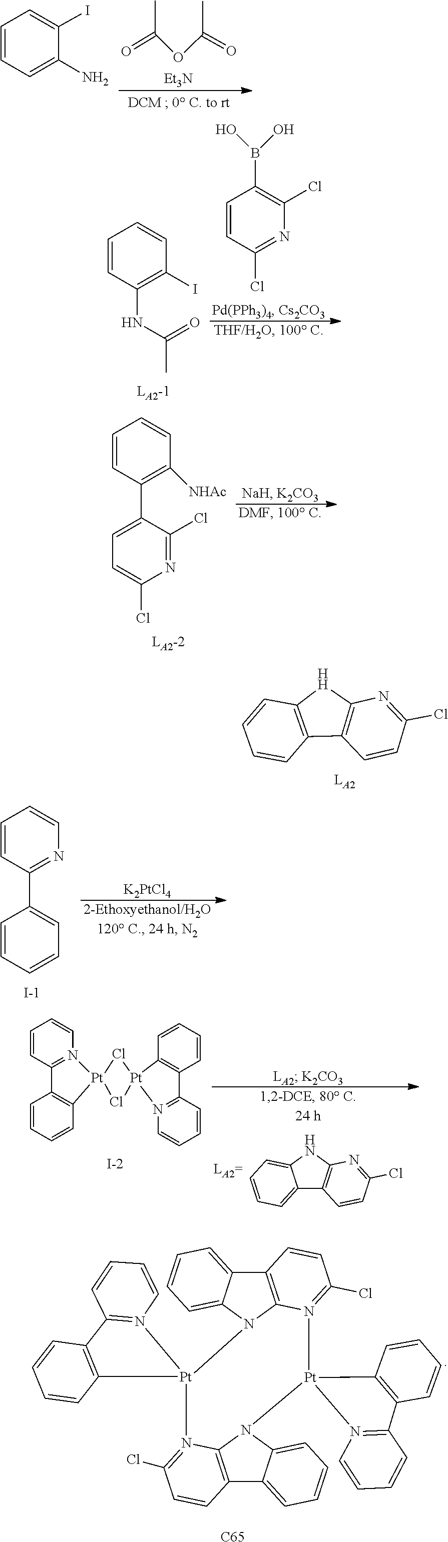

The preparation method of compound C65 comprises the following steps.
1) Preparation of intermediate L_{A2}-1

A 250 mL dry double-necked round-bottom flask was taken and argon was blown therein, 2-iodoaniline (8.76 g, 40.0 mmol) was weighed and added in the flask, the flask was vacuumized and introduced argon for three times, 50 mL of dry dichloromethane was added into the flask, and acetic anhydride (12.23 mL, 88.0 mmol) and triethylamine (4.53 mL, 48.0 mmol) were added under the ice water bath. The reaction system was stirred for 36 hours under the protection of argon gas, and then naturally rose to the room temperature, the materials were subjected spin drying and column chromatodiagramy separation to obtain white solid product L_{A2-1} (9.38 g, 90% yield). ¹H NMR (400 MHz, CDCl₃) δ (ppm): 8.20 (d, J=8.3 Hz, 1H), 7.84-7.70 (m, 1H), 7.47-7.19 (m, 2H), 6.96-6.71 (m, 1H), 2.24 (s, 3H).
2) Preparation of intermediate L_{A2}-2

A 250 mL double-necked round-bottom flask was taken, and the flask was vacuumized and argon was blown therein for three cycles. L_{A2}-1 (2.61 g, 10 mmol), 2,6-dichloro-3-pyridineboronic acid (2.88 g, 15 mmol), cesium carbonate (9.78 g, 30 mmol) and tetrakis (triphenylphosphine) palladium (1.16 g, 1 mmol) were weighted and added into the flask, the flask was vacuumized and argon was blown therein for three cycles. 60 mL THF and 30 mL distilled water were extracted and introduced into the reaction vessel. The reaction system was stirred at 100° C. for 40 hours, then cooled to room temperature and spin-dried. After extracted with dichloromethane (DCM) and water, the organic phase of the lower layer was spin-dried, separated by column chromatodiagramy (the volume ratio of petroleum ether:ethyl acetate=1:1), and the yellow solid product L_{A2}-2 was obtained (2.06 g, yield 73%). ¹H NMR (500 MHz, CDCl₃) (ppm): 7.90 (d, J=8.2 Hz, 1H), 7.64 (d, J=8.0 Hz, 1H), 7.55-7.10 (m, 5H), 6.87 (s, 1H), 2.02 (s, 3H).
3) Preparation of intermediate L_{A2}

A 100 mL dry double-necked round-bottom flask was taken and argon was blown therein. L_{A2}-2 (1.92 g, 6.82 mmol), potassium carbonate (5.66 g, 40.92 mmol) and sodium hydride (0.55 g, 13.64 mmol) were weighted and introduced into the flask, the flask was vacuumized and argon was blown therein for three cycles. 40 mL of dry DMF were added into the reaction flask, then the materials were stirred at 100° C. for 48 hours, and cooled to room temperature. The reaction system was quenched with water, and then filtered. The filter residue was dissolved with dichloromethane (DCM) and then separated through a silica gel column (eluent: DCM) to obtain a pale yellow solid L_{A2} (0.74 g, yield 54%). ¹H NMR (500 MHz, CDCl₃) δ (ppm): 9.55 (s, 1H), 8.28 (d, J=8.0 Hz, 1H), 8.03 (d, J=7.8 Hz, 1H), 7.64-7.46 (m, 2H), 7.36-7.29 (m, 1H), 7.23 (d, J=8.0 Hz, 1H).
4) The preparation method of compound I-2 is the same as that in Example 1.
5) The preparation method of compound C65 is the same as that of compound C1, the difference is that compound L_{A1} is replaced by L_{A2}, and the obtained compound C65 is a red solid (yield 32%). Mass spectrum: [M+H]: 1101.1104.

### Example 10

This example provides the preparation method of compound C157, and its synthetic route is as follows:

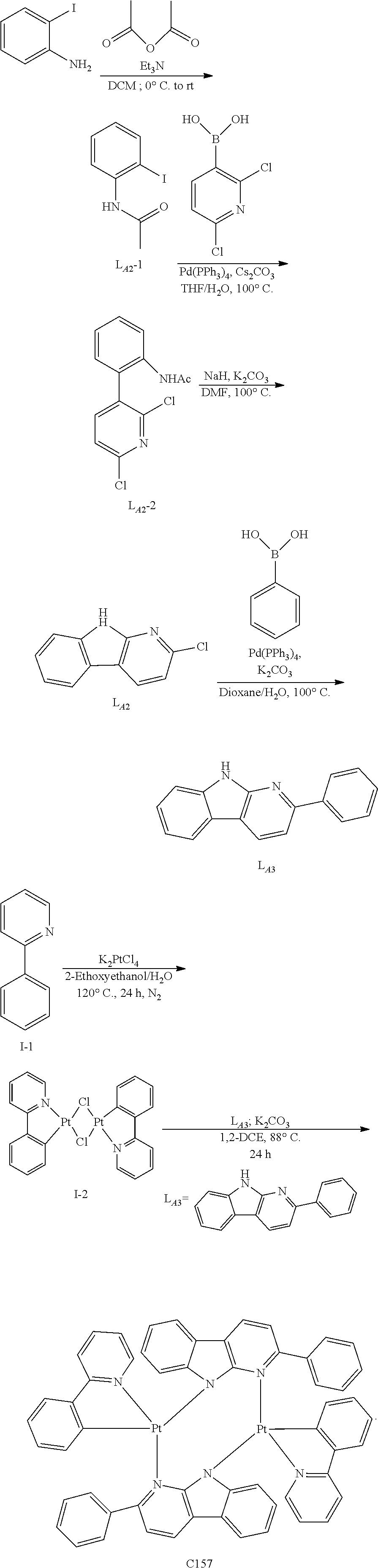

The preparation method of the compound C157 comprises the following steps:
1) The preparation of intermediate L_{A2} is the same as that in Example 9;
2) Preparation of intermediate L_{A3}:

A 250 mL double-necked round-bottom flask was taken and argon was blown therein, L_{A} (2.11 g, 10.43 mmol), phenylboronic acid (5.09 g, 41.72 mmol), potassium carbonate (11.53 g, 83.44 mmol) and Pd(PPh₃)₄ (0.96 g, 0.83 mmol) were weighted and added into the flask, the flask was vacuumized and argon was blown therein for three cycles. 60 mL of 1,4-dioxane and 60 mL of distilled water were added into the flask, the reaction system was stirred at 100° C. for 18 hours, and cooled to room temperature. After spin-dried, the crude product was extracted with DCM and water, and the organic phase of the lower layer was spin-dried and separated by column chromatodiagramy (DCM) to obtain a light yellow solid L_{A} (1.55 g, yield 61%). ¹H NMR (500 MHz, DMSO-d6) δ (ppm): 11.85 (s, 1H), 8.57 (d, J=8.1 Hz, 1H), 8.24-8.10 (m, 3H), 7.81 (d, J=8.1 Hz, 1H), 7.59-7.49 (m, 3H), 7.45 (dd, J=8.6, 7.2 Hz, 2H), 7.28-7.13 (m, 1H);
3) The preparation method of compound I-2 is the same as that in Example 1; and
4) The preparation method of compound C157 is the same as that of compound C1, the difference is that L_{A1} is replaced by L_{A3}, and the obtained compound C157 is a red solid (yield 27%). Mass spectrum: [M+H]: 1185.2490.

### Example 11

This example provides the preparation method of compound C161, and its synthetic route is as follows:

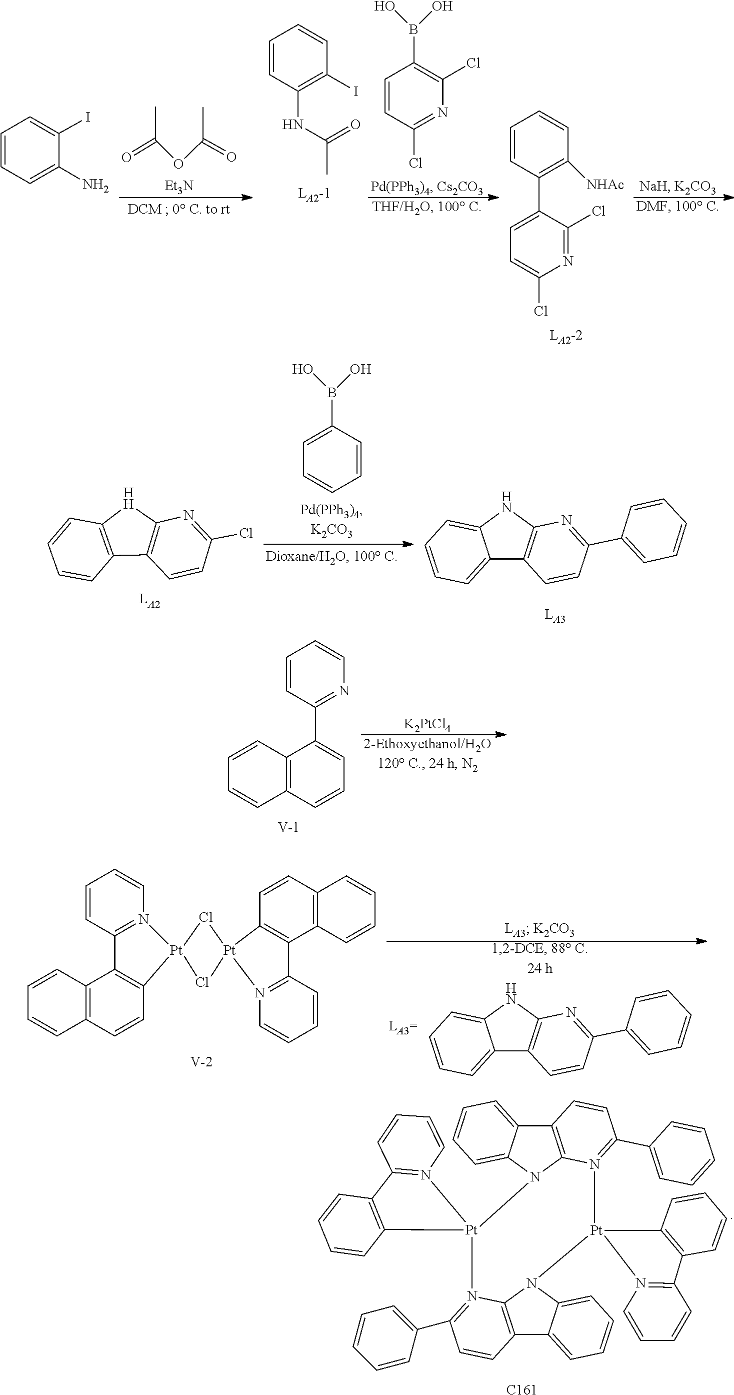

The preparation method of compound C161 comprises the following steps:
1) The preparation of intermediate L_{A2} is the same as that in Example 9;
2) The preparation of intermediate L_{A3} is the same as that in Example 10;
3) The preparation method of compound V-2 is the same as that in Example 5; and
4) The preparation method of compound C161 is the same as that of compound C1, the difference is that compound I-2 is replaced by V-2, and L_{A1} is replaced by L_{A3}, and the obtained compound C161 is a dark red solid (yield 20%). Mass spectrum: [M+H]: 1285.2802.

### Example 12

This example provides the preparation method of compound C165, and its synthetic route is as follows:

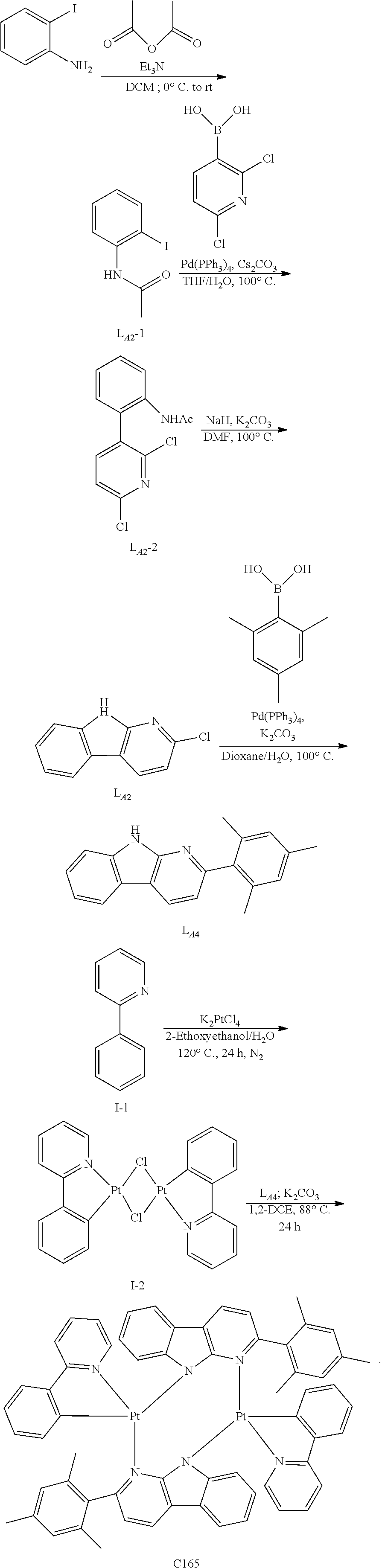

The preparation method of compound C165 comprises the following steps:
1) The preparation of intermediate L_{A2} is the same as that in Example 9;
2) The preparation of intermediate L_{A4} is the same as the synthesis of L_{A3} in Example 10, the difference is that phenylboronic acid is replaced by 4-pyridineboronic acid, and the eluent used for column chromatodiagramy separation is a mixed system of DCM:EA=3:2 to obtain light yellow solid L_{A4} (452.88 mg, yield 53%);
3) The preparation method of compound I-2 is the same as that in Example 1; and
4) The preparation method of compound C165 is the same as that of compound C1, except that L_{A1} is replaced by L_{A4}, and the obtained compound C165 is a dark red solid (yield 20%). Mass spectrum: [M+H]: 1269.3455.

### Device Example 1

This example provides an organic electroluminescent device, as shown in FIG. 1, comprising anode layer 1, hole injection layer 2, hole transport layer 3, electron blocking layer 4, light emitting layer 5, hole blocking layer 6, electron transport layer 7, electron injection layer 8 and cathode layer 9 arranged sequentially on a glass substrate from bottom to top.

The device structure is ITO/HAT-CN(5 nm)/TAPC(30 nm)/TcTa(15 nm)/Compound C1:DMIC-Cz:DMIC-TRz:(50 nm)/ANT-BIZ(40 nm)/Liq(2 nm)/Al (100 nm).

Wherein, both hole blocking layer 6 and electron transport layer 7 are made of ANT-BIZ, and the sum of the thickness of the two layers is 40 nm.

Anode layer 1 is made of ITO material, that is, indium tin oxide material.

12-hexaazatriphenylene (HAT-CN) is selected as the material of hole injection layer 2, and the structure is as follows:

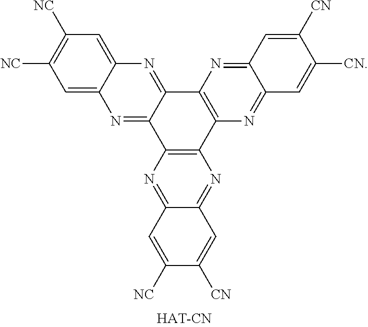 [SMILES: N#Cc1cc2nc3c4nc5cc(C#N)c(C#N)cc5nc4c4nc5cc(C#N)c(C#N)cc5nc4c3nc2cc1C#N]

4,4′-cyclohexyl bis[N,N-bis(4-methylphenyl)aniline] (TAPC) is selected as the material of hole transport layer 3, and the structure is as follows:

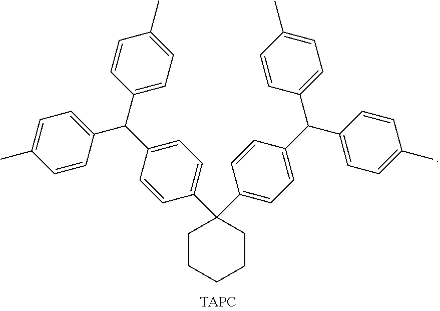

TcTa is selected as the material of electron blocking layer 4, and the structure is as follows:

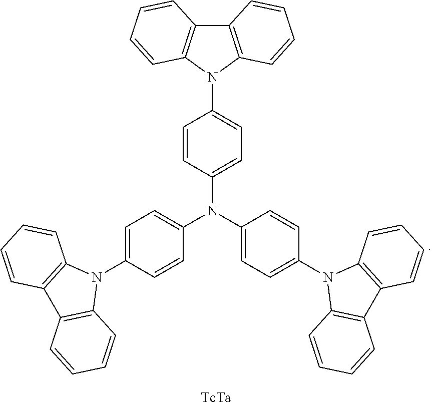 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; "TcTa"]

Light emitting layer 5 is formed by co-doping the host material and the guest material, wherein a blend of compounds DMIC-Cz and DMIC-TRz (mass ratio of 1:1) is selected as the host material, and compound C1 of the present application is selected as the guest material. The doping amount of the guest material accounts for 6% of the total mass of the host and guest materials; wherein the chemical structures of the host material compounds are as follows:

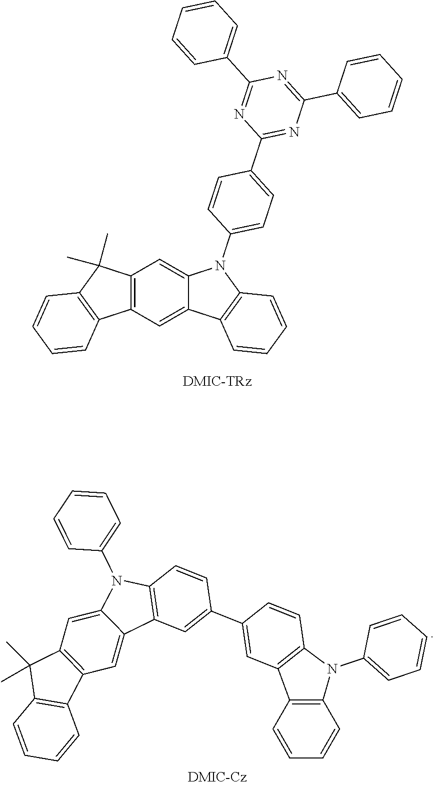 [SMILES: CC1(C)c2ccccc2-c2cc3c4ccccc4n(-c4ccc(-c5nc(-c6ccccc6)nc(-c6ccccc6)n5)cc4)c3cc21 ; CC1(C)c2ccccc2-c2cc3c4cc(-c5ccc6c(c5)c5ccccc5n6-c5ccccc5)ccc4n(-c4ccccc4)c3cc21]

Both hole blocking layer 6 and electron transport layer 7 are made of ANT-BIZ, and the structure is as follows:

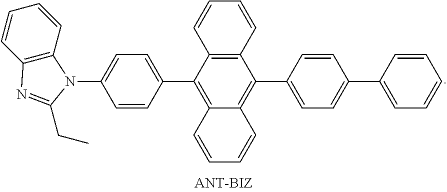 [SMILES: CCc1nc2ccccc2n1-c1ccc(-c2c3ccccc3c(-c3ccc(-c4ccccc4)cc3)c3ccccc23)cc1]

Liq is selected as the material of electron injection layer 8;
The metal Al material is selected as the material of cathode layer 9.

### Device Example 2

This example provides an organic electroluminescent device, which differs from the organic electroluminescent device provided in Device Example 1 in that: the doping amount of the guest material C1 in light emitting layer 5 accounts for 9% of the total mass of the host material and the guest material.

### Device Example 3

This example provides an organic electroluminescent device, which differs from the organic electroluminescent device provided in Device Example 1 in that: the doping amount of the guest material C1 in light emitting layer 5 accounts for 12% of the total mass of the host material and the guest material.

### Device Example 4

This example provides an organic electroluminescent device, which differs from the organic electroluminescent device provided in Device Example 1 in that: compound C4 of the present application is adopted as the guest material in light emitting layer 5, and the doping amount of the guest material accounts for 6% of the total mass of the host material and the guest material.

### Device Example 5

This example provides an organic electroluminescent device, which differs from the organic electroluminescent device provided in Device Example 1 in that: compound C4 of the present application is adopted as the guest material in light emitting layer 5, and the doping amount of the guest material accounts for 9% of the total mass of the host material and the guest material.

### Device Example 6

This example provides an organic electroluminescent device, which differs from the organic electroluminescent device provided in Device Example 1 in that: compound C4 of the present application is adopted as the guest material in light emitting layer 5, and the doping amount of the guest material accounts for 12% of the total mass of the host material and the guest material.

### Device Example 7

This example provides an organic electroluminescent device, which differs from the organic electroluminescent device provided in Device Example 1 in that: compound C9 of the present application is adopted as the guest material in light emitting layer 5, and the doping amount of the guest material accounts for 6% of the total mass of the host material and the guest material.

### Device Example 8

This example provides an organic electroluminescent device, which differs from the organic electroluminescent device provided in Device Example 1 in that: compound C9 of the present application is adopted as the guest material in light emitting layer 5, and the doping amount of the guest material accounts for 9% of the total mass of the host material and the guest material.

### Device Example 9

This example provides an organic electroluminescent device, which differs from the organic electroluminescent device provided in Device Example 1 in that: compound C9 of the present application is adopted as the guest material in light emitting layer 5, and the doping amount of the guest material accounts for 12% of the total mass of the host material and the guest material.

### Test Example 1

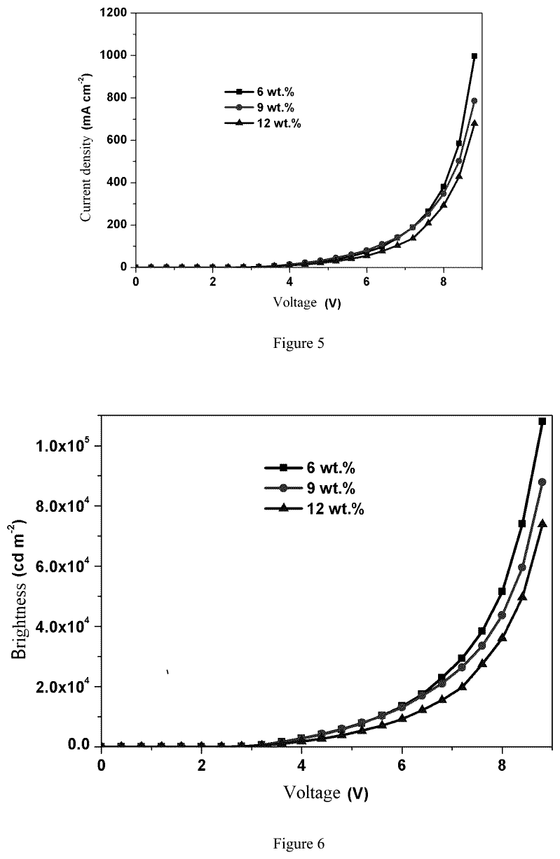

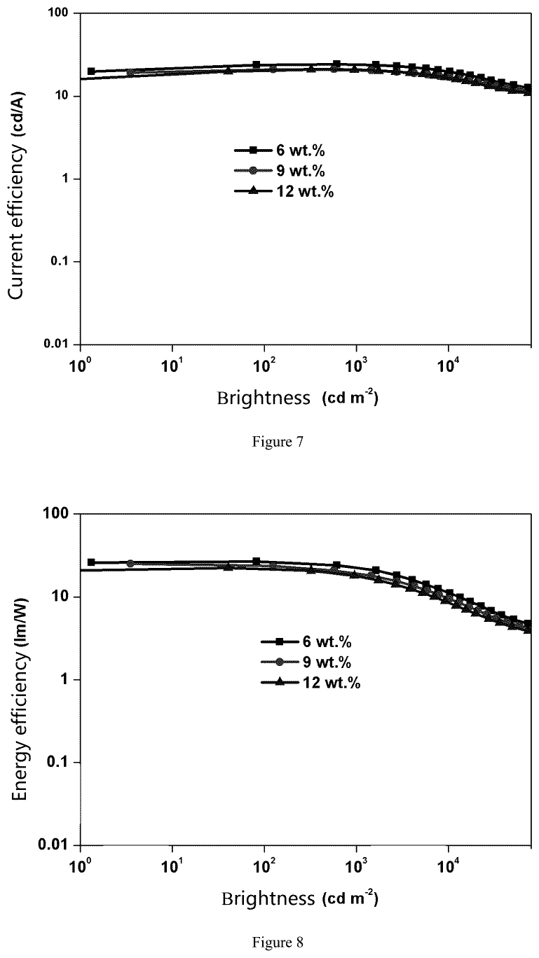

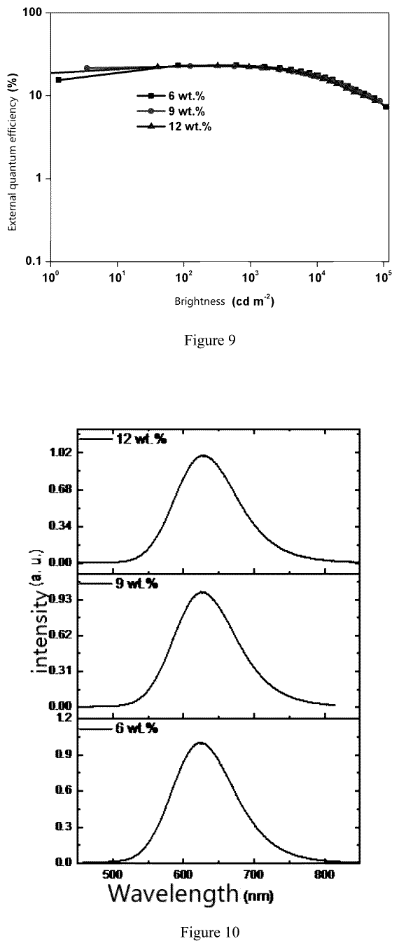

The organic electroluminescent devices provided in Device Examples 1-3 were tested, and the current-brightness-voltage characteristics of the devices were measured by a Keithley source measurement system (Keithley 2400 Sourcemeter, Keithley 2000 Currentmeter) with calibrated silicon photodiodes. All tests were conducted in air at room temperature, and the test results are shown in Table 1 and FIGS. 4-9.

TABLE 1
device performance test results

| | | CE | | PE | | EQE | | |
|---|---|---|---|---|---|---|---|---|
| | | [cd A⁻¹]^{[b]} | | [lm W⁻¹]^{[c]} | | [%]^{[d]} | | CIE |
| Device | L | | 10000 | | 10000 | | 10000 | [(x, |
| Example | [cd m⁻²]^{[a]} | Max. | cd m⁻² | Max. | cd m⁻² | Max. | cd m⁻² | y)]^{[e]} |
| 1 | 108075 | 24.4 | 19.9 | 26.8 | 20.0 | 23.3 | 17.8 | (0.62, 0.38) |
| 2 | 87872 | 21.1 | 17.1 | 25.1 | 17.1 | 22.8 | 17.0 | (0.61, 0.38) |
| 3 | 73904 | 21.0 | 16.6 | 22.3 | 16.7 | 22.9 | 16.6 | (0.62, 0.38) |

^{[a]}maximum brightness;
^{[b]}current efficiency;
^{[c]}power efficiency;
^{[d]}external quantum efficiency;
^{[e]}CIE coordinate @10,000 cd · m⁻².

The red light-emitting OLED device prepared by the present application using compound C1 as the guest material has a maximum luminous brightness exceeding 100,000 cd·m⁻², a maximum current efficiency of 24.4 cd A⁻¹, a maximum power of 26.8 lm W⁻¹, and a maximum external quantum efficiency of 23.3%.

### Test Example 2

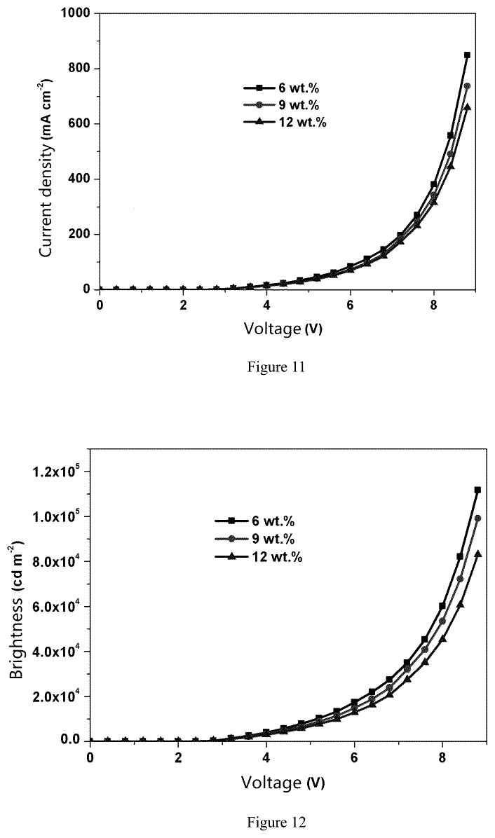

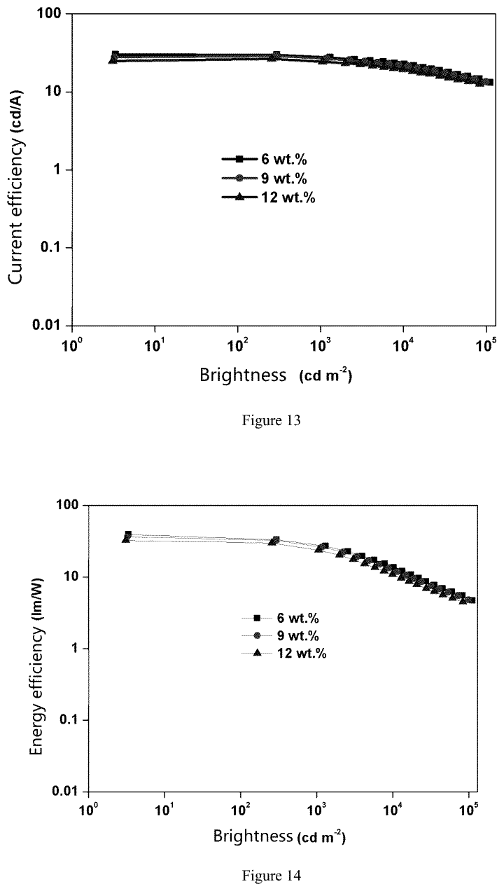

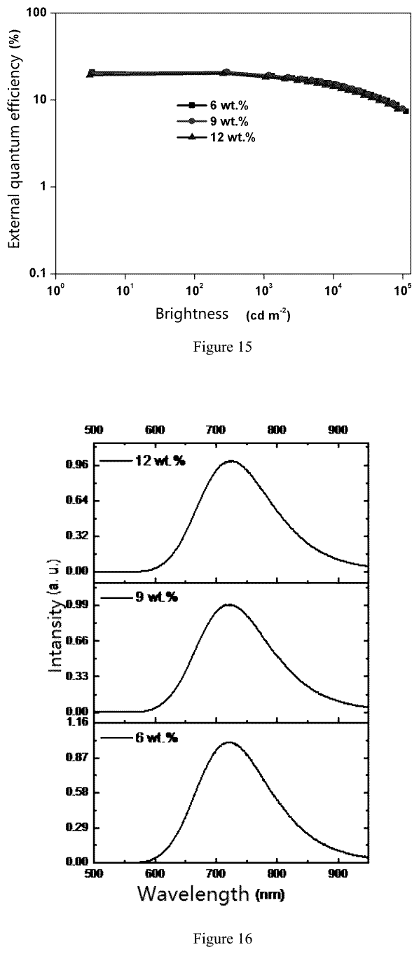

The organic electroluminescent devices provided in Device Examples 4-6 were tested, and the current-brightness-voltage characteristics of the devices were measured by a Keithley source measurement system (Keithley 2400 Sourcemeter, Keithley 2000 Currentmeter) with calibrated silicon photodiodes. All tests were conducted in air at room temperature, and the test results are shown in Table 2 and FIGS. 10-15.

TABLE 2
device performance test results

| | | CE | | PE | | EQE | | |
|---|---|---|---|---|---|---|---|---|
| | | [cd A⁻¹]^{[b]} | | [lm W⁻¹]^{[c]} | | [%]^{[d]} | | CIE |
| Device | L | | 1000 | | 1000 | | 10,000 | [(x, |
| Example | [cd m⁻²]^{[a]} | Max. | cd m⁻² | Max. | cd m⁻² | Max. | cd m⁻² | y)]^{[e]} |
| 4 | 111800 | 30.1 | 27.8 | 39.3 | 27.3 | 20.8 | 19.0 | (0.60, 0.40) |
| 5 | 99171 | 29.0 | 26.8 | 26.5 | 20.18 | 21.0 | 19.7 | (0.60, 0.40) |
| 6 | 83058 | 26.6 | 24.3 | 24.3 | 21.1 | 20.1 | 18.3 | (0.61, 0.39) |

^{[a]}maximum brightness;
^{[b]}current efficiency;
^{[c]}power efficiency;
^{[d]}external quantum efficiency;
^{[e]}CIE coordinate @10,000 cd · m⁻².

The orange-red light-emitting OLED device prepared by the present application using compound C4 as the guest material has a maximum luminous brightness exceeding 111,800 cd·m⁻², a maximum current efficiency of 30.1 cd A⁻¹, a maximum power of 39.3 lm W⁻¹, and a maximum external quantum efficiency of 21.0%.

### Test Example 3

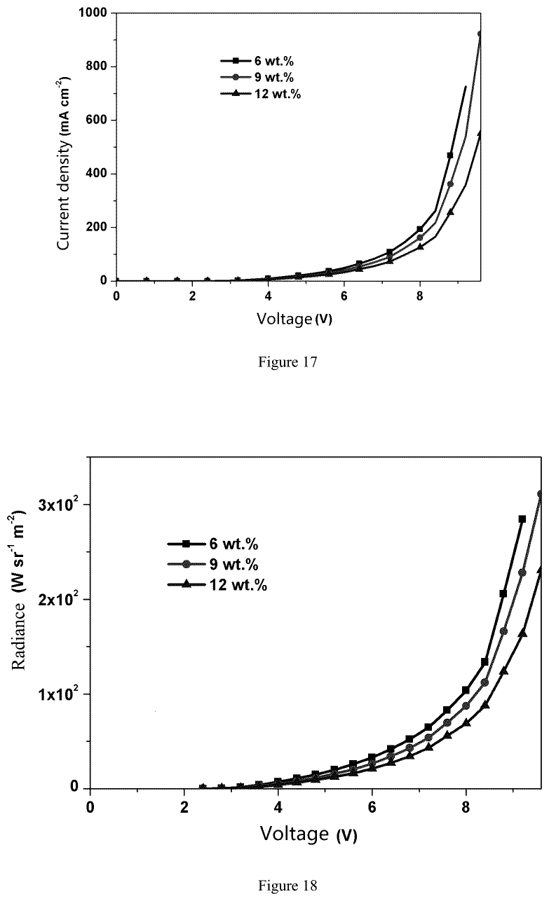

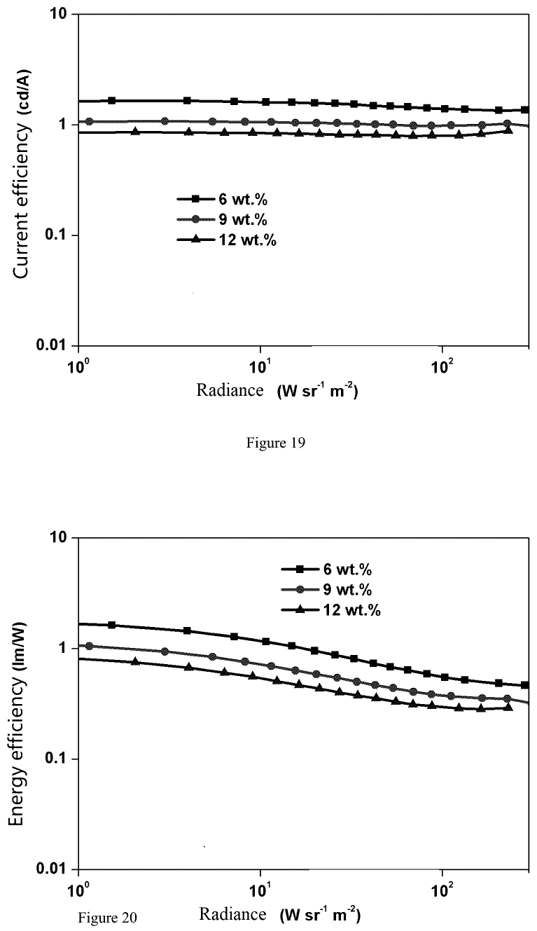

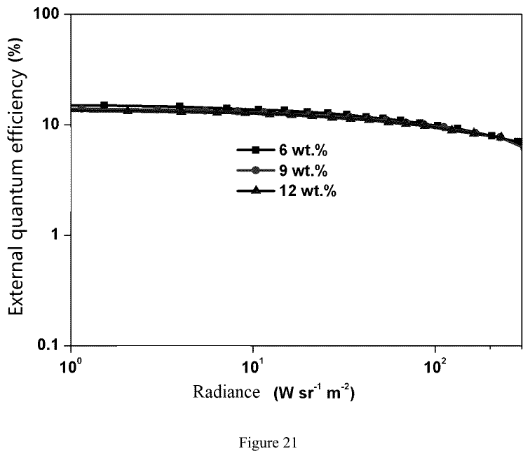

The organic electroluminescent devices provided in Device Examples 7-9 were tested, and the current-brightness-voltage characteristics of the devices were measured by a Keithley source measurement system (Keithley 2400 Sourcemeter, Keithley 2000 Currentmeter) with calibrated silicon photodiodes. All tests were conducted in air at room temperature, and the test results are shown in Table 3 and FIGS. 16-21.

TABLE 3
device performance test results

| | | CE | | PE | | EQE | | |
|---|---|---|---|---|---|---|---|---|
| | R | [cd A⁻¹]^{[b]} | | [lm W⁻¹]^{[c]} | | [%]^{[d]} | | CIE |
| Device | [W sr⁻¹ | | 100 W | | 100 W | | 100 W | [(x, |
| Example | m⁻²]^{[a]} | Max. | sr⁻¹ m⁻² | Max. | sr⁻¹ m⁻² | Max. | sr⁻¹ m⁻² | y)]^{[e]} |
| 7 | 285 | 1.65 | 1.39 | 1.79 | 0.55 | 15.0 | 9.90 | (0.67, 0.31) |
| 8 | 311 | 1.07 | 0.99 | 1.25 | 0.37 | 14.0 | 9.62 | (0.69, 0.30) |
| 9 | 231 | 0.86 | 0.80 | 0.90 | 0.29 | 13.4 | 9.78 | (0.70, 0.30) |

^{[a]}maximum brightness;
^{[b]}current efficiency;
^{[c]}power efficiency;
^{[d]}external quantum efficiency;
^{[e]}CIE coordinate @100 W sr⁻¹ m⁻².

The near-infrared light-emitting OLED device prepared by the present application using compound C9 as the guest material has a maximum radiance of 311 W sr⁻¹ m⁻² and a maximum external quantum efficiency of 15.0%. The external quantum efficiency remains at 9.90% even at a radiance of 100 W sr⁻¹ m⁻².

In summary, the present application effectively regulates the distance between central metal atoms by using α-carboline derivatives as bridging bidentate ligands, induces strong Pt—Pt interactions, and produces MMLCT (metal-metal-to-ligand charge transfer) excited state, which promotes the red shift of luminescence. At the same time, by optimizing and adjusting the auxiliary ligands, the emission color adjustment and structural rigidity adjustment are further realized, and a class of red-near-infrared light-emitting phosphorescent materials with high emission efficiency and excellent performance is obtained. When they are applied to a light-emitting device, the compounds of the present application exhibit good device performance, and the maximum external quantum efficiency is as high as 23.3%.

Obviously, the above-mentioned embodiments are only examples for clear description, rather than limiting the implementation. For those of ordinary skill in the art, other changes or changes in different forms can be made on the basis of the above description. It is not necessary and impossible to exhaustively list all the implementation manners here. And the obvious changes or modifications derived therefrom are still within the scope of protection of the present application.

1. A binuclear metal platinum complex, having the following structure: 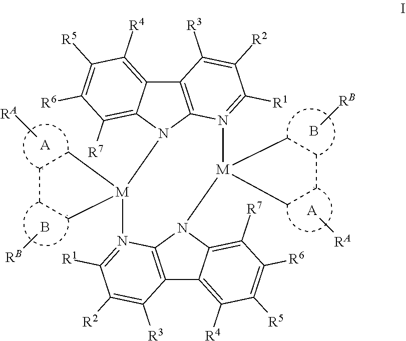
wherein, M is platinum metal, ring A and ring B are each independently selected from a C₆-C₁₈ aryl and a C₅-C₁₇ heteroaryl, ring A and ring B can be connected by a single bond or by forming a fused ring, and ring A and ring B coordinate with metal M center in a form of a negative monovalent bidentate ligand;
ring A and ring B are optionally substituted by one or more substituents R^{A} or R^{B}; R^{A} and R^{B} are each independently selected from hydrogen, deuterium, a heteroatom-containing substituent, a C₁-C₄₀ alkyl, a C₂-C₄₀ alkenyl, a C₂-C₄₀ alkynyl, a C₆-C₄₈ aryl, and a C₅-C₄₈ heteroaryl;
R¹ to R⁷ are the same or different and are each independently selected from hydrogen, deuterium, a heteroatom-containing substituent, a C₁-C₄₀ alkyl, a C₂-C₄₀ alkenyl, a C₂-C₄₀ alkynyl, a C₆-C₄₈ aryl and a C₅-C₄₈ heteroaryl;
or adjacent two of R¹ to R⁷ are connected with each other to form a C₃-C₁₀ cycloalkyl, a C₆-C₃₀ aryl or a C₅-C₃₀ heteroaryl.

2. The binuclear metal platinum complex according to claim 1, wherein, ring A and ring B are respectively selected from phenyl, naphthyl, anthryl, fluorenyl, pyridyl, pyrimidinyl, pyridazinyl, pyrazinyl, quinolinyl, isoquinolinyl, benzopyrimidinyl, benzopyridazinyl, benzopyrazinyl, thienyl, pyrrolyl, pyrazolyl, thiazolyl, imidazolyl, oxazolyl, 1,2,4-triazolyl, 1,2,3-triazolyl, isoxazolyl, isothiazolyl, indolyl, benzimidazolyl, benzothienyl, benzothiazolyl, azacarbene group;
ring A and ring B are optionally substituted by one or more substituents R^{A} or R^{B}; R^{A} and R^{B} are each independently selected from hydrogen, deuterium, a heteroatom-containing substituent, a C₁-C₄₀ alkyl, a C₆-C₄₈ aryl, and a C₅-C₄₈ heteroaryl.

3. The binuclear metal platinum complex according to claim 1, wherein, R¹ to R⁷ are the same or different and are each independently selected from hydrogen, deuterium, a heteroatom-containing substituent, a C₁-C₁₀ alkyl, a C₆-C₂₀ aryl and a C₅-C₁₉ heteroaryl;
or adjacent two of R¹ to R⁷ are connected with each other to form a C₃-C₈ cycloalkyl, a C₆-C₁₀ aryl or a C₅-C₉ heteroaryl.

4. The binuclear metal platinum complex according to claim 2, wherein, R^{A} and R^{B} are each independently selected from —F, —Cl, —Br, —I, —O(R′), —S(R′), —N(R′)₂, —SO(R′), —SO₂(R′), —P(R′)₂, —PO(R′)₂, —PO(OR′)(R′), —PO(OR′)₂, —Si(R′)₃, a C₁-C₂₀ alkyl, a C₂-C₂₀ alkenyl, a C₂-C₂₀ alkynyl, a C₁-C₂₀ haloalkyl, a C₁-C₈ alkoxy, a C₃-C₈ cycloalkyl, a C₃-C₈ heterocycloalkyl, a C₃-C₈ aryl, a C₃-C₈ heteroaryl; wherein, R′ is independently selected from hydrogen, a halogen, a C₁-C₈ alkyl, a C₁-C₈ haloalkyl, a C₃-C₈ cycloalkyl, a C₃-C₈ heterocycloalkyl, a C₃-C₈ aryl, and a C₃-C₈ heteroaryl.

5. The binuclear metal platinum complex according to claim 3, wherein, R², R³, R⁴, R⁶ and R⁷ are selected from hydrogen, and R¹ and R⁵ are independently selected from hydrogen, deuterium, a heteroatom-containing substituent, a C₁-C₄₀ alkyl, a C₆-C₄₈ aryl and a C₃-C₄₈ heteroaryl.

6. The binuclear metal platinum complex according to claim 1, wherein, in formula I, 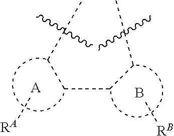
comprises the following structures:

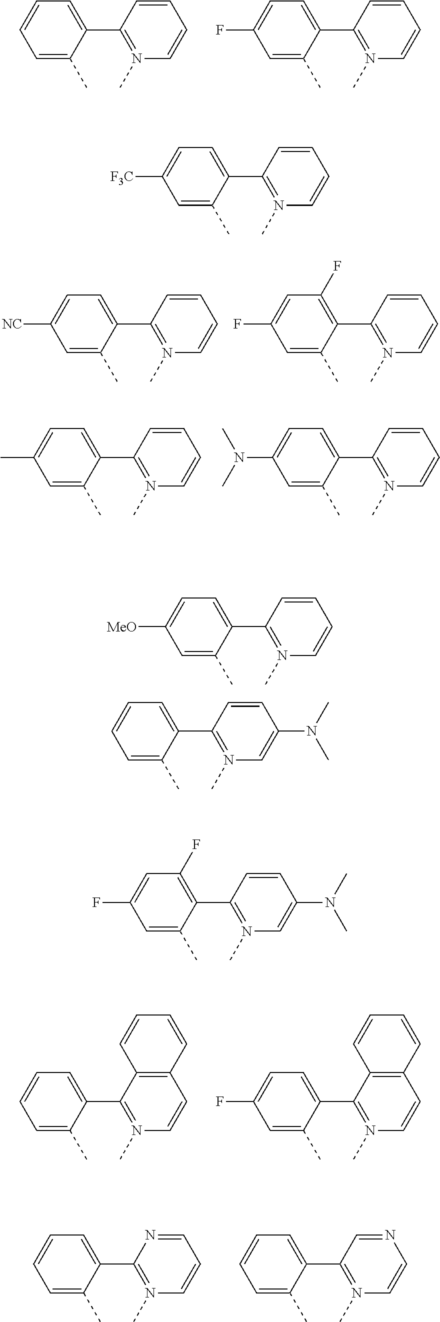

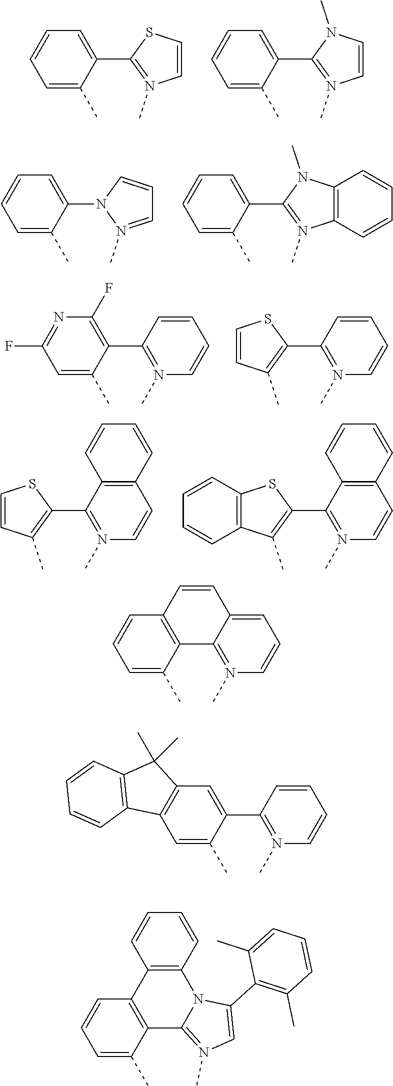

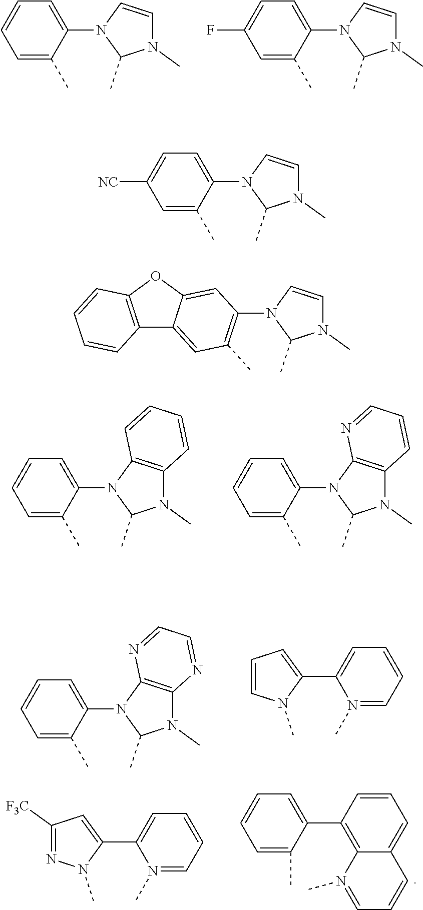

7. The binuclear metal platinum complex according to claim 1, wherein, in formula I, 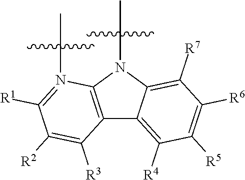
comprises the following structures:

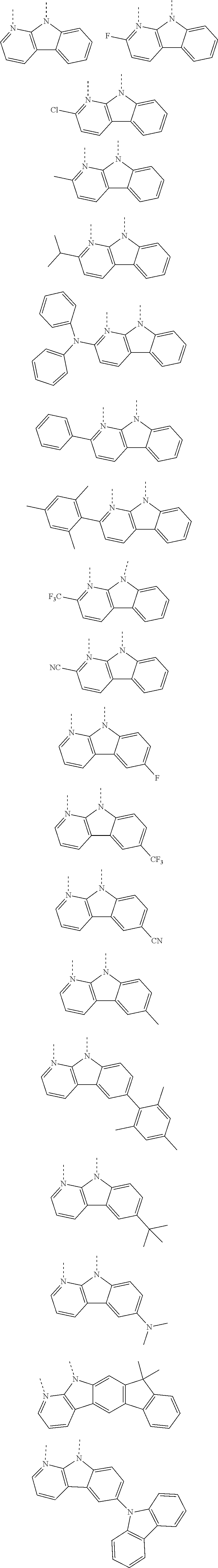

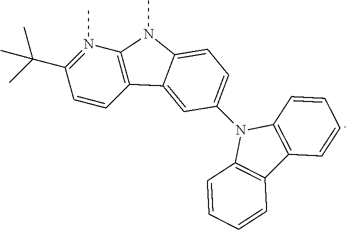

8. The binuclear metal platinum complex according to claim 1, having the following structure: 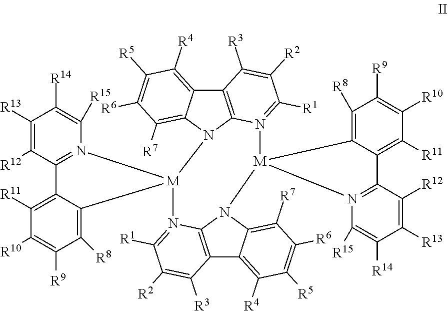
wherein, M is platinum metal;
R¹ to R¹⁵ are the same or different and are each independently selected from hydrogen, deuterium, a heteroatom-containing substituent, a C₁-C₄₀ alkyl, a C₁-C₄₀ alkoxy, a C₂-C₄₀ alkenyl, a C₂-C₄₀ alkynyl, a C₆-C₄₈ aryl and a C₅-C₄₈ heteroaryl; or
adjacent two of R¹ to R¹⁵ are connected with each other to form a C₃-C₁₀ cycloalkyl, a C₆-C₃₀ aryl or a C₅-C₃₀ heteroaryl.

9. The binuclear metal platinum complex according to claim 8, wherein, R¹ to R¹⁵ are the same or different and are each independently selected from hydrogen, deuterium, a halogen, a C₁-C₁₀ alkyl, a C₁-C₁₀ alkoxy, and a C₆-C₃₀ aryl; or
adjacent two of R¹ to R¹⁵ are connected with each other to form a C₆-C₃₀ aryl.

10. The binuclear metal platinum complex according to claim 9, wherein, the halogen is selected from fluorine, chlorine, bromine and iodine;
the C₁-C₁₀ alkyl is selected from methyl, ethyl, n-propyl, isopropyl, n-butyl, isobutyl, sec-butyl and tert-butyl;
the C₁-C₁₀ alkoxy is selected from methoxy and ethoxy; and
the C₆-C₃₀ aryl is selected from phenyl, naphthyl and anthryl.

11. The binuclear metal platinum complex according to claim 10, wherein, the binuclear metal platinum complex comprises the following structures:

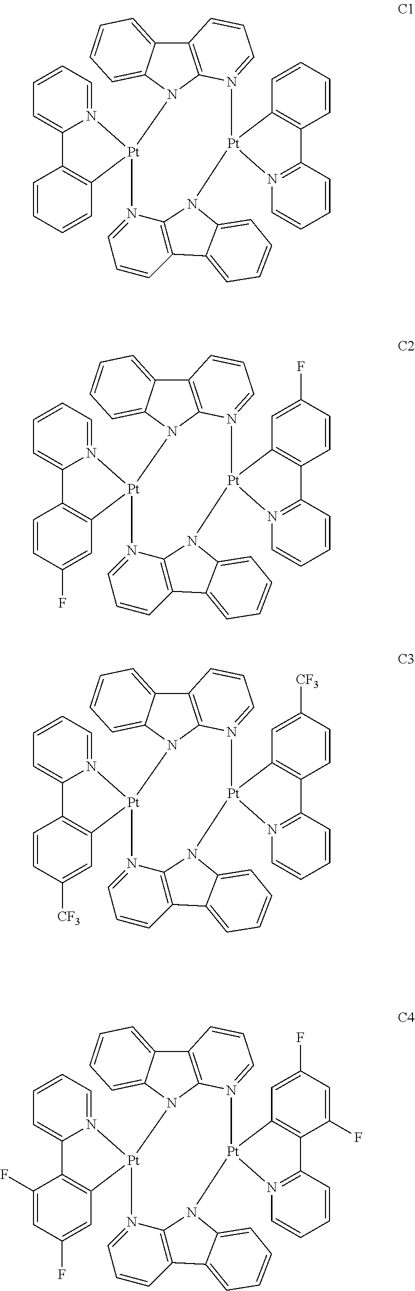

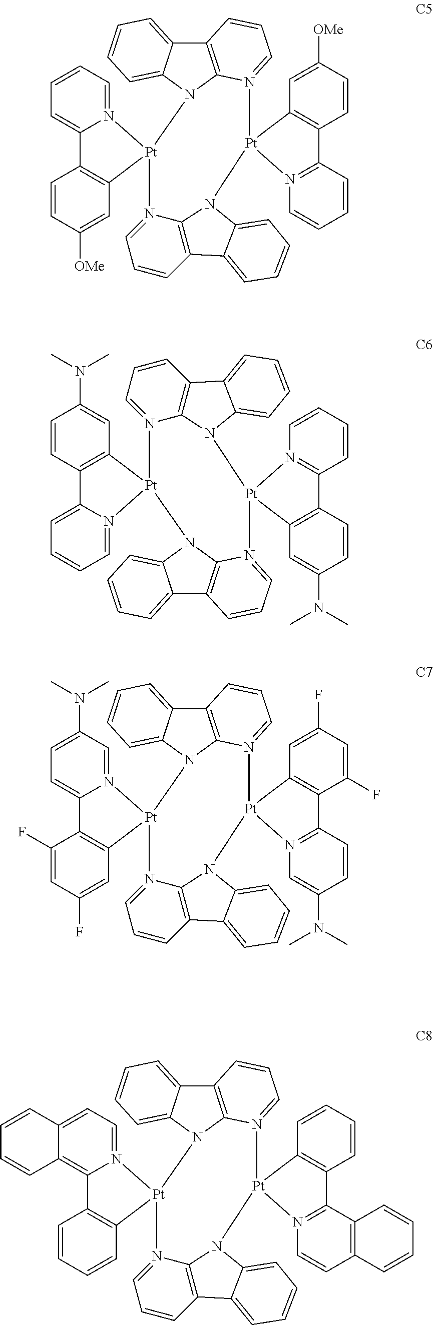

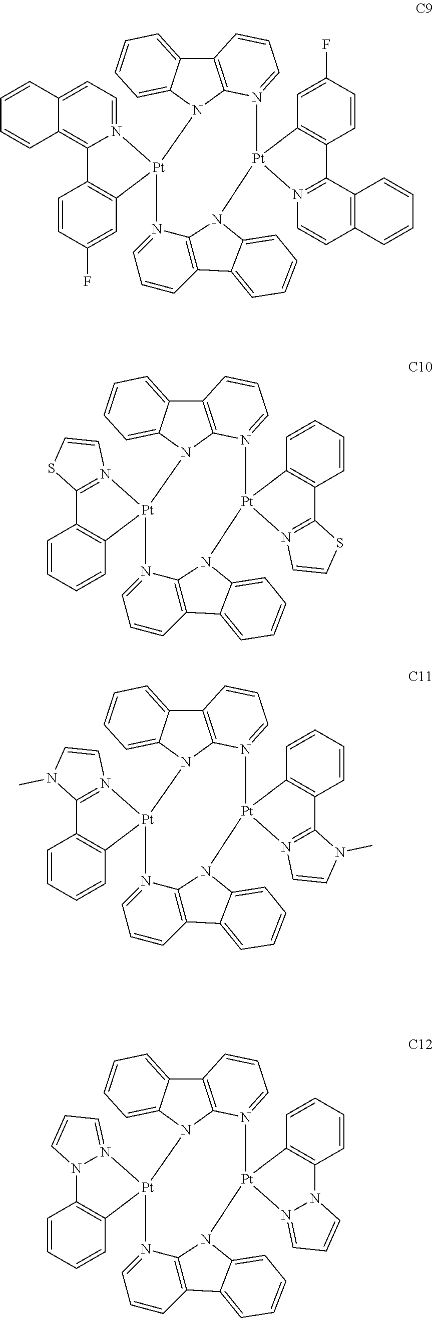

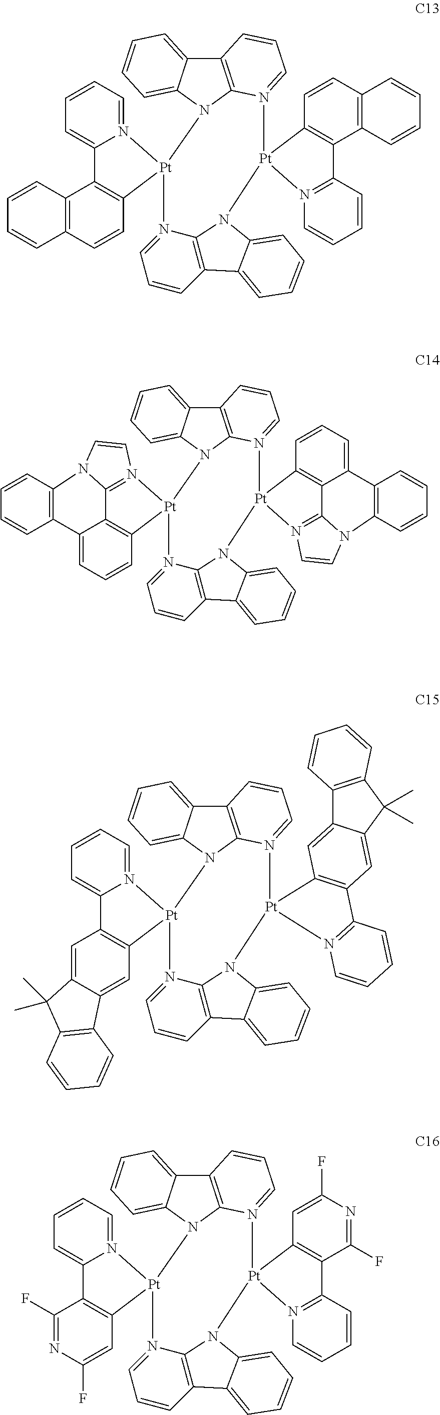

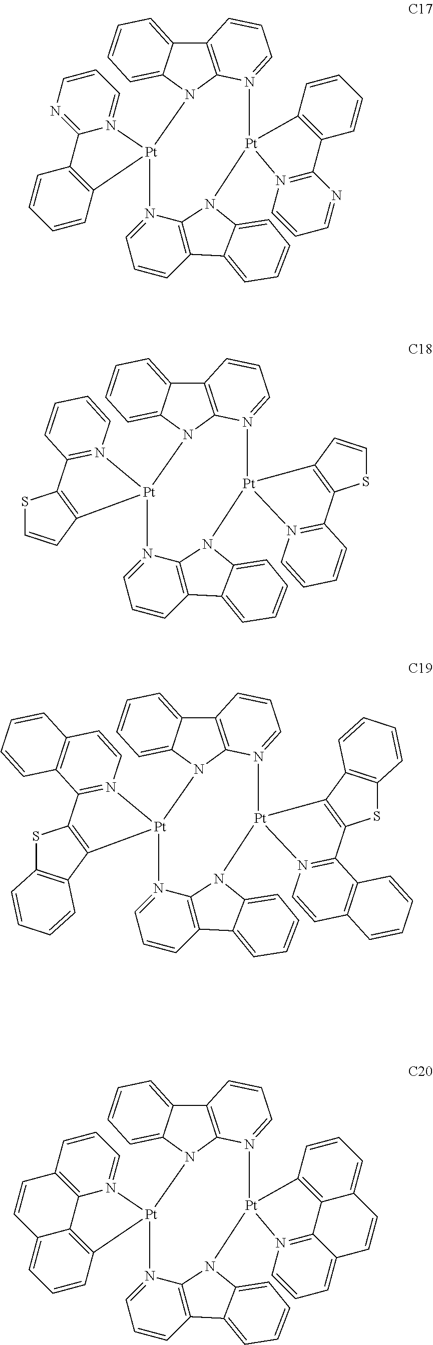

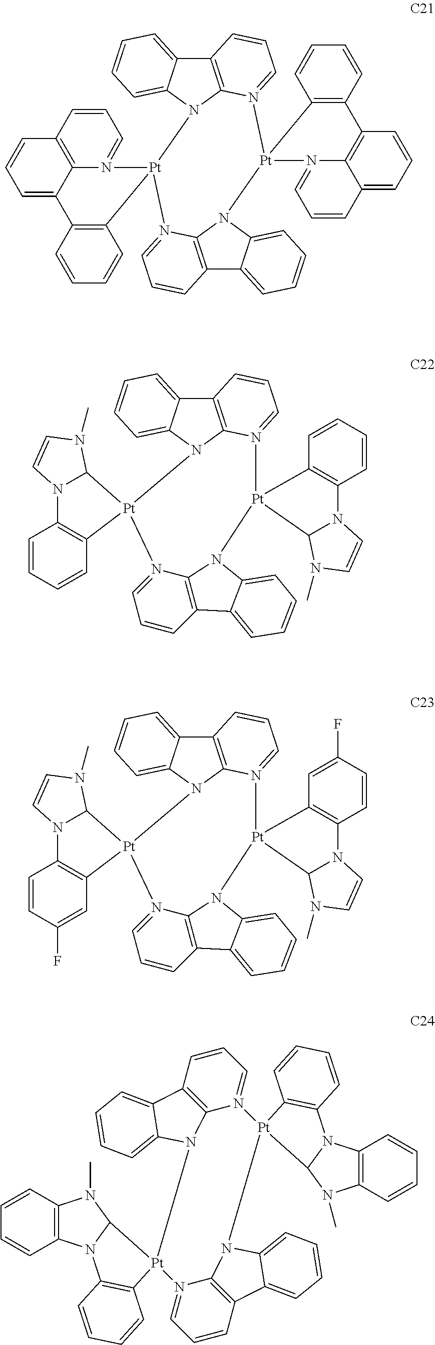

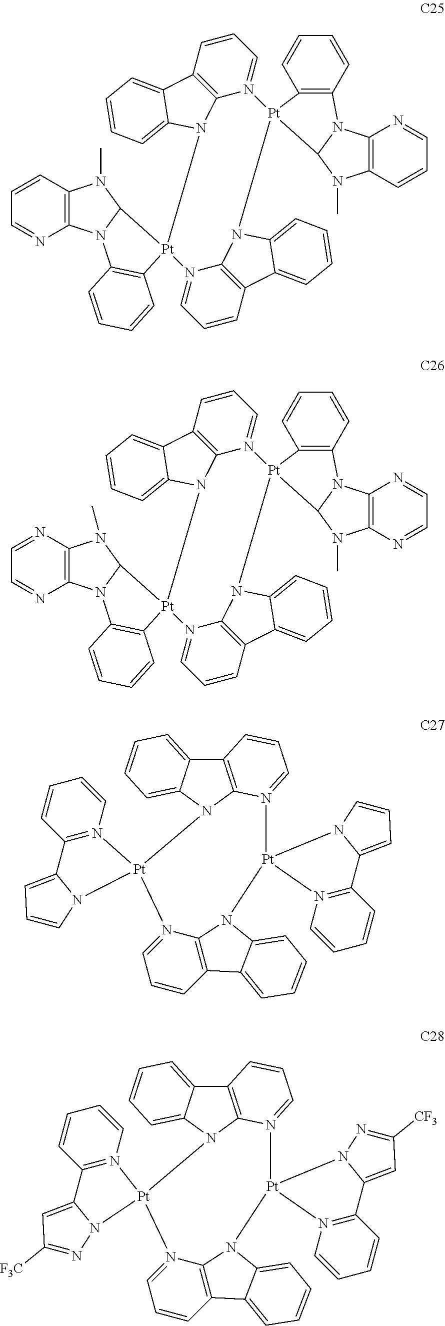

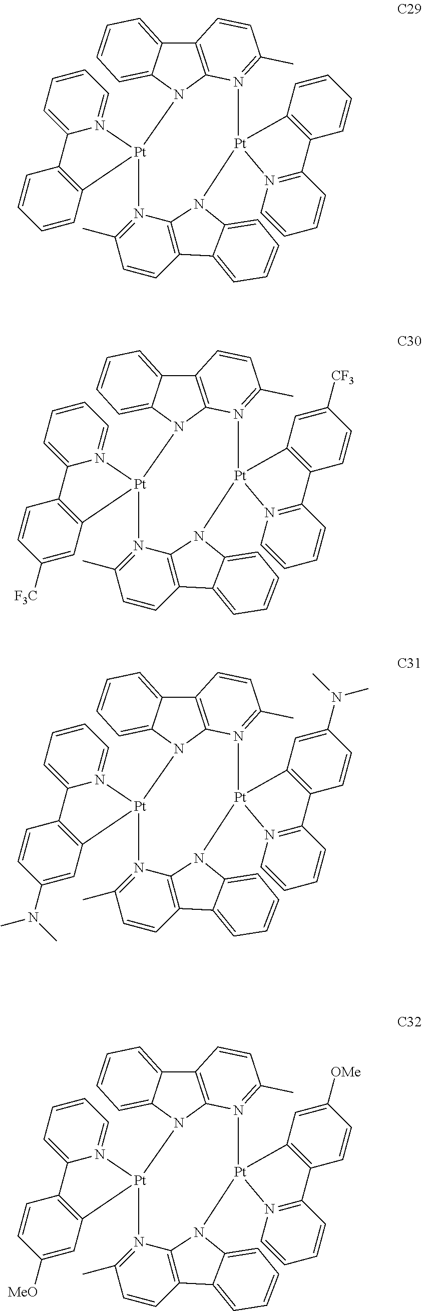

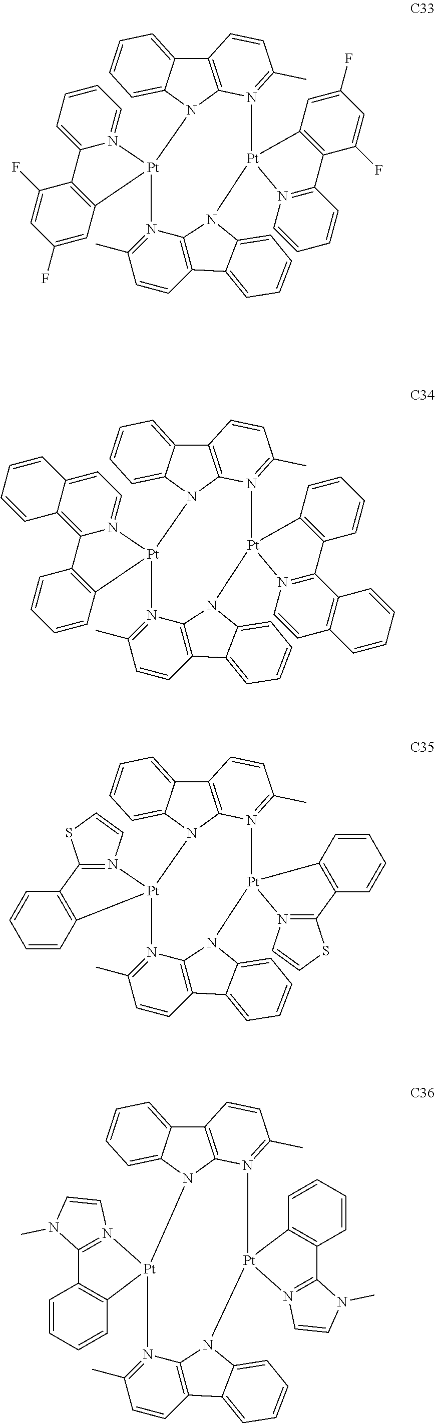

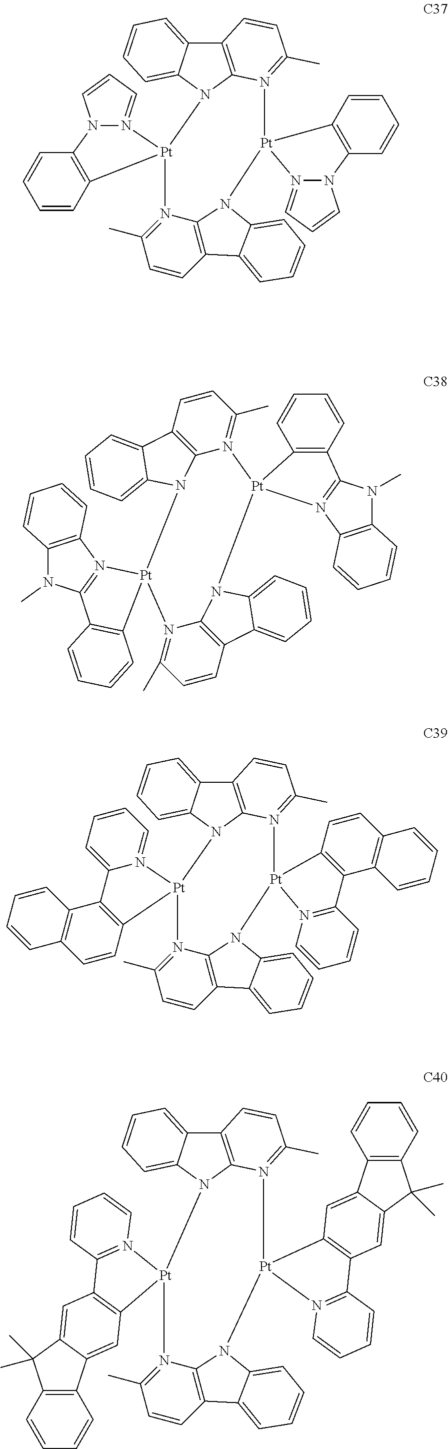

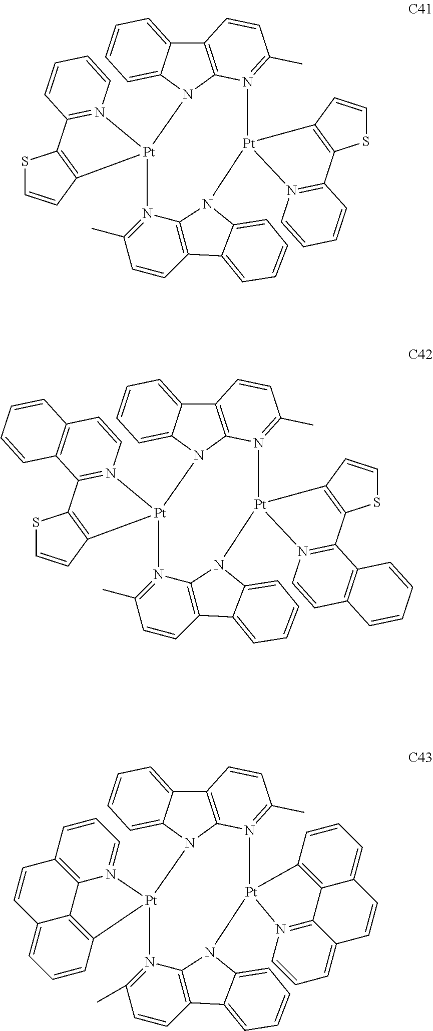

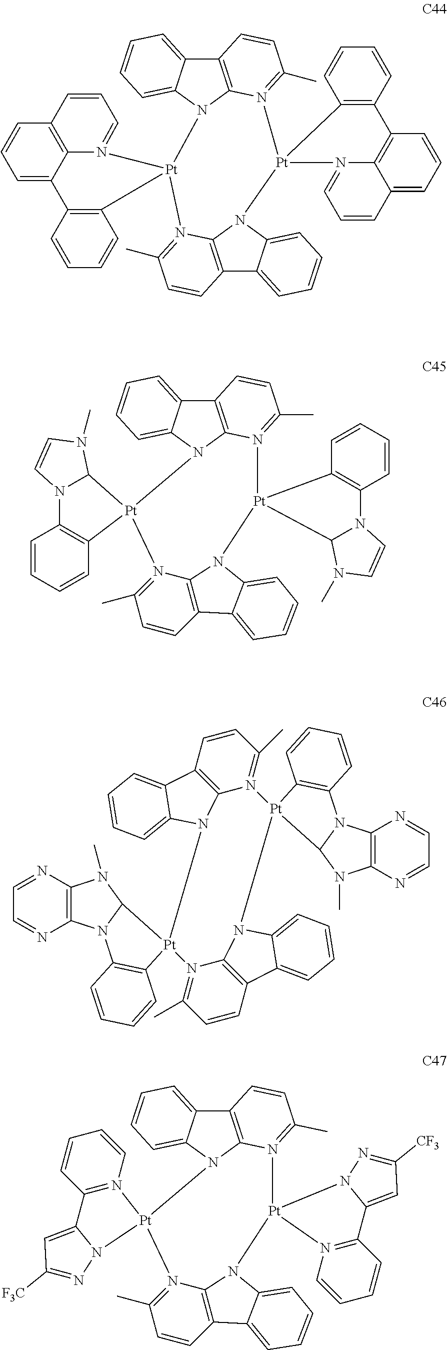

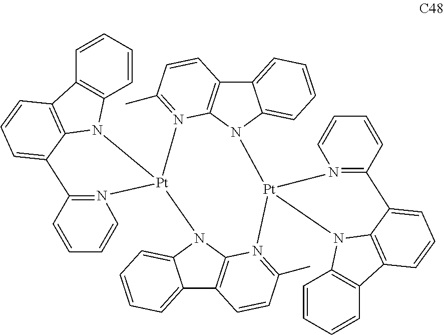

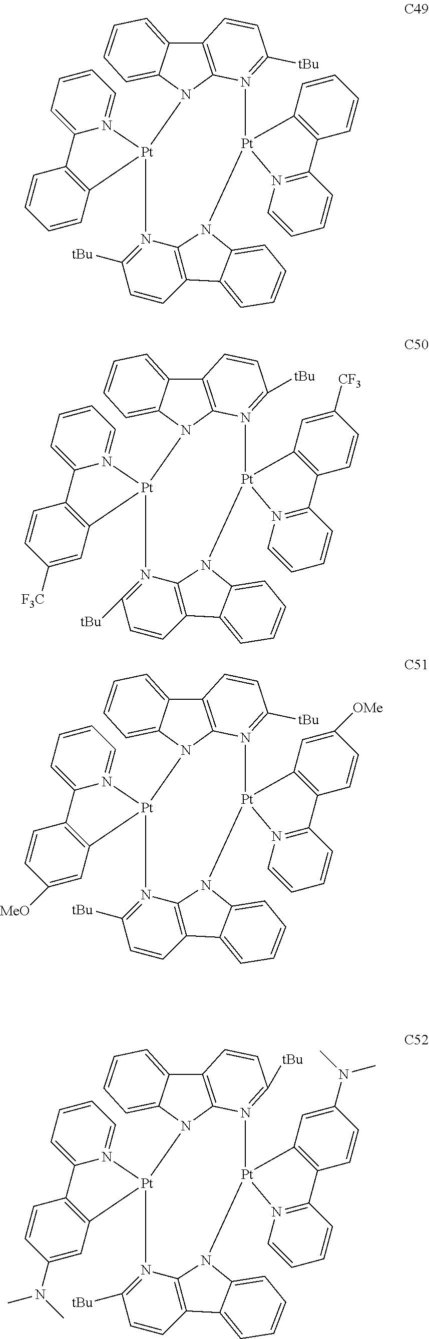

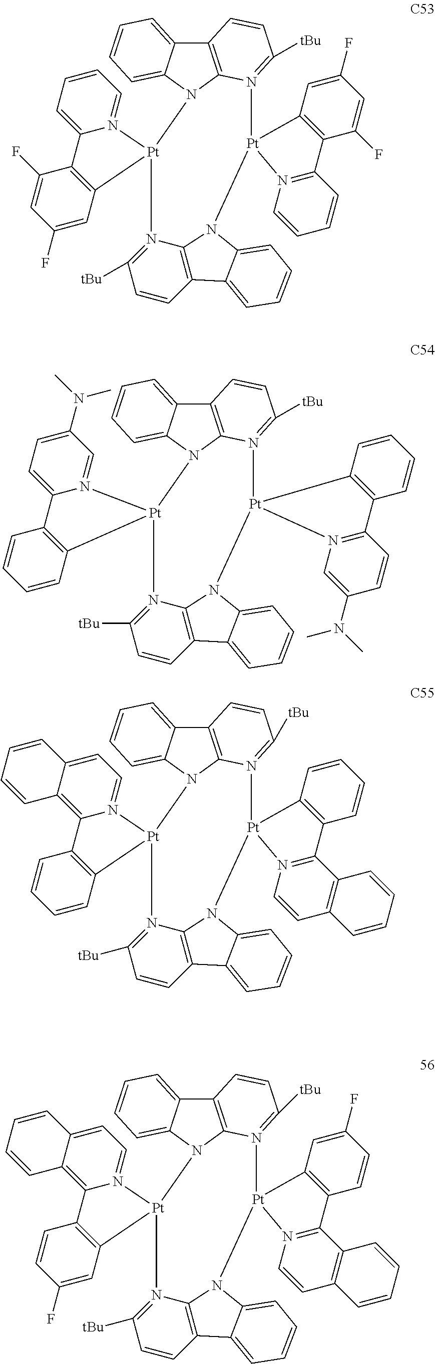

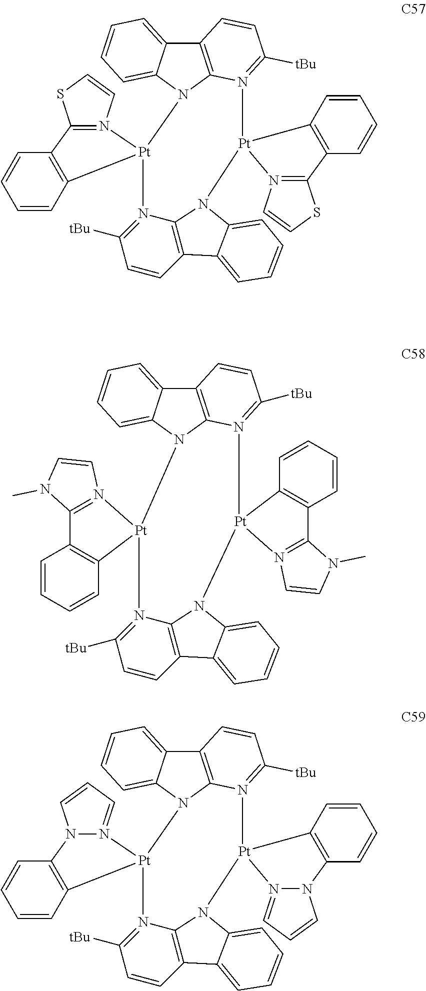

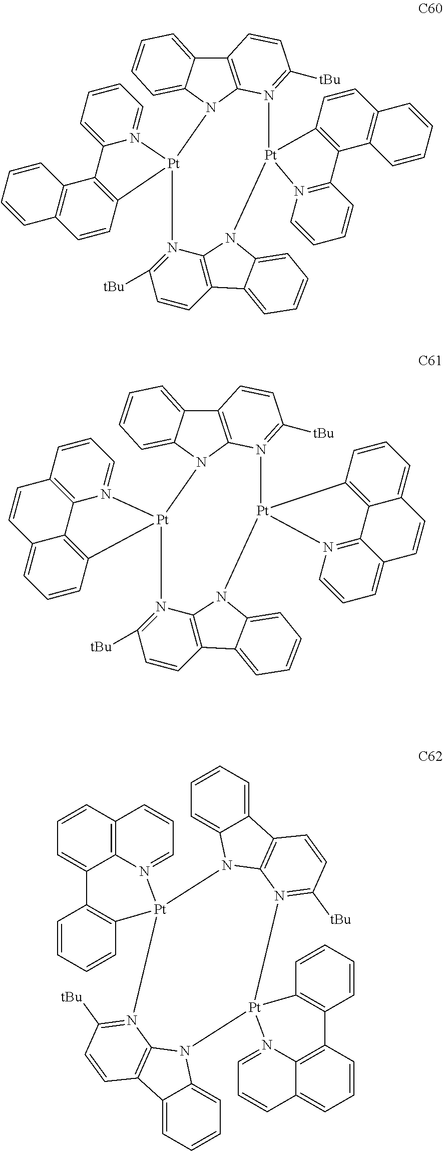

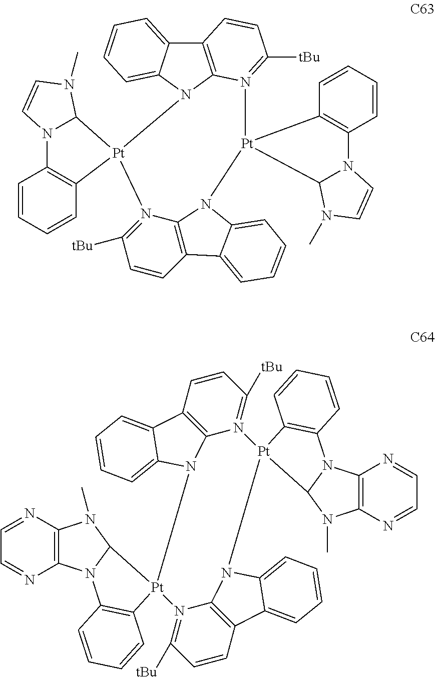

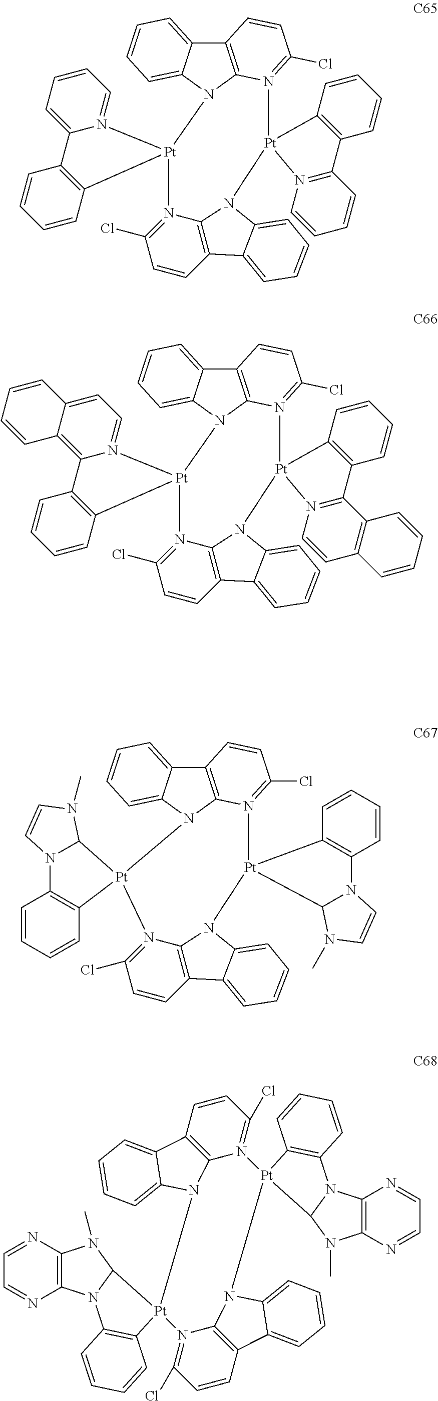

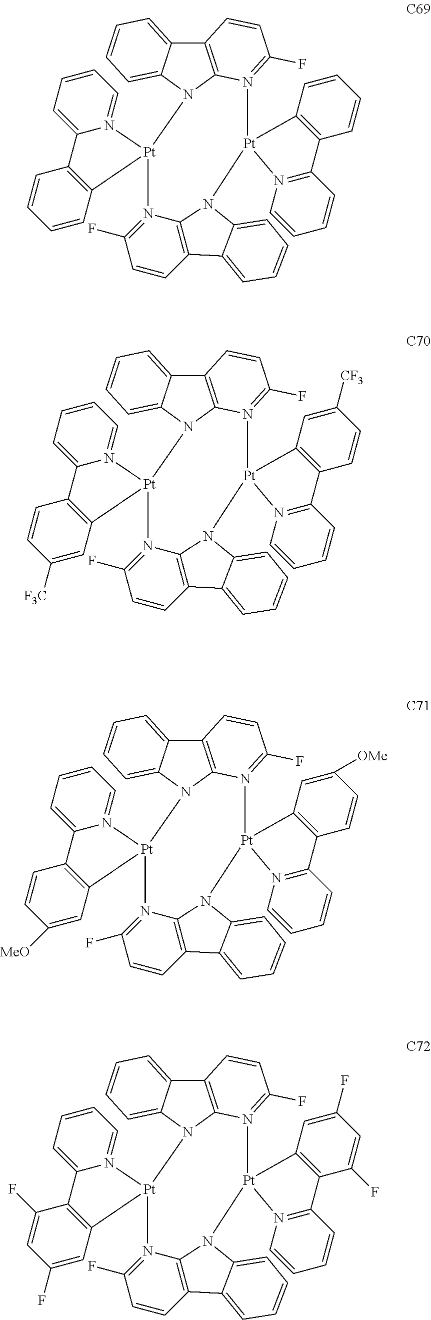

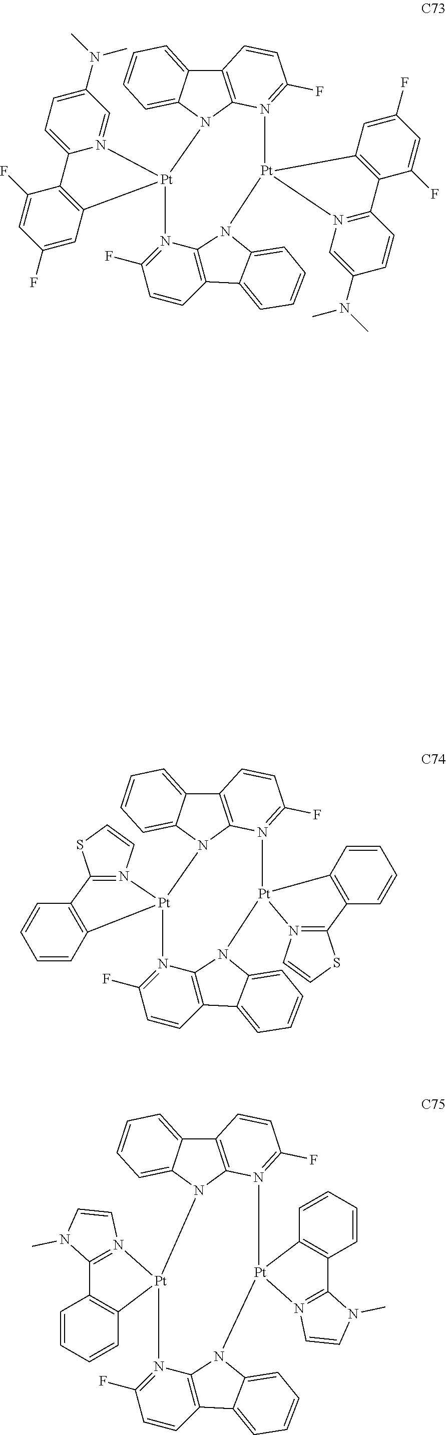

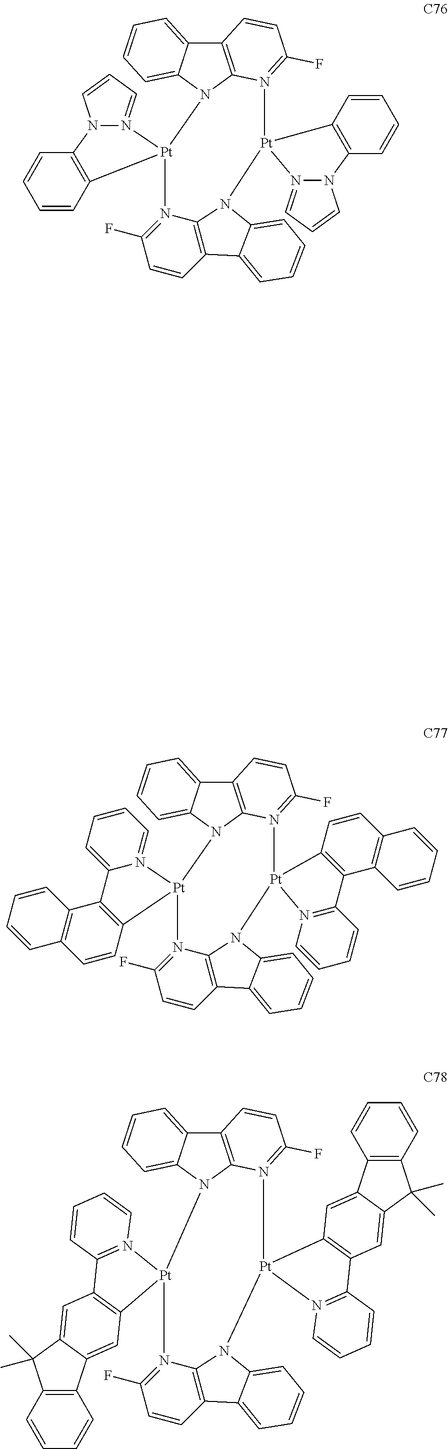

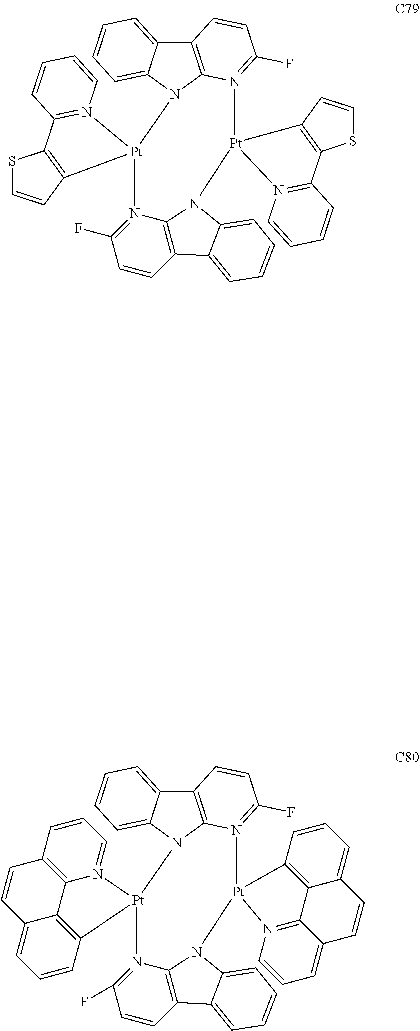

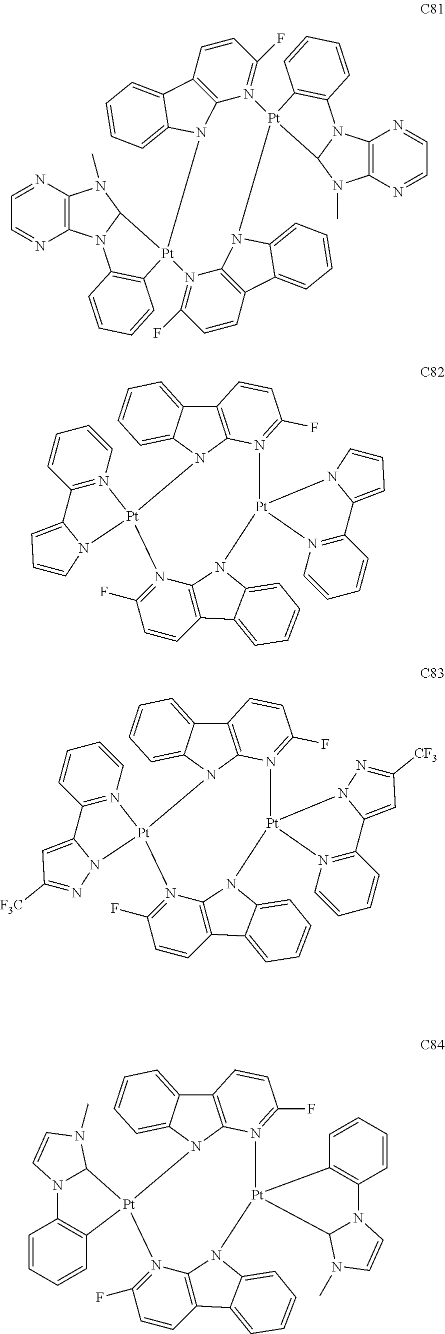

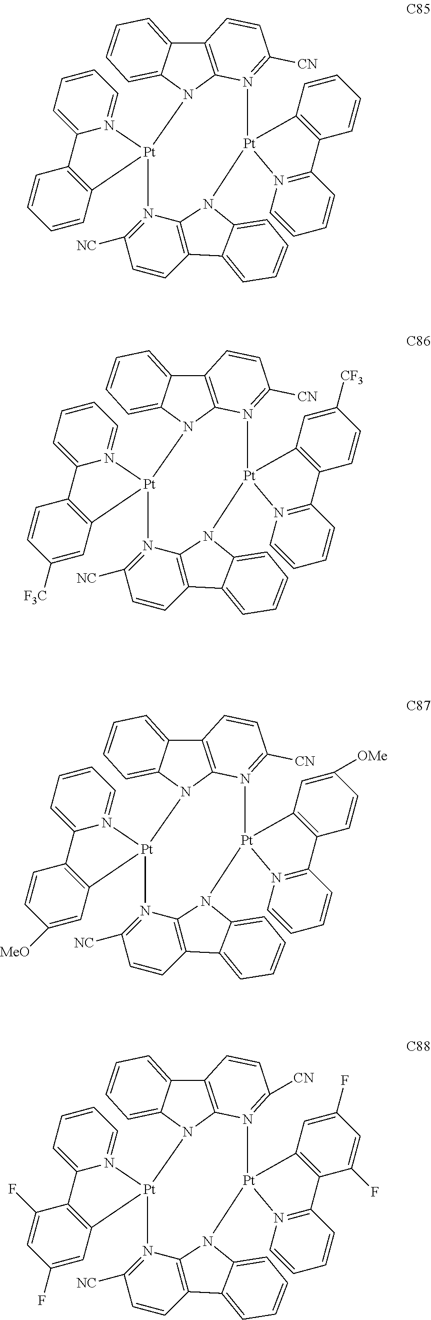

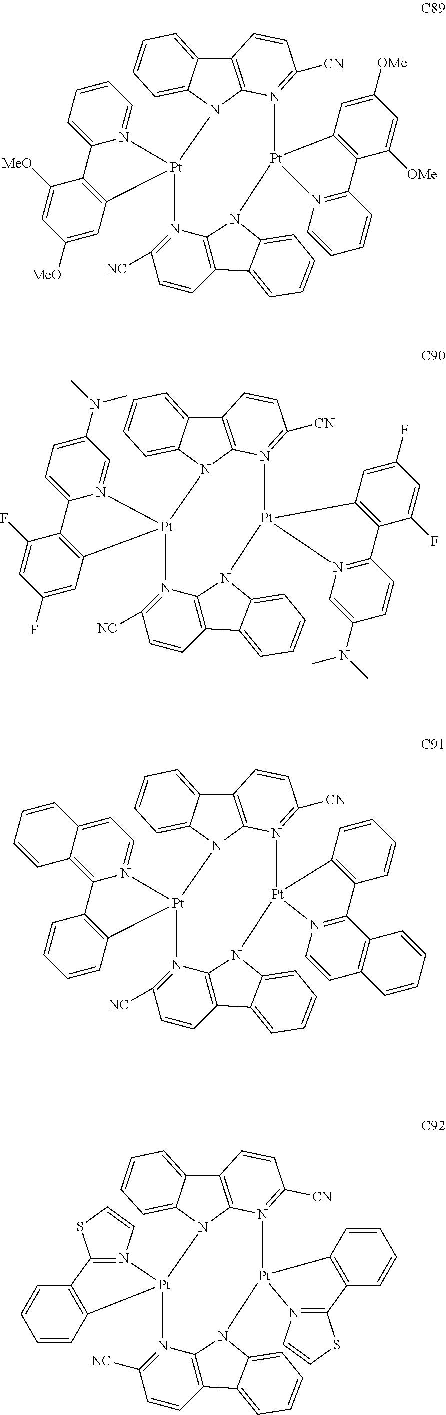

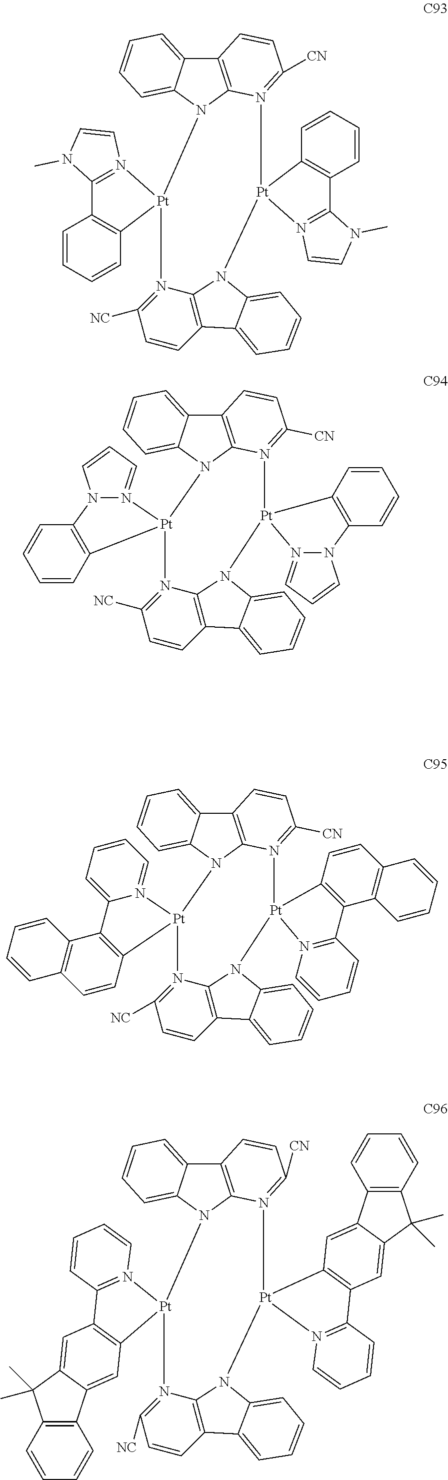

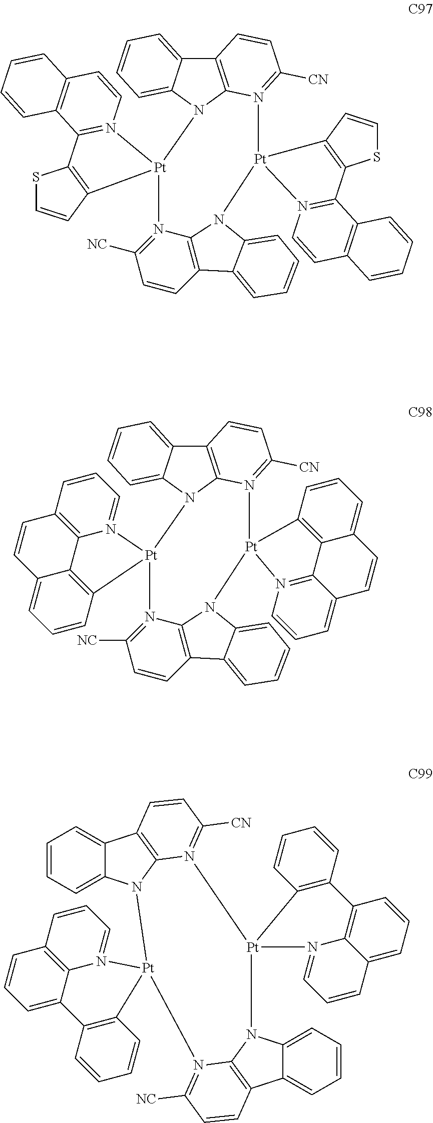

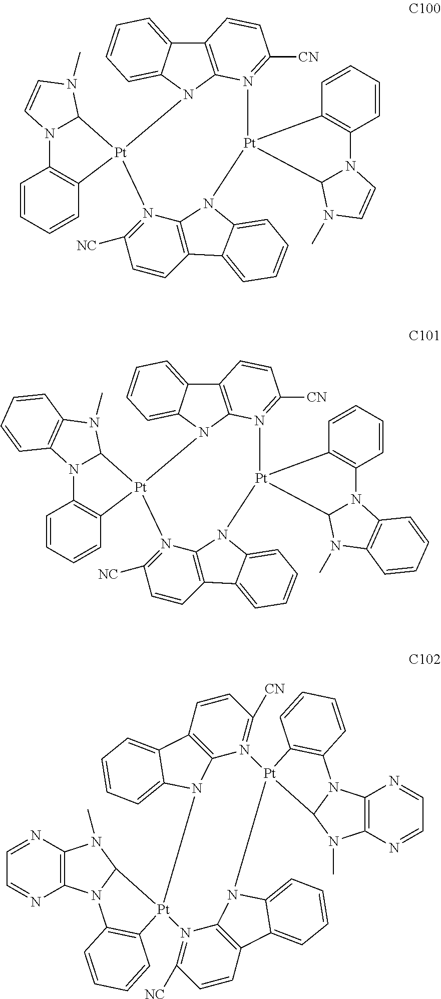

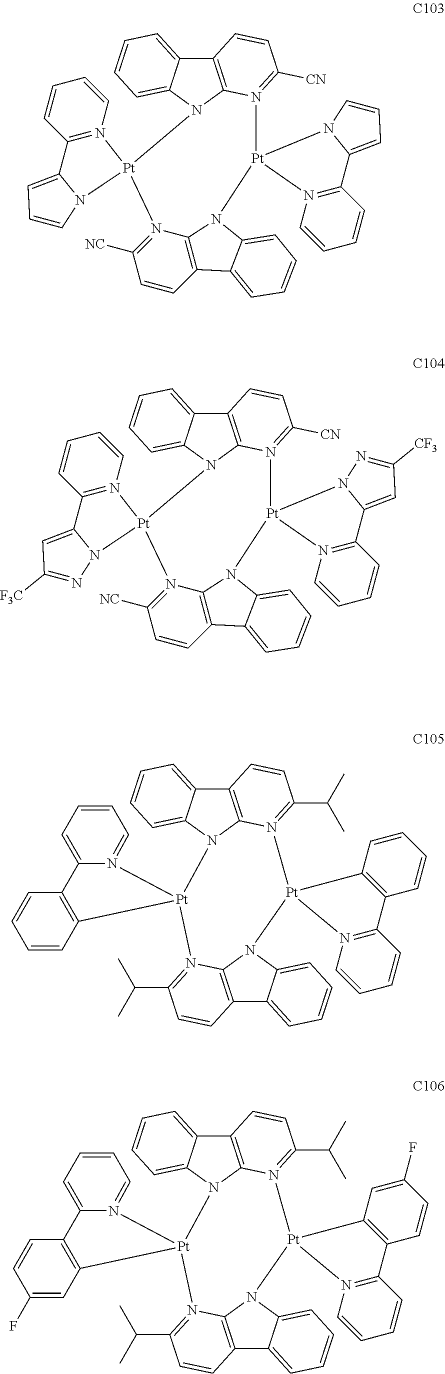

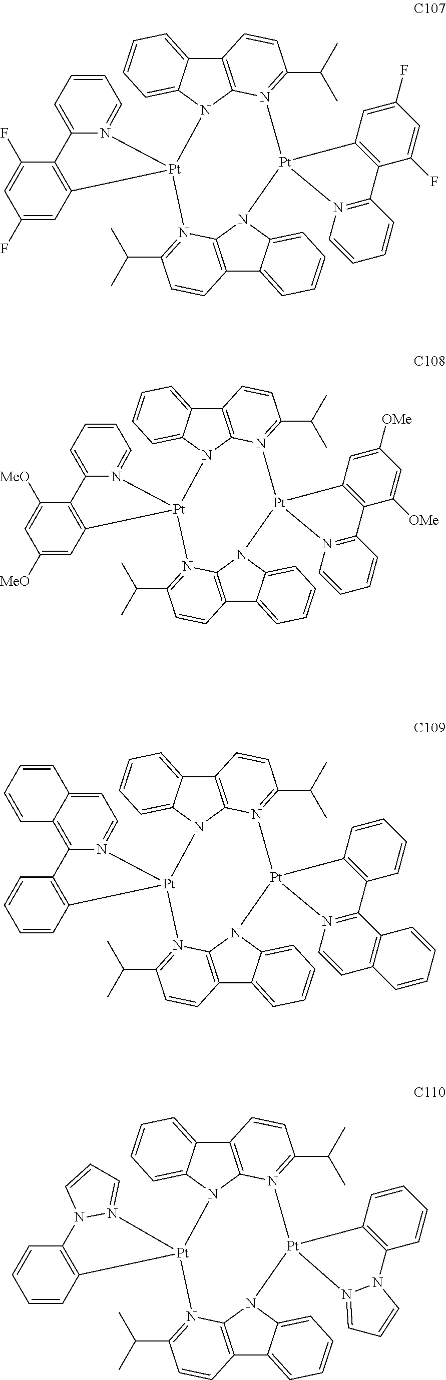

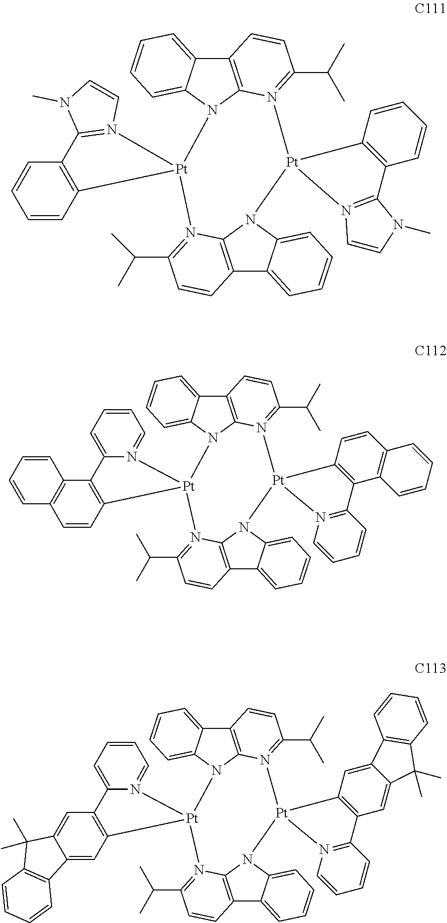

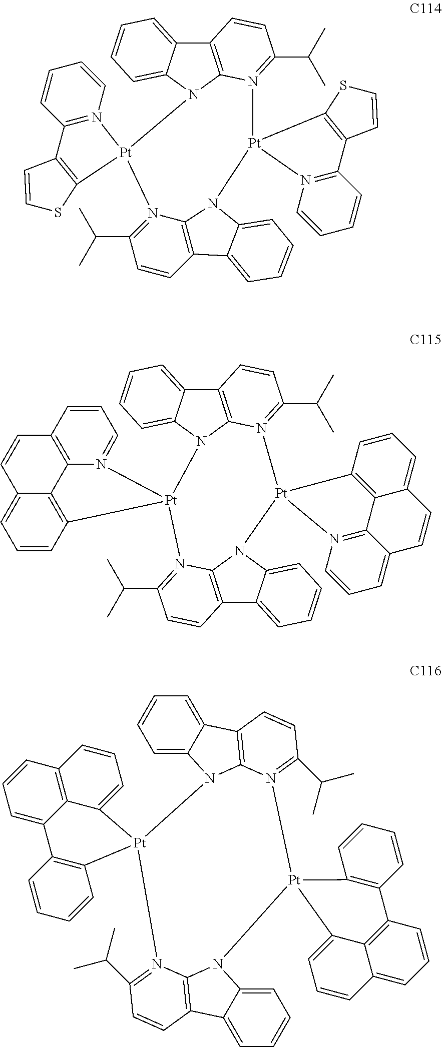

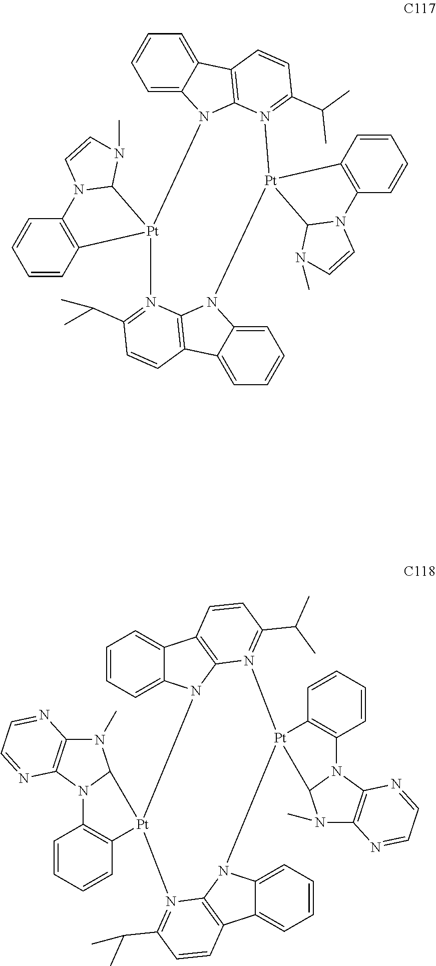

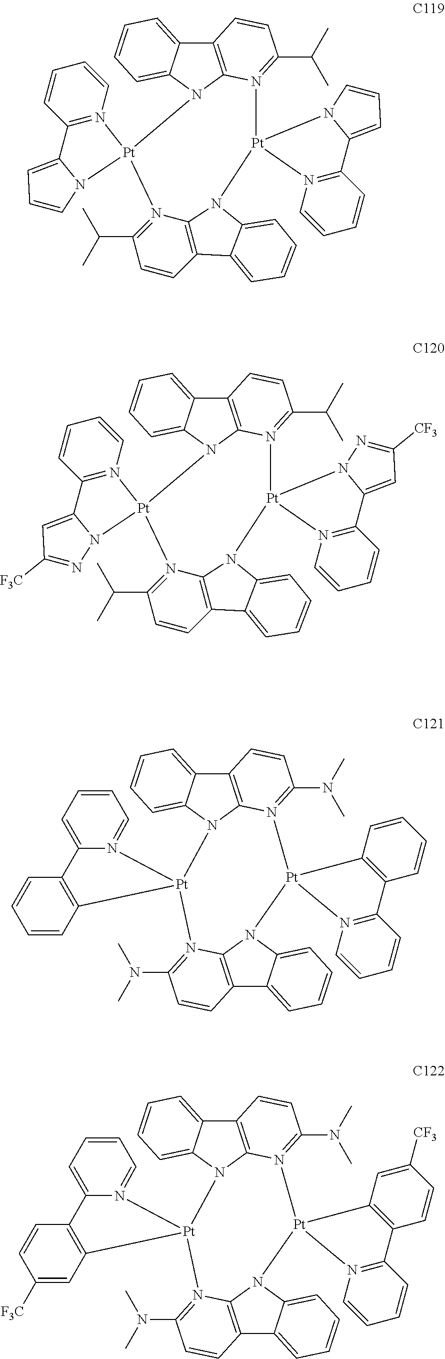

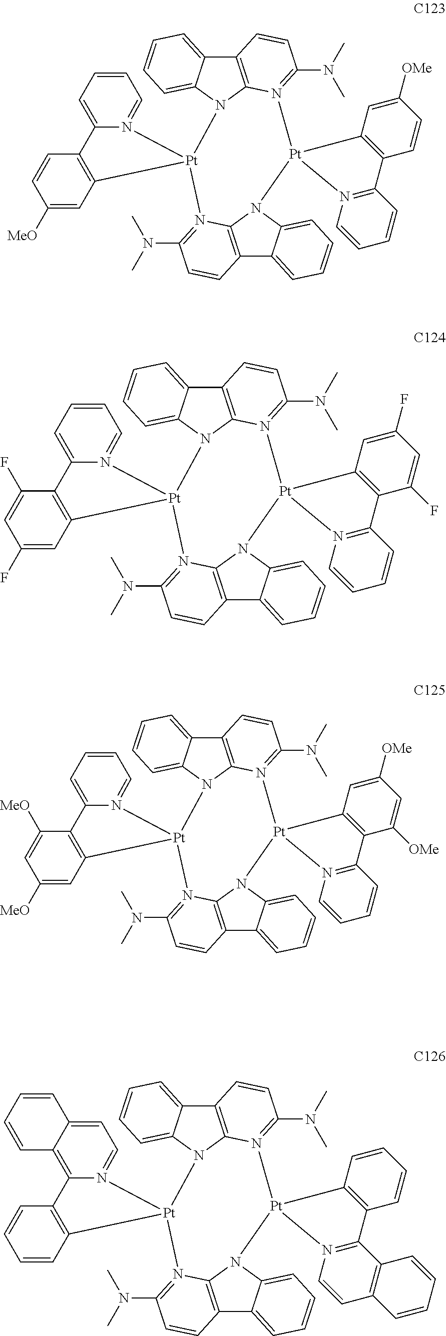

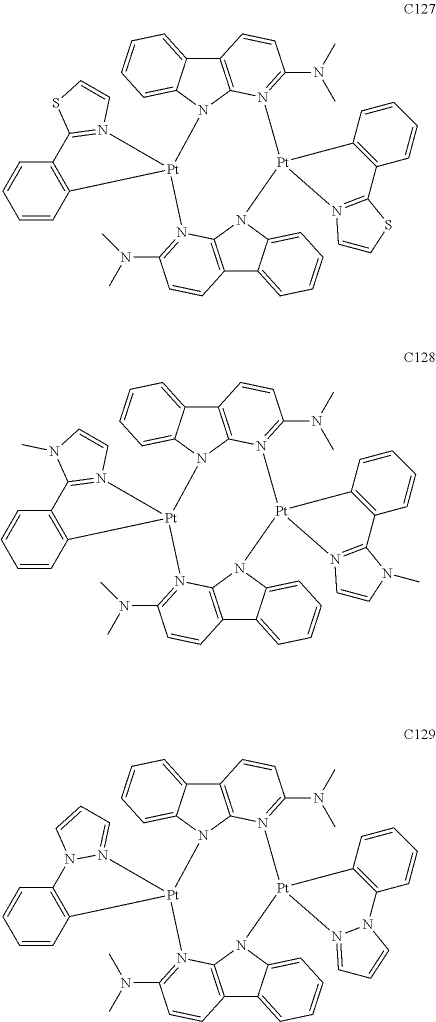

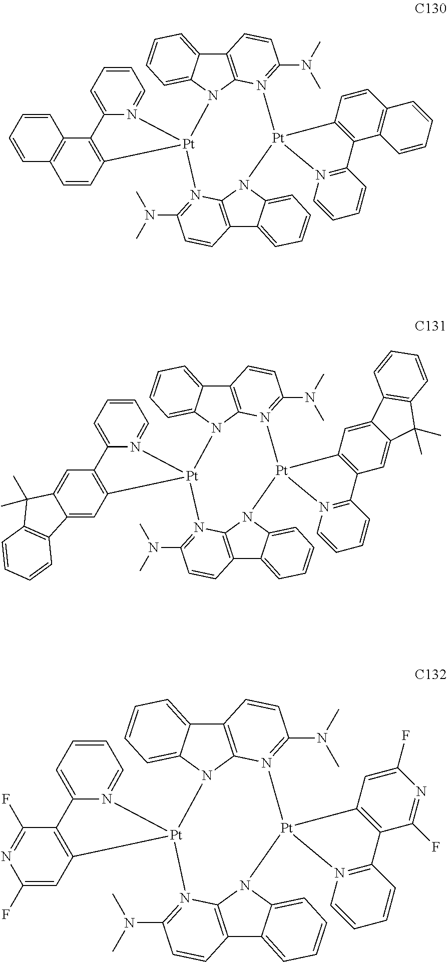

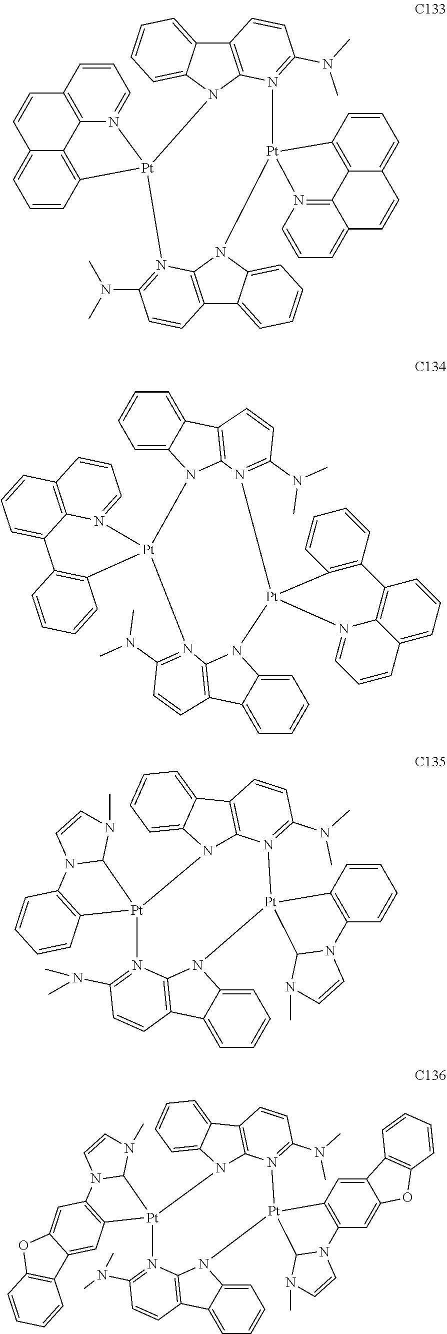

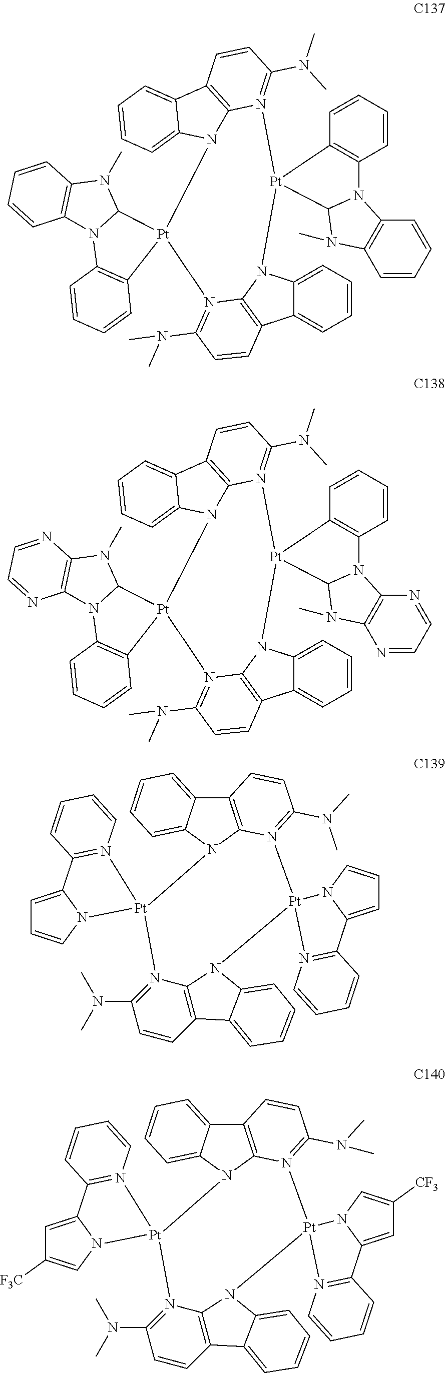

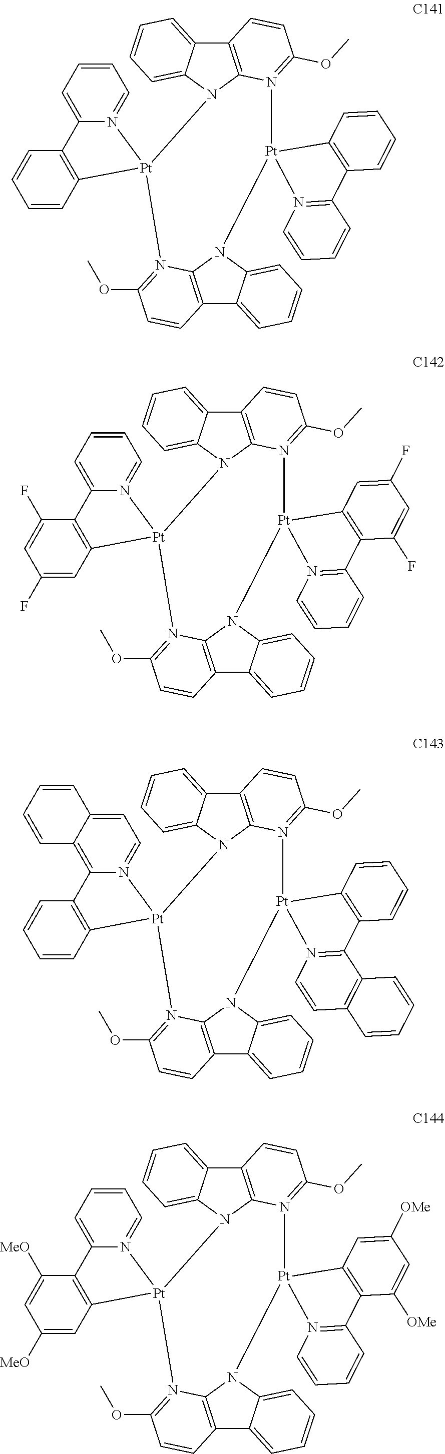

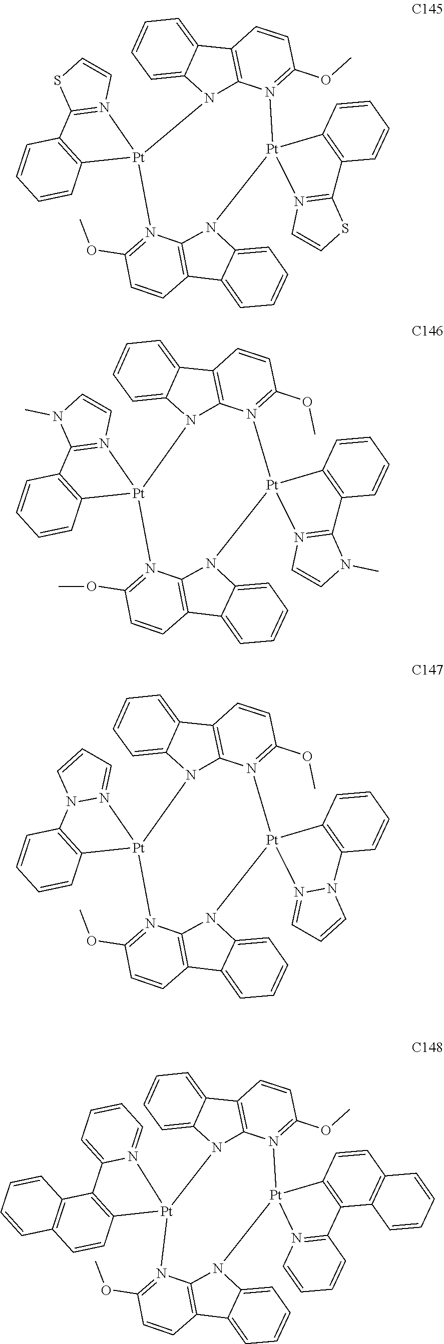

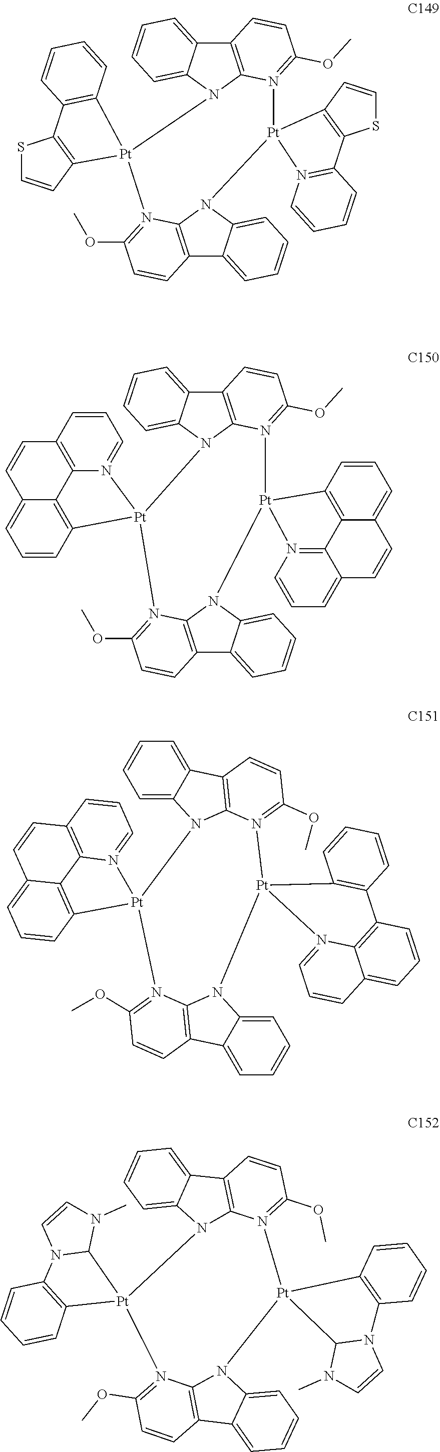

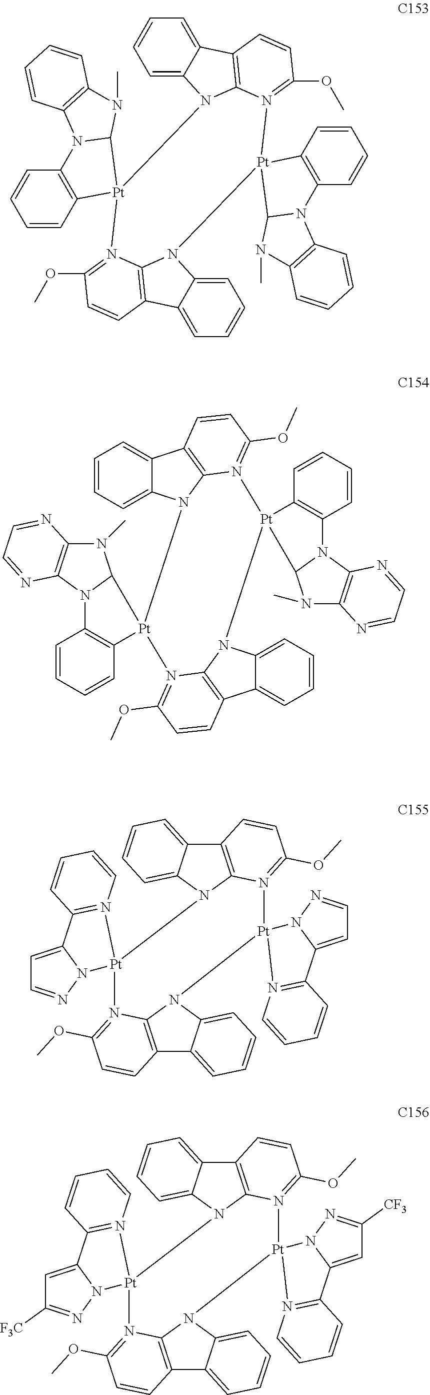

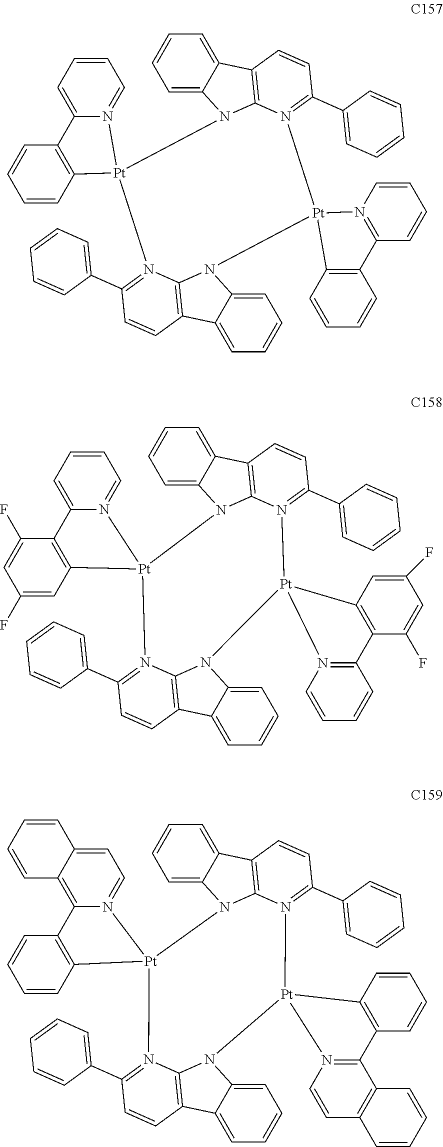

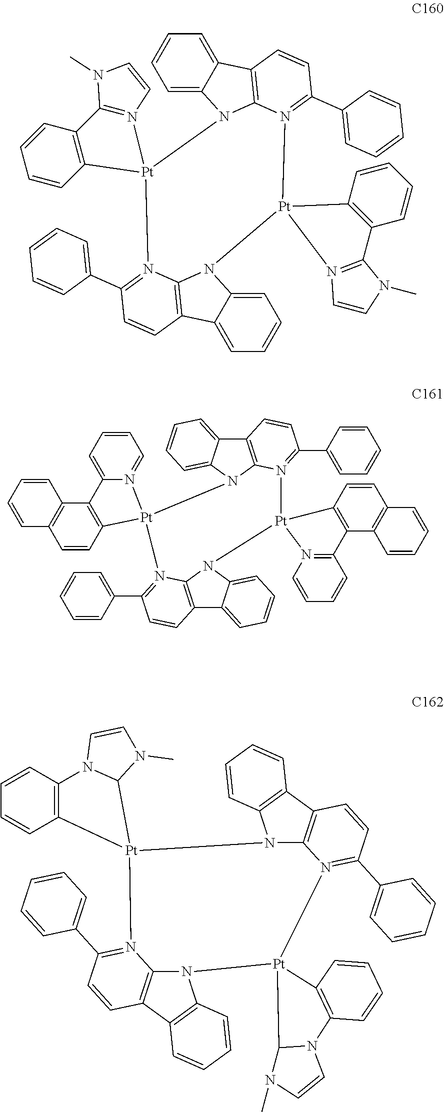

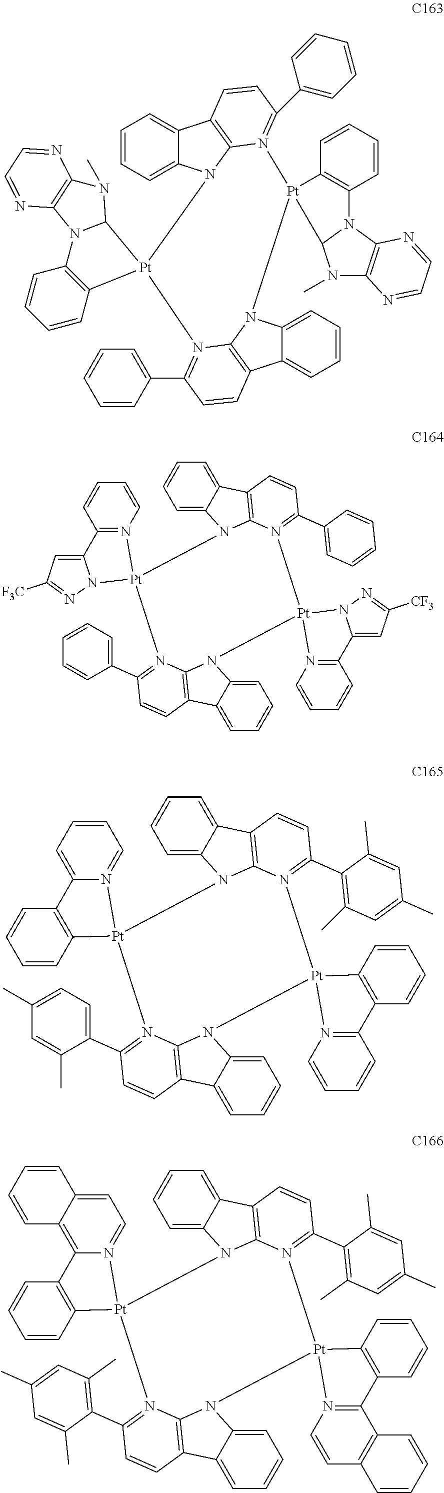

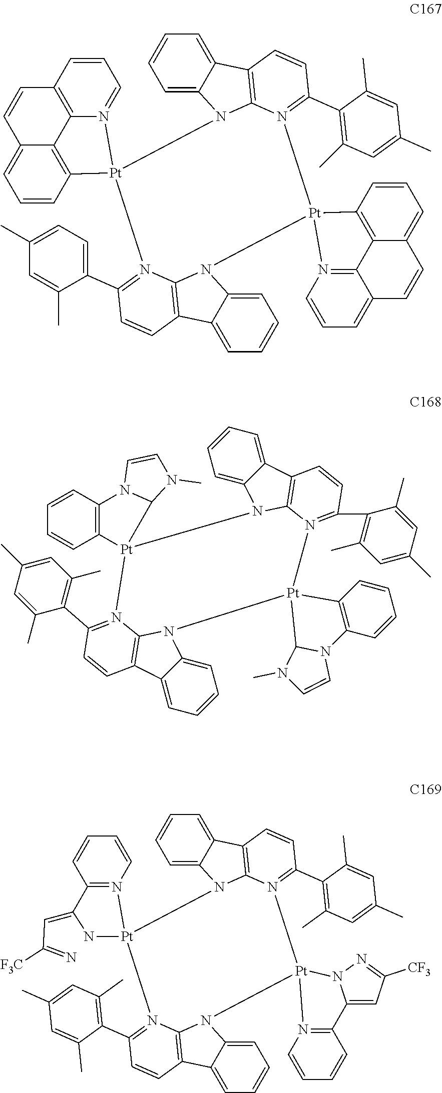

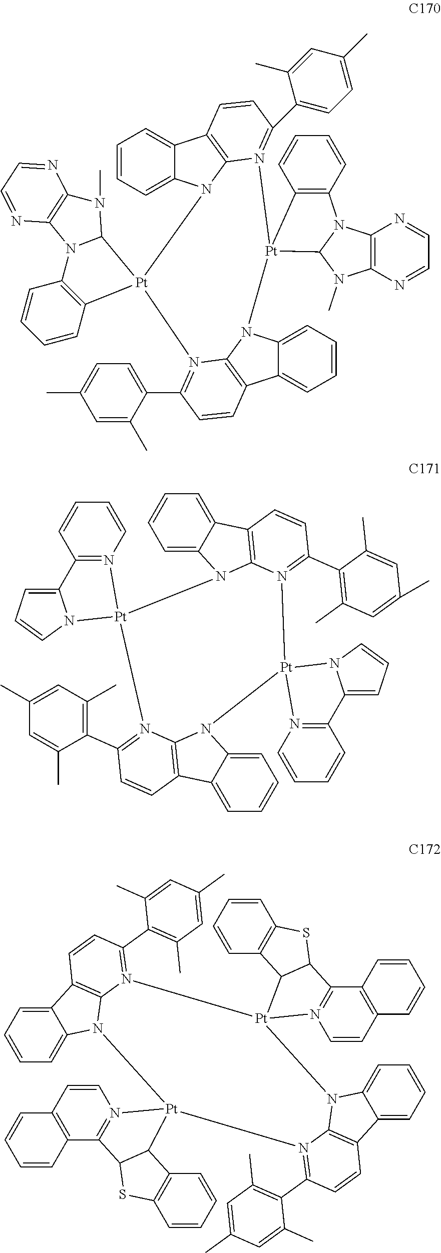

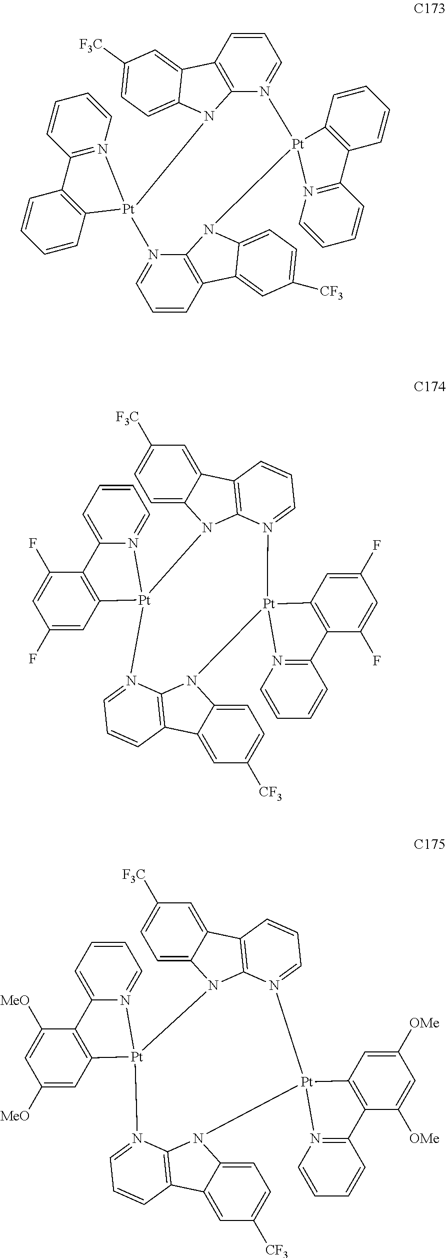

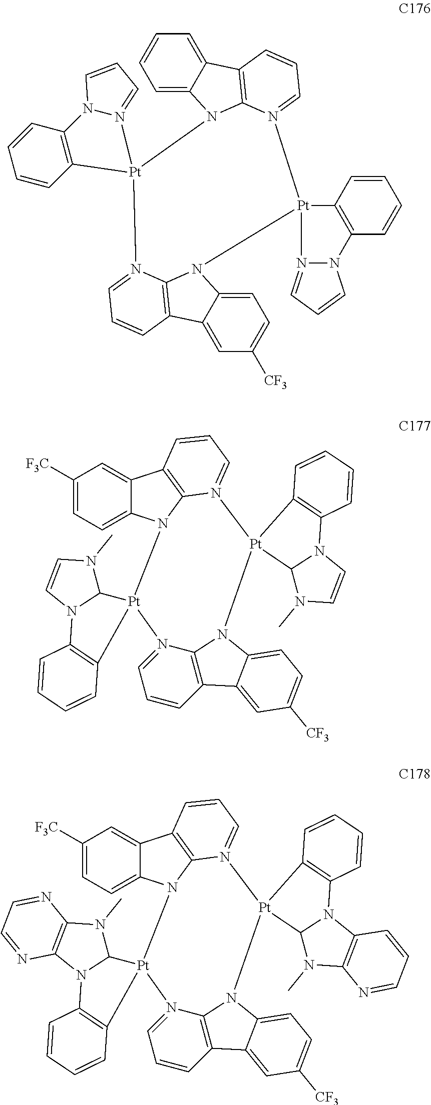

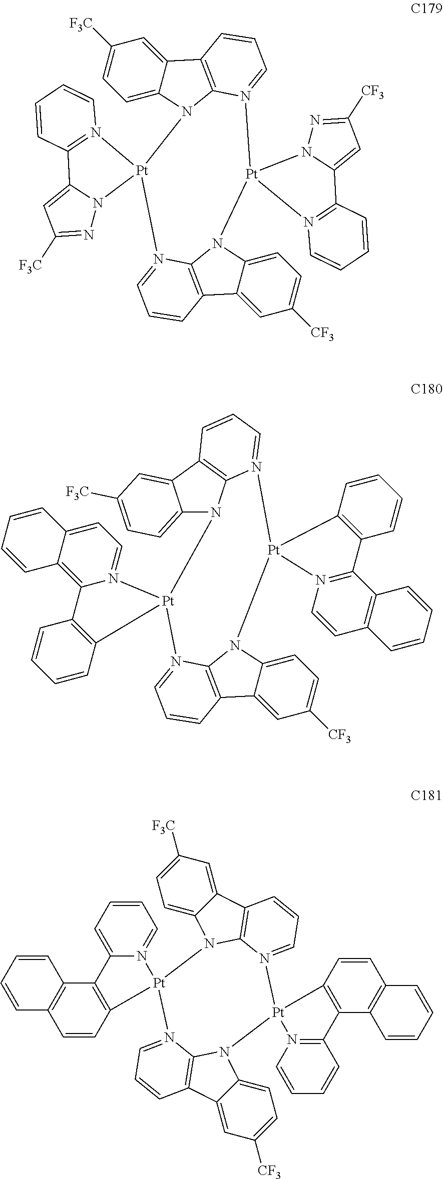

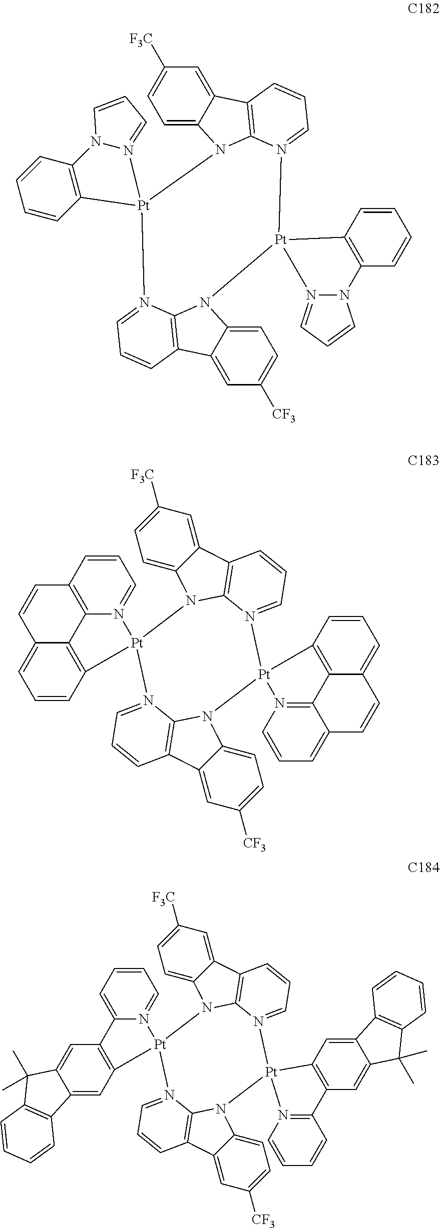

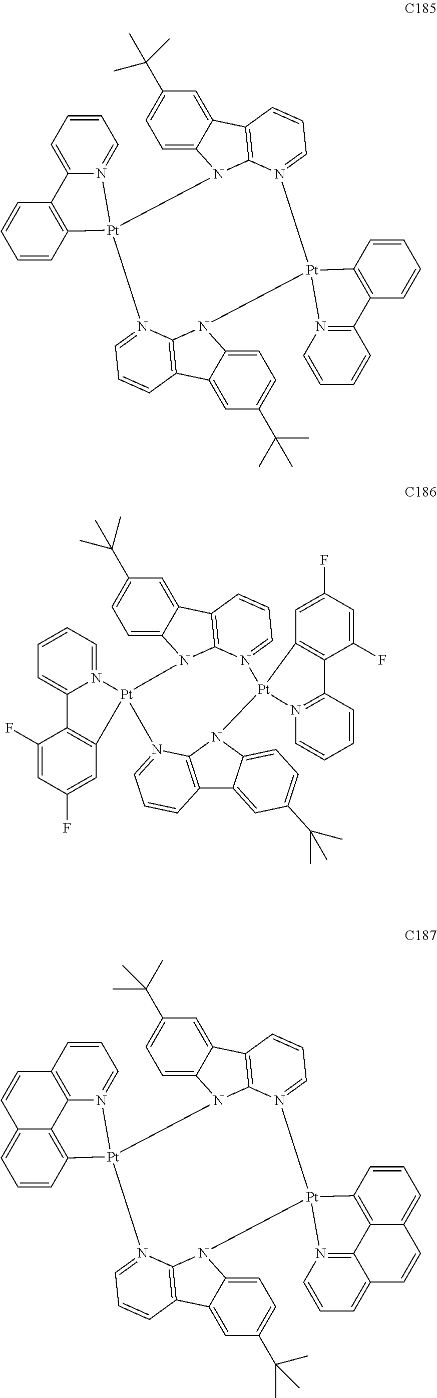

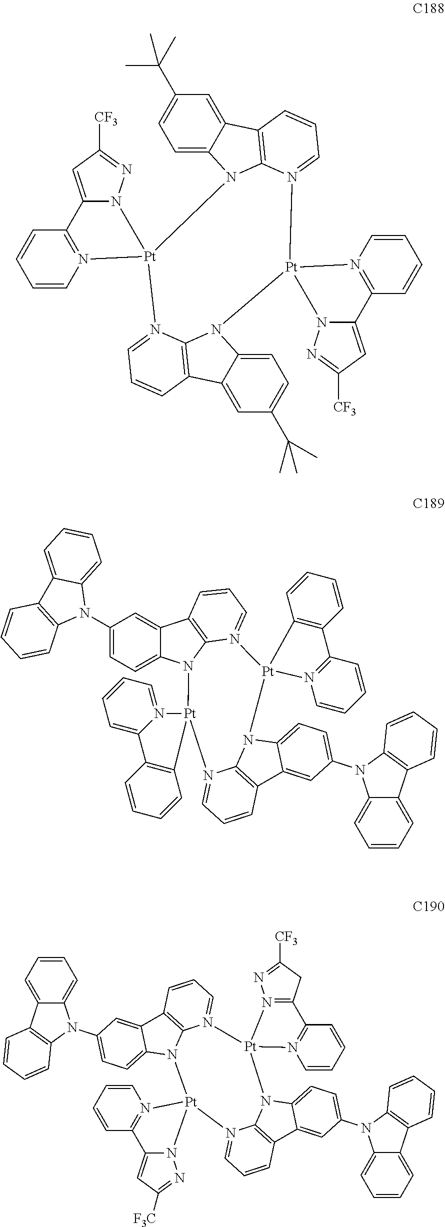

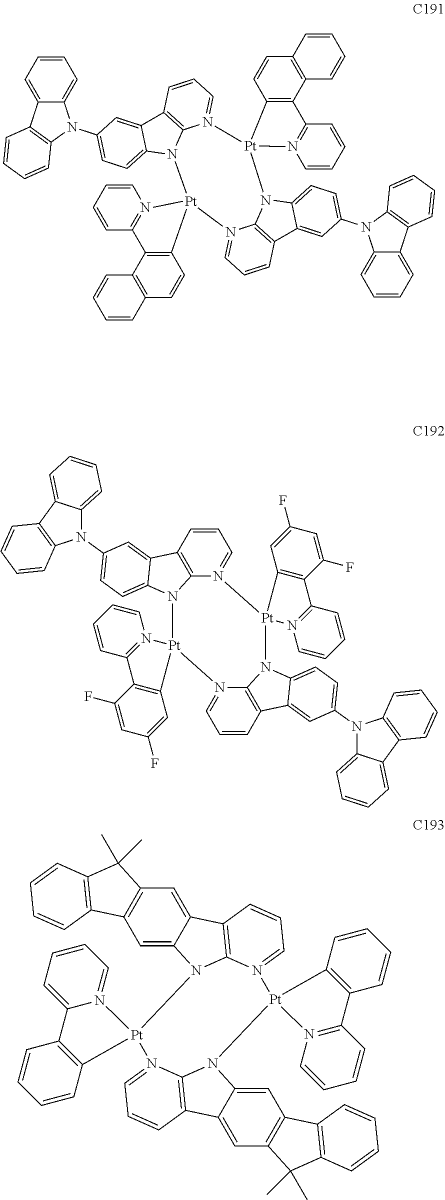

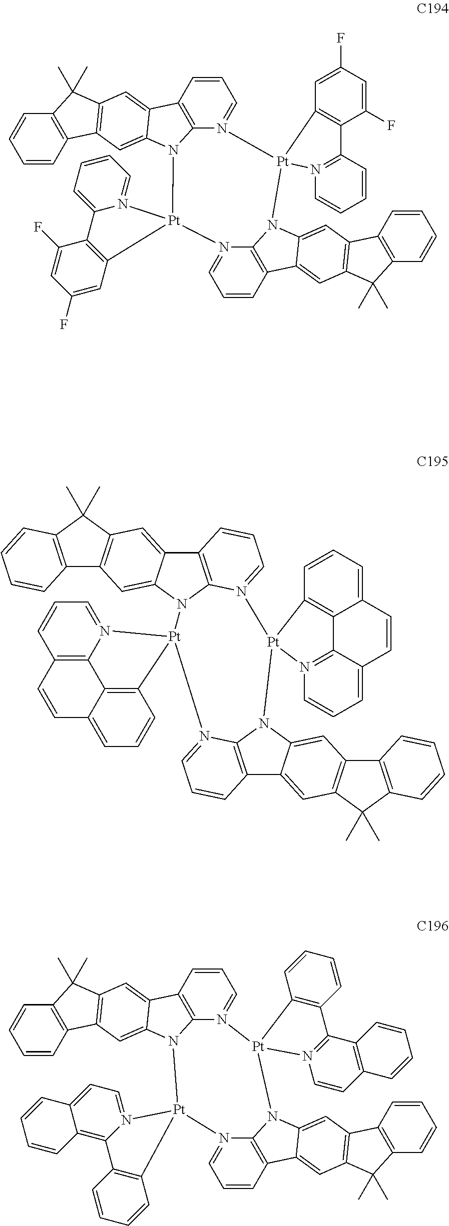

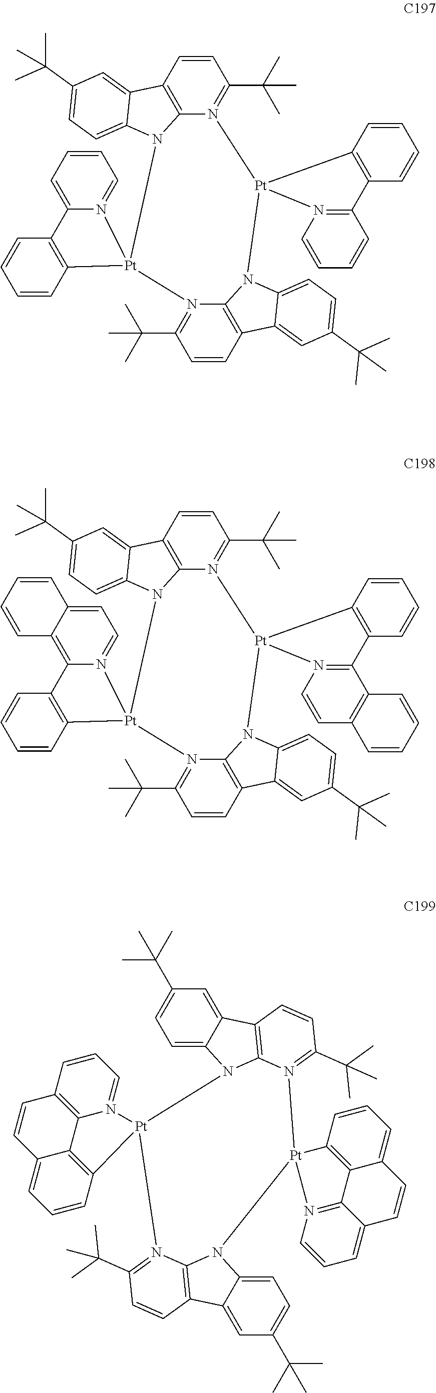

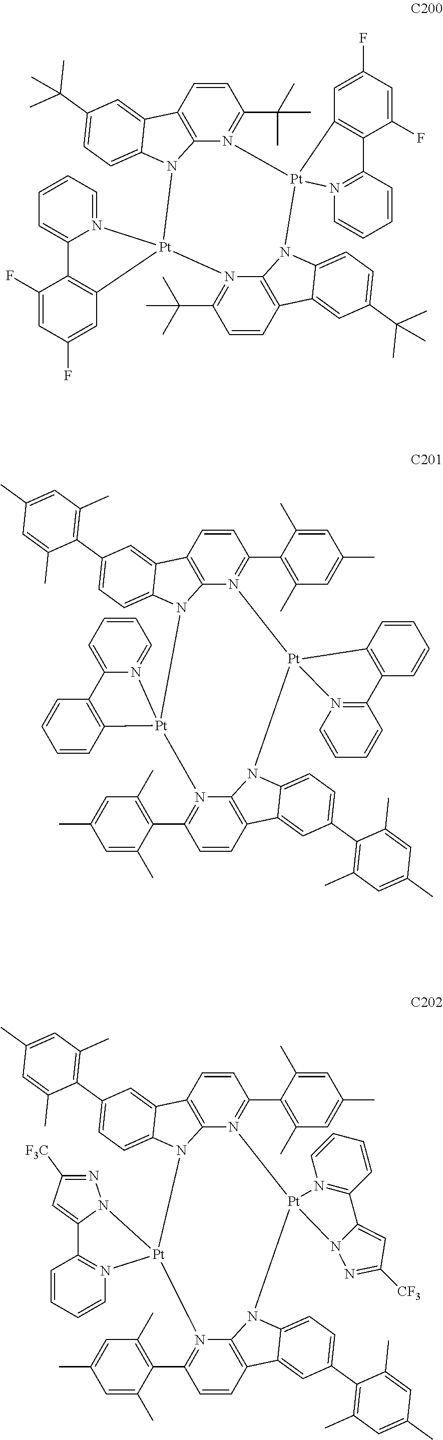

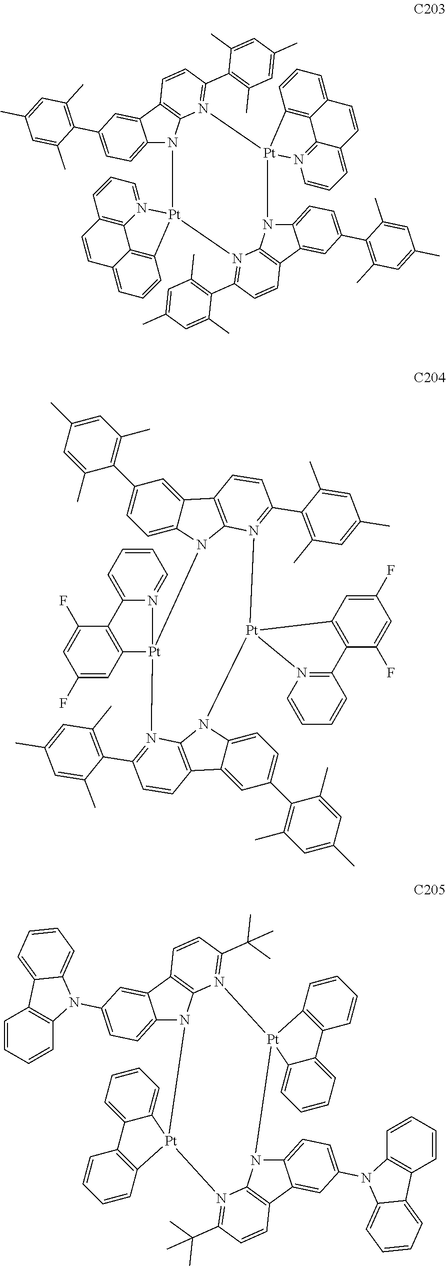

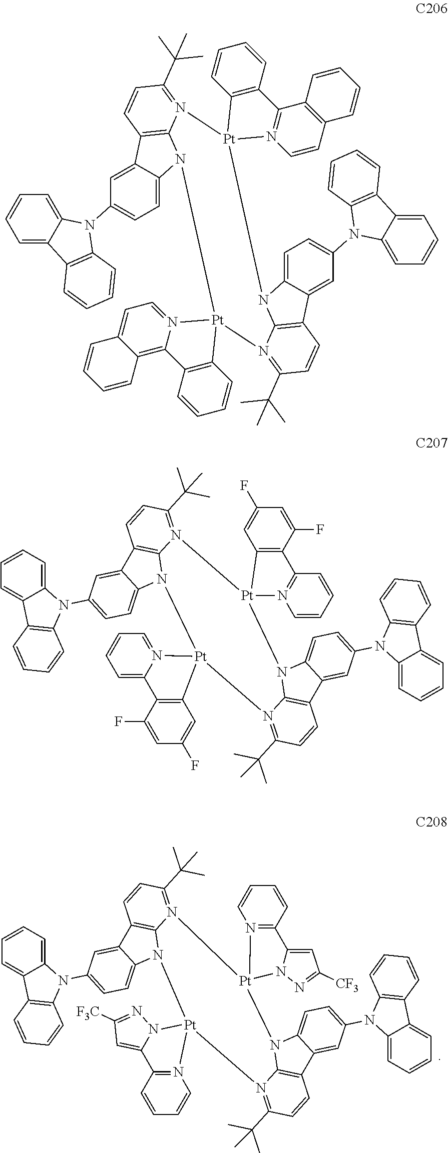

12. An organic electroluminescent device, wherein, the organic electroluminescent device comprises a first electrode, a second electrode and a light emitting layer positioned between the first electrode and the second electrode, wherein the light emitting layer comprises any one of, or a combination of at least two of, the binuclear metal platinum complex according to claim 1.

13. An organic electroluminescent device, wherein, the organic electroluminescent device comprises a first electrode, a second electrode and a light emitting layer positioned between the first electrode and the second electrode, wherein, the light emitting layer comprises the binuclear metal platinum complex according to claim 1 and an organic functional material, wherein the binuclear metal platinum complex accounts for 0.01%-100% by mass and the organic functional material accounts for 0-99.9% by mass.
